(19) United States
(12) Patent Application Publication
(10) Pub. No.: US 2026/0111626 A1
(43) Pub. Date: Apr. 23, 2026

(54) BROADBAND RAY TRACING-BASED ULTRASONIC SENSOR SIMULATION FOR SIMULATION ENVIRONMENTS AND APPLICATIONS

(71) Applicant: NVIDIA Corporation, Santa Clara, CA (US)

(72) Inventors: Viacheslav BOLNYKH, Berlin (DE); Ayman Elsaeid, Berlin (DE)

(21) Appl. No.: 18/924,716

(22) Filed: Oct. 23, 2024

(51) Int. Cl. G06F 30/20; G06T 15/06

(52) U.S. Cl. CPC G06F 30/20; G06T 15/06

(57) ABSTRACT

In various examples, broadband ray tracing-based ultrasonic sensor simulation for simulation environments and applications is disclosed. Ray tracing-based ultrasonic sensor array simulation may be used to generate a waveform representing measurement data for simulating sensor inputs for machines operating in a simulated environment. An ultrasonic sensor array simulation model may include a pre-firing ray preparation stage, a ray tracing-based energy transport engine, and a contribution ray processing stage. The ray preparation stage may generate a set of rays based on parameters characterizing sonic emissions. The ray tracing-based energy transport engine computes the trajectory of individual reflected rays produced from the sonic emissions. The ray tracing-based energy transport engine may compute an atmospheric and interaction attenuation for the individual rays. Contributions rays received at a sensor receiver may be used by the contribution ray processing stage to compute a measurement data output from the ultrasonic sensor array simulation model.

### CROSS-REFERENCE TO RELATED APPLICATIONS

This application is related to U.S. patent application Ser. No. ______, titled “SIMULATING ULTRASONIC SIGNALS USING RAY TRACING,” attorney docket 24-MU-0059US01/420509, filed on even date herewith, which is hereby incorporated by reference in its entirety.

### BACKGROUND

In the development of autonomous vehicles, simulation environments are used to create realistic and dynamic virtual driving environments that mimic real-world scenarios, allowing the autonomous systems to be trained to navigate and react in various situations. For example, a virtual driving environment can simulate different weather conditions, traffic scenarios, and pedestrian behaviors, and/or other diverse conditions. One advantage of using simulations is the ability to test edge scenarios within virtual driving environments that are rare or extreme and may not occur frequently in real-world driving. In a simulation environment, these situations can be safely replicated, allowing the autonomous system to learn how to react appropriately. In order to perceive and realistically interact with its surroundings within a virtual driving environment, the sensor on the vehicle may be simulated using sensor models that are capable of simulating the physical effects relevant for the sensor modality in use.

### SUMMARY

Embodiments of the present disclosure relate to broadband ray tracing-based ultrasonic sensor simulation for simulation environments and applications. Systems and methods are disclosed that include a ray tracing-based ultrasonic sensor array simulation model that generates a waveform representing measurement data for use as a simulated vehicle sensor input within a simulation environment such as a virtual driving environment.

As described herein, ray tracing-based ultrasonic sensor array simulation may be used to generate a waveform representing measurement data that may be used to simulate vehicle sensor inputs in virtual driving environments—including hardware-in-the-loop simulations. Ray tracing-based ultrasonic sensor array simulation may be performed using an ultrasonic sensor array simulation model that includes a pre-firing ray preparation stage that prepares and emits a broadband wave into the virtual driving environments (e.g., simulating an ultrasonic sensor (USS) emitter), a contribution ray processing stage that aggregates contribution energies representing received reflections of the broadband wave (e.g., simulating one or more USS receivers), and a ray tracing-based energy transport engine that models sound wave reflections (e.g., from one or more objects in the virtual driving environments) that determine the contribution energies.

In some embodiments, the ray preparation stage generates a plurality of rays based on parameters characterizing the sonic emissions of the physical sensor device that the ultrasonic sensor array simulation is simulating. The ray preparation stage takes input parameters, such as but not limited to ray density, pulse power, and/or membrane directivity, in order to prepare a set of rays that represent a sampling of the front of an emitted wave transmitted by the ultrasonic sensor. The tracking of rays that propagate between an emitter and one or more receivers of the USS simulation is performed using the ray tracing-based energy transport engine. Based on the location of the simulated USS emitter within the simulation environment, and the location of one or more USS receivers in the simulation environment, the ray tracing-based energy transport engine processes the plurality of rays computed by the pre-firing ray preparation stage as launched into the simulation environment from the location of the simulated USS emitter. The ray tracing-based energy transport engine computes the trajectory of an individual ray based on the location and translation of the simulated USS emitter and the offset of the individual ray from the main axis of the emitter, and computes a resulting set of reflections from that individual ray generated by interactions with one or more objects in the simulation environment. Ray reflections that complete a propagation path from the USS emitter to a USS receiver are referred to herein as “contribution rays” that carry contribution energies that may be used by the contribution ray processing stage in computing a USS measurement data output from the ultrasonic sensor array simulation model. Because sound energy attenuates as a function of distance, the attenuation of the initial energy level of the ray as emitted from the sensor emitter (which is a value stored in each ray) may be multiplied by an atmospheric attenuation coefficient to compute a contribution energy associated with the contribution as received at the USS receiver. The contribution energy of a contribution may also be influenced based on object interaction attenuations. That is, when a ray is reflected by the surface of an object, the energy transported by that ray is attenuated by an interaction attenuation factor because at least a portion of the energy is absorbed by the object. As such, in some embodiments, the ray tracing-based energy transport engine may compute an interaction attenuation to a reflected ray based at least in part on one or more material characteristics of objects that reflect rays to further attenuate the contribution energy of a contribution. Waveform reconstruction may be performed during the contribution ray processing stage using a set of contribution rays received by one or more USS receivers to produce a waveform representing an output from the ultrasonic sensor array simulation that may be used as an ultrasonic sensor measurement by other systems.

### BRIEF DESCRIPTION OF THE DRAWINGS

The present systems and methods for simulating ultrasonic signals using broadband ray tracing and are described in detail below with reference to the attached drawing figures, wherein:

FIG. 1 is a data flow diagram illustrating an example simulation platform comprising an ultrasonic sensor (USS) array simulation model, in accordance with some embodiments of the present disclosure;

FIG. 2 is a data flow diagram illustrating an example broadband ray data structure, in accordance with some embodiments of the present disclosure;

FIG. 3 is a data flow diagram illustrating an example of contribution ray generation by a ray tracing-based energy transport engine, in accordance with some embodiments of the present disclosure;

FIG. 4 is a data flow diagram illustrating an example of contribution ray data processing to produce USS measurement signals, in accordance with some embodiments of the present disclosure;

FIG. 5 is a diagram illustrating an example method for an ultrasonic sensor (USS) array simulation, in accordance with some embodiments of the present disclosure;

FIGS. 6A-6F are example illustrations of a simulation system, in accordance with some embodiments of the present disclosure;

FIG. 7A is an example illustration of a simulation system at runtime, in accordance with some embodiments of the present disclosure;

FIG. 7B includes a cloud-based architecture for a simulation system, in accordance with some embodiments of the present disclosure;

FIG. 8A is an illustration of an example autonomous vehicle, in accordance with some embodiments of the present disclosure;

FIG. 8B is an example of camera locations and fields of view for the example autonomous vehicle of FIG. 8A, in accordance with some embodiments of the present disclosure;

FIG. 8C is a block diagram of an example system architecture for the example autonomous vehicle of FIG. 8A, in accordance with some embodiments of the present disclosure;

FIG. 8D is a system diagram for communication between cloud-based server(s) and the example autonomous vehicle of FIG. 8A, in accordance with some embodiments of the present disclosure;

FIG. 9 is a block diagram of an example computing device suitable for use in implementing some embodiments of the present disclosure; and FIG. 10 is a block diagram of an example data center suitable for use in implementing some embodiments of the present disclosure.

### DETAILED DESCRIPTION

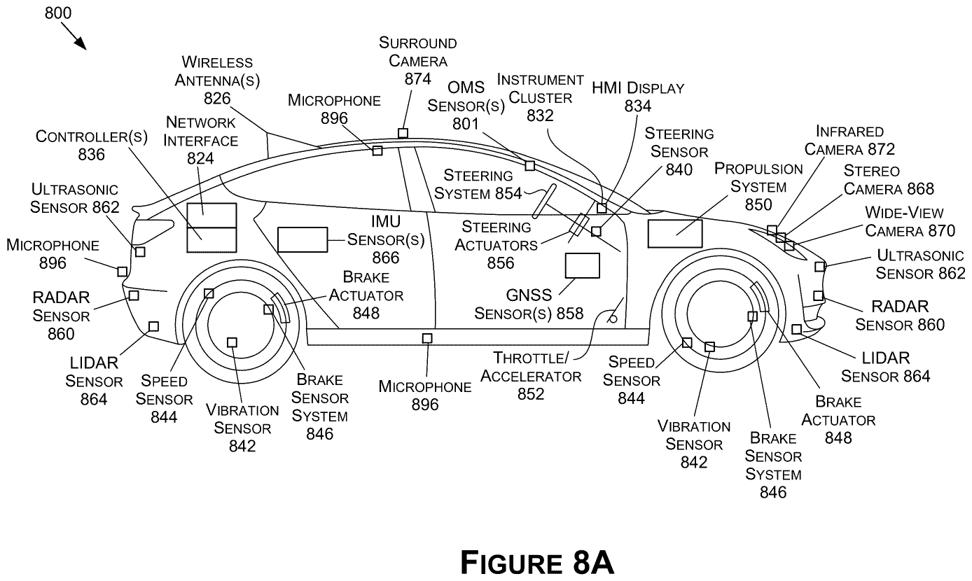

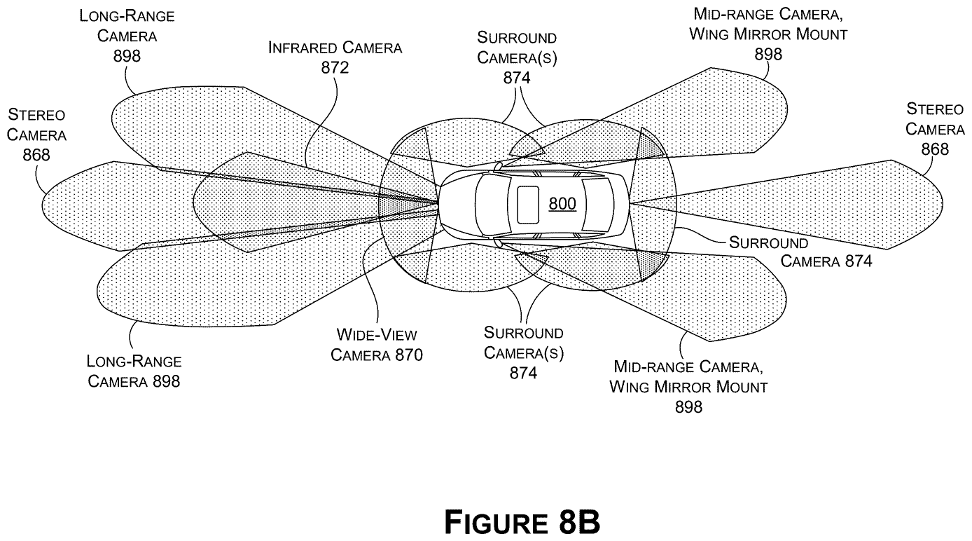

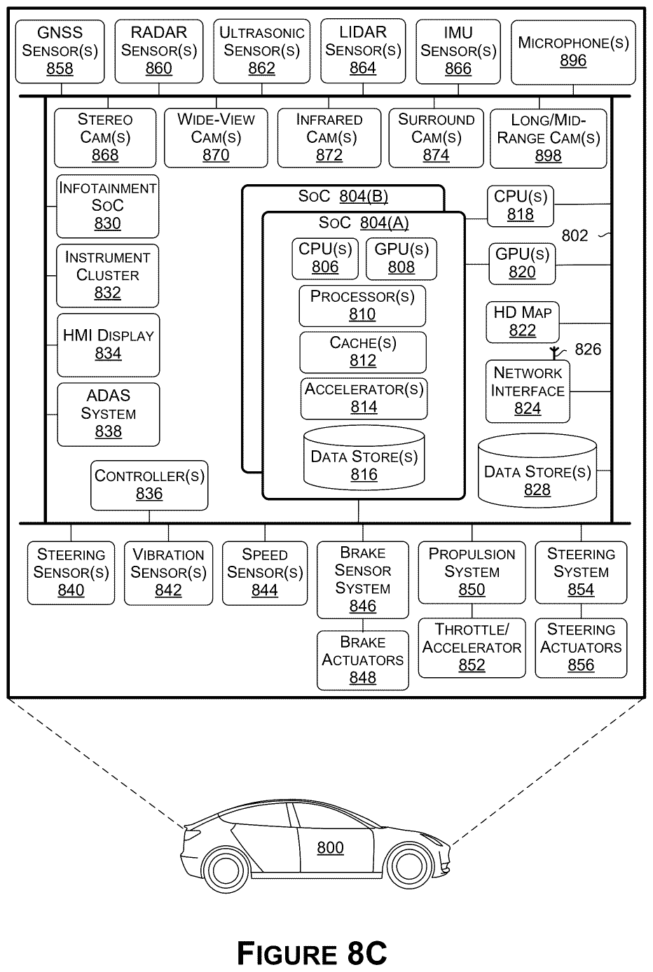

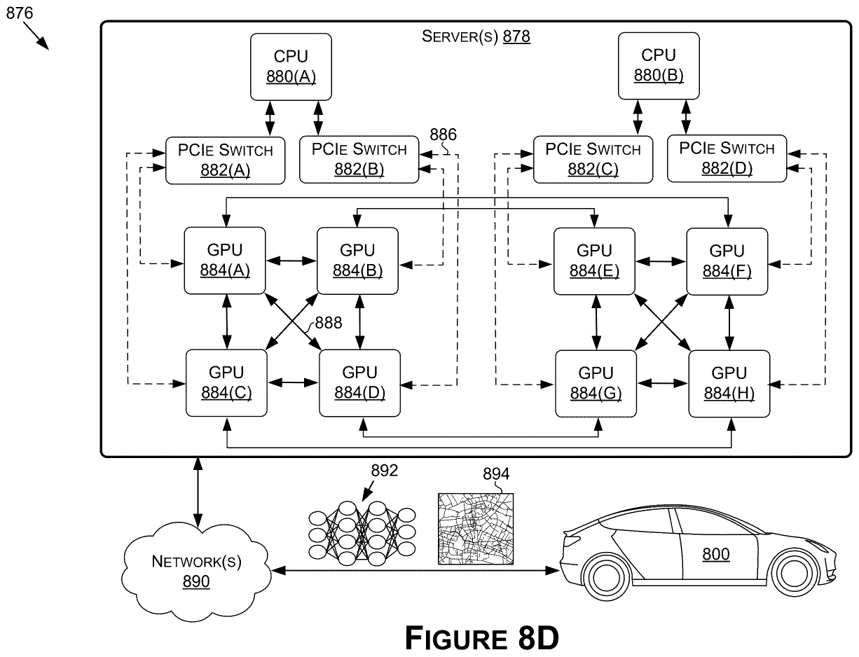

Systems and methods are disclosed related to simulating ultrasonic signals using broadband ray tracing. Although the present disclosure may be described with respect to an example autonomous or semi-autonomous vehicle or machine 800 (alternatively referred to herein as “vehicle 800” or “ego machine 800,” an example of which is described with respect to FIGS. 8A-8D), this is not intended to be limiting. For example, the systems and methods described herein may be used by, without limitation, non-autonomous vehicles or machines, semi-autonomous vehicles or machines (e.g., in one or more advanced driver assistance systems (ADASs)), autonomous vehicles or machines, piloted and unpiloted robots or robotic platforms, warehouse vehicles, off-road vehicles, vehicles coupled to one or more trailers, flying vessels, boats, shuttles, emergency response vehicles, motorcycles, electric or motorized bicycles, aircraft, construction vehicles, trains, underwater craft, remotely operated vehicles such as drones, and/or other vehicle types. In addition, although the present disclosure may be described with respect to simulation of ultrasonic sensors for autonomous driving, this is not intended to be limiting, and the systems and methods described herein may be used in augmented reality, virtual reality, mixed reality, robotics, security and surveillance, autonomous or semi-autonomous machine applications, and/or any other technology spaces where ultrasonic sensor modeling may be used.

The present disclosure relates to ultrasonic sensor simulation for simulation environments and applications. More specifically, one or more embodiments include a ray tracing-based ultrasonic sensor array simulation that generates a waveform representing measurement data for use as a simulated vehicle sensor input within a dynamic simulation environment such as a virtual driving environment.

An ultrasonic sensor (USS) is a type of sensor that measures the distance to a target by emitting ultrasonic sound waves and processing reflections of the emitted ultrasonic sound waves (e.g., as a short burst) to compute a total propagation time. The total propagation time indicates a distance to the object that produced the reflections of the emitted ultrasonic sound waves. Within the context of autonomous vehicles, ultrasonic sensors are primarily used during low-speed maneuvers, such as for parking applications. However, in virtual driving environment technologies today, there is presently a lack of sensor models that can produce sensor data of sufficient fidelity to mimic the sensor data produced by an ultrasonic sensor for use in real-time driving simulations (such as hardware-in-the-loop simulations).

For example, many existing technologies for modeling sound-based sensors are primarily focused on simulating underwater sonar sensors or acoustic simulations (e.g., for seismic sensing or room acoustics). Modeling the physics of the underwater acoustics applicable to sonar sensors does not accurately model ultrasonic waves propagating through air, and does not produce a perception of the environment with sufficient resolution for tasks such as navigating a vehicle in parking scenarios. Moreover, current sonar models are not readily adapted to simulating automotive schemes of using USS sensor crosstalk to improve triangulation capabilities. While models for acoustic sensors are known, those models are primarily focused on getting the highest fidelity possible using post-processing algorithms (e.g., using finite difference or finite element methods) as opposed to computational complexity, speed, or performance - and therefore are not suitable for real-time hardware-in-the-loop simulation environments. Adapting such acoustic techniques for less complex computations produces low-fidelity phenomenological models with poor accuracies that renders them unusable for end-to-end testing and simulation-driven system development. Other USS simulation techniques based on finite element simulation offer a high level of fidelity, but at the expense of large computational cost. Many published methodologies are limited to the well-bounded room acoustics (e.g., where the emitted acoustic energy stays within a closed environment), whereas automotive applications operate in environments having open boundaries wherein much of the emitted energy from a sensor may be lost into the surrounding environment. Technologies using rasterization techniques are typically fast to compute, however, they lack the accuracy needed to control the movement of a vehicle.

In contrast to these existing technologies, the embodiments presented herein provide for ray tracing-based ultrasonic sensor array simulation. As described herein, ray tracing-based ultrasonic sensor array simulation may be used to generate a waveform representing measurement data that may be used to simulate vehicle sensor inputs in dynamic environments (e.g., virtual driving environments)—including hardware-in-the-loop simulations. Ray tracing-based ultrasonic sensor array simulation may be performed using an ultrasonic sensor array simulation model that includes a pre-firing ray preparation stage that prepares and emits a broadband wave into the virtual driving environments (e.g., simulating a USS emitter), a contribution ray processing stage that aggregates contribution energies representing received reflections of the broadband wave (e.g., simulating one or more USS receivers), and a ray tracing-based energy transport engine that models sound wave reflections (e.g., from one or more objects in the virtual driving environments) that determine the contribution energies.

In some embodiments, the ray preparation stage generates a plurality of rays based on parameters characterizing the sonic emissions of the physical sensor device that the ultrasonic sensor array simulation is simulating. For example, an ultrasonic sensor typically comprises a piezoelectric material membrane, either circular or elliptical in shape, that is driven by applying a modulated electrical signal (e.g., using pulse-width modulation, amplitude of frequency modulation, or other type of modulation) to stimulate the membrane to emit high-frequency acoustic pulses (e.g., between 23 kHz and 500 kHz). The effective range of an ultrasonic sensor is inversely proportional to its operating frequency so that lower frequency sensors are more effective for long-range measurements as compared to higher frequency sensors that are more effective for short-range measurements.

The ray preparation stage takes input parameters, such as but not limited to ray density, pulse power, and/or membrane directivity, in order to prepare a set of rays that represent a sampling of the front of an emitted wave transmitted by the ultrasonic sensor. For example, based on a function of the shape and/or directivity of the membrane, emissions from an ultrasonic sensor may exhibit a gain/radiation pattern where pulse power of the front of an emitted wave is at a maximum along a main axis normal to the surface at the center of the membrane, and diminishes in power as a function of angular offset (e.g., with respect to azimuth and elevation planes) from the main axis. That is, the emitters are not isotropic and do not emit the same amount of energy in all angular directions. As such, while the pulse power parameter may define the total power of the sonic energy emitted from the simulated sensor, the power of the wave front at a given angular offset will comprise a fraction of that total power that may be computed based on the gain pattern applied by the ray preparation stage. Moreover, the gain pattern itself may be a function of a field of view parameter for the sensor emitter—with a narrow angle sensor having gains that fade to zero at greater angles more rapidly than wide-angle sensors.

With respect to ray density, this input parameter may indicate to the ray preparation stage the density of the sampling of the simulated wave front—which determines how many rays are used to simulate the wave front of an emitted pulse. For purposes of a simplified example, a ray density parameter instructing the ray preparation stage to generate a ray at every one degree of angular offset (e.g., with respect to azimuth and elevation planes) from the main axis will produce a substantially denser sampling of the simulated wave front than a ray density parameter instructing the ray preparation stage to generate a ray at every 5 degrees of angular offset. The ray preparation stage may assign one or more (e.g., each) ray(s) an initial energy level that is a fraction of the total pulse power parameter as determined using the gain pattern. Because simulations using a greater ray density use greater compute to execute in real time as compared to a lower ray density, in some embodiments, adjusting the ray density parameter may be used to optimize USS simulation to better accommodate execution on a particular set of hardware.

Within the context of a simulation executed by a simulation platform, at least one and potentially each ray may be defined using a data structure that stores a payload of properties describing various characteristics of the sample of the wave front represented by that ray. For example, the data structure may initially transport information such as, but not limited to, power data indicating an initial energy level of the ray as emitted from the sensor emitter, and frequency data indicating a frequency of the energy (e.g., based on a nominal operating frequency of the sensor). In some embodiments, a simulated USS may comprise a dual or multifrequency sensor that is capable of emitting acoustic pulses at different frequencies. In such embodiments, the ray preparation stage may generate a distinct, independent set of rays for each channel of different frequencies—based on a set of input parameters defined for each frequency. The frequency data carried by each ray emitted into the simulation environment may be used to distinguish rays representing a sample of a first frequency channel wave front from rays representing samples of a different frequency channel wave front. In some embodiments, a ray may comprise modulation information indicating a modulation mode of the wave front represented by the set of rays (e.g., a chirp, a pulse-width modulation, a single frequency modulation, amplitude of frequency modulation, etc.).

In some embodiments, tracking of rays that propagate between a emitter and one or more receivers of the USS simulation is performed using the ray tracing-based energy transport engine. Based on the location of the simulated USS emitter within the simulation environment, and the location of one or more USS receivers in the simulation environment, the ray tracing-based energy transport engine processes the plurality of rays computed by the pre-firing ray preparation stage as launched into the simulation environment from the location of the simulated USS emitter. The ray tracing-based energy transport engine computes the trajectory of an individual ray based on the location and translation of the simulated USS emitter and the offset of the individual ray from the main axis of the emitter, and computes a resulting set of reflections from that individual ray generated by interactions with one or more objects in the simulation environment. In some embodiments, the ray tracing-based energy transport engine applies vector algebra-based algorithms that compute one or more ray reflections based on the incident angle of an incoming ray that reflects off the surface of an object. At least on (e.g., some, each, all, etc.) ray reflection(s) may also comprise a data structure that carries information based at least on the information embedded in its respective parent ray as initially generated by the pre-firing ray preparation stage and emitted by the USS emitter. The launch of an (e.g., each) initial ray launched by the USS emitter thus has the potential to cause the generation of many ray reflections, depending on the number, size, and position of objects in the simulation environment that present surfaces from which rays can be reflected. While many of the ray reflections will have trajectories that cause them to propagate in directions away from the USS receivers, those ray reflections that do complete the path from the USS emitter to a USS receiver are referred to herein as “contribution rays” that carry contribution energies, which may be used by the contribution ray processing stage in computing a USS measurement data output from the ultrasonic sensor array simulation model.

In some embodiments, for a (e.g., each) ray reflection representing a contribution, the ray tracing-based energy transport engine may compute a total propagation time (e.g., a round-trip delay time) indicating the amount of time that has elapsed from the launch of the ray from the USS emitter to the reception of the contribution at a USS receiver. For example, the information carried by a contribution may indicate the time the parent ray was emitted from the USS sensor, and the ray tracing-based energy transport engine may record to the ray data structure the time that a contribution was received at a USS receiver. The difference in time represents the total propagation time associated with the contribution energy of that contribution—which also indicates the total distance traveled by that contribution energy (e.g., the speed of sound in air at 20° C. is about 343 meters/second). Because sound energy attenuates as a function of distance, the attenuation of the initial energy level of the ray as emitted from the sensor emitter (which is a value stored in each ray) may be multiplied by an atmospheric attenuation coefficient to compute a contribution energy associated with the contribution as received at the USS receiver. In some embodiments, the atmospheric attenuation coefficient may be adjusted to account for environmental conditions that affect either propagation speed or energy absorption, such as temperature and/or humidity.

The contribution energy of a contribution may also be influenced based on object interaction attenuations. That is, when a ray is reflected by the surface of an object, the energy transported by that ray is attenuated by an interaction attenuation factor because at least a portion of the energy is absorbed by the object. When the object comprises a hard and/or dense surface material (such as stone or brick surfaces), the attenuation of energy that continues to propagate with the reflected ray can be expected to be minimal. In contrast, when the object comprises a soft and/or porous surface material (e.g., fabric and/or foliage), the attenuation of energy that continues to propagate with the reflected ray can be expected to be greater. As such, in some embodiments, the ray tracing-based energy transport engine may compute an interaction attenuation to a reflected ray based at least in part on one or more material characteristics of objects that reflect rays to further attenuate the contribution energy of a contribution. Moreover, for some object surfaces, the amount of acoustic energy absorbed by an objection (and therefore the amount of interaction attenuation) may at least in part be a function of the frequency of the acoustic energy. As such, in some embodiments, the ray tracing-based energy transport engine may read the frequency data from a ray and compute the interaction attenuation caused by a ray's interaction with the object further based on the frequency data. The resulting contribution energy of a contribution received at a USS sensor may thus be computed by reducing the initial energy level of the ray as emitted from the sensor emitter based on the combination of atmospheric attenuation and one or more object interaction attenuations.

In this way, a respective contribution energy may be computed by the ray tracing-based energy transport engine for contributions received at a USS receiver. The contributions received at a USS receiver may originate from different rays of a simulated wave emission and/or from multipath propagations of rays resulting from reflections of the same initial ray by different object surfaces. The contribution energies of the set of contributions ray-traced to a USS receiver from an emission may be aggregated (e.g., using radiometric equations) to compute a total of received energy at that USS receiver, and the same aggregation of contribution energies performed at one or more (e.g., each) of the USS receivers of the ultrasonic sensor array simulation. A waveform reconstruction may be performed by the contribution ray processing stage using the set of contributions from the USS receiver to produce a waveform representing an output from the ultrasonic sensor array simulation that may be used as an ultrasonic sensor measurement by other systems.

At the contribution ray processing stage, the ultrasonic sensor array simulation may generate a contribution list for each USS receiver. The contribution list may include, in one or more embodiments, on the order of millions of contributions, where a contribution represents a distinct acoustic energy path through the simulation environment from the USS emitter to that respective USS receiver. Moreover, a contribution carries embedded information as described herein, such as its final contribution energy level (after application of atmospheric and object interaction attenuations), total propagation time, frequency data, the number of reflections encountered along that contribution's path from the USS emitter, and/or other information as described herein.

With regards to a physical USS receiver device, the receiver may comprise a membrane that receives reflections of the acoustic energy pulse. The energies from those various reflections will cause the membrane to vibrate in a distinct time-dependent pattern that is indicative of the time delay and energy levels of the various reflections as they interact with the membrane. The resulting time-dependent vibrations of the membrane are converted into electrical signals representing a waveform output from that receiver. To model this process in simulation, embodiments of the present disclosure process the aggregation of contributions—e.g., during a contribution ray processing stage—based on a model that mimics the membrane vibration response to the reception of the contribution energies based on the frequency of the contributions as indicated by the embedded frequency data carried by the contributions. In some embodiments, the contribution ray processing stage accumulates the contribution energies and constructs an output waveform based on assigning each contribution to represent a component of the output waveform, performing an energy summation over time by taking into account the contribution energy of each contribution, the relative timing of each contribution as received at the USS receiver, and the frequency data for the emitted wave front.

Based on these parameters, the contribution ray processing stage assembles an acoustic wave envelope representing a time-dependent gain function resulting from the aggregation of the contributions resulting from the emitted pulse, applies the model of the physical membrane to compute the vibrational effect of the acoustic wave envelope on the membrane, and converts the vibrations into a representation of a sensor output measurement signal. In some embodiments, the acoustic wave envelope represents an envelope sampled with a particular sampling frequency (e.g., determined by the model) and may be produced by directly depositing the ray energy into a particular sample. In some embodiments, the contribution ray processing stage may introduce noise to the output waveform to simulate known device-specific characteristics and/or external noises. For example, to produce a more realistic sensor output signal, the contribution ray processing stage may include a thermal noise component that mimics thermal noise found in output signals from physical USS sensors and/or that mimics electromagnetic interference (EMI) in an electrical path picked up from an outside source. The sensor output measurement signal may be supplied as USS sensor data input to perception systems of an ego-machine simulation operating within the simulation environment—where the sensor output measurement signal may be evaluated to determine the distance and/or position of objects within a proximity of the ego machine and used to assist in navigating the ego machine, for example, into or out of a parking space.

A real-life physical USS may be implemented as a transceiver that integrates both transmitter and receiver functionalities in the same sensor device. As such, in some embodiments, the ultrasonic sensor simulation described herein may include one or more simulated USS transceivers where a round-trip path of a ray involves contributions being received by a receiver at the location shared with an emitter from which the original set of rays was emitted. Moreover, in some real-life physical vehicles that use ultrasonic sensors, the vehicle may comprise a plurality of USS sensor devices distributed about the vehicle exterior, each of which may be operated in conjunction with each other in various combinations. For example, an electronic control unit (ECO) of the vehicle may operate reconfigurable sets of USS sensor devices together to form a USS sensor array. In such an array, one sensor may be designated as the USS emitter to emit the ultrasonic pulse, and one or more of the other sensors may be designated as USS receivers to receive and process the resulting signal reflection and output waveform signals based on the respective reflected energies they receive. Such sensor crosstalk techniques may be used to improve triangulation capabilities so that a vehicle's perception system may more accurately determine the position of objects around the vehicle. In some embodiments, the ultrasonic sensor array simulation model may simulate sensor crosstalk techniques by receiving contributions from a set of emitted rays at multiple simulated USS receivers, and may use waveform reconstruction to produce a USS measurement data output from each simulated USS receiver. The perception systems executed within the simulation environment may then apply those sensor crosstalk techniques using the measurement data output from each simulated USS receiver to more accurately determine the position of objects within the simulation environments. The array may be reconfigurable by the simulation platform so that different configurations may define which devices operate as USS emitters and which operate as USS receivers.

As previously mentioned, depending on the complexity of a simulation environment (e.g., the size, number, dynamic movements and/or location of objects that may reflect sound energy) the number of contributions received at the one or more USS receivers that need to be processed to construct output waveforms may be on the order of millions of contributions. Moreover, to support real-time driving simulations such as hardware-in-the-loop simulations, pre-firing ray preparation, ray tracing-based energy transport, and contribution ray processing stage contribution processing to generate output waveform sensor measurements need to be performed within the same real-time time duration that a physical USS sensor would take to emit an ultrasonic pulse and output a resulting measurement signal. As such, in some embodiments, one or more operations of the pre-firing ray preparation, ray tracing-based energy transport, and/or contribution ray processing stage contribution processing may be executed by the simulation platform using parallel computing techniques, graphics processing unit (GPU) acceleration, and/or similar techniques where large sets of individual contributions may be processed in parallel (where the same set of computations are performed for each contribution) to construct the output waveform associated with each of the one or more USS receivers. In some embodiments, for example, ray tracing-based energy transport and contribution ray processing stage contribution processing may be implemented using NVIDIA RTX™ ray-tracing and neural-rendering technologies. Embodiments may apply a bounding volume hierarchy (BVH)-based process (e.g., a hierarchical grouping of three-dimensional (3D) objects, where each group is associated with a conservative bounding box) to interpolate ray positions during ray tracing to determine the contributions that reach a particular USS receiver.

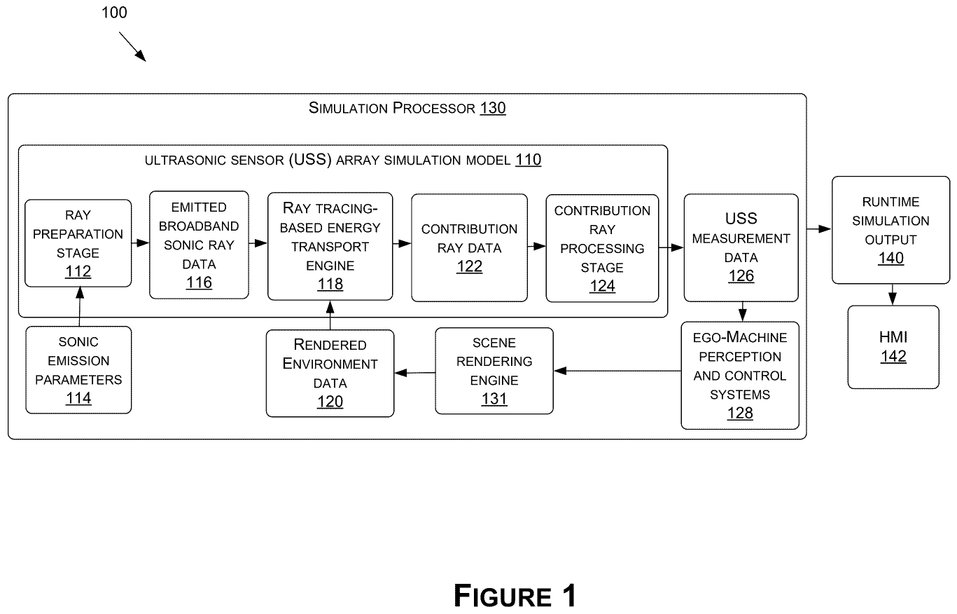

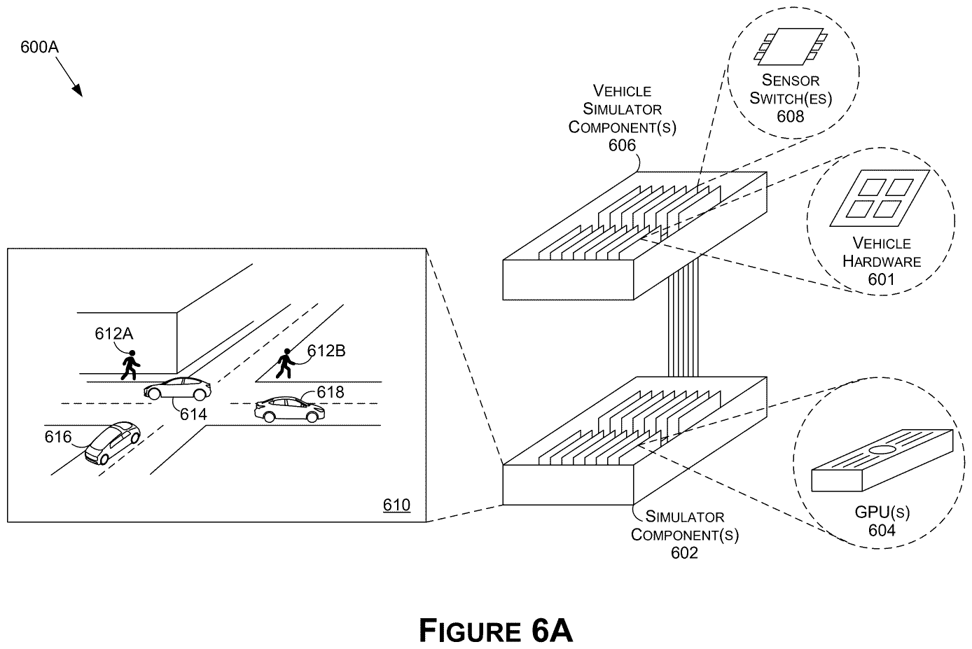

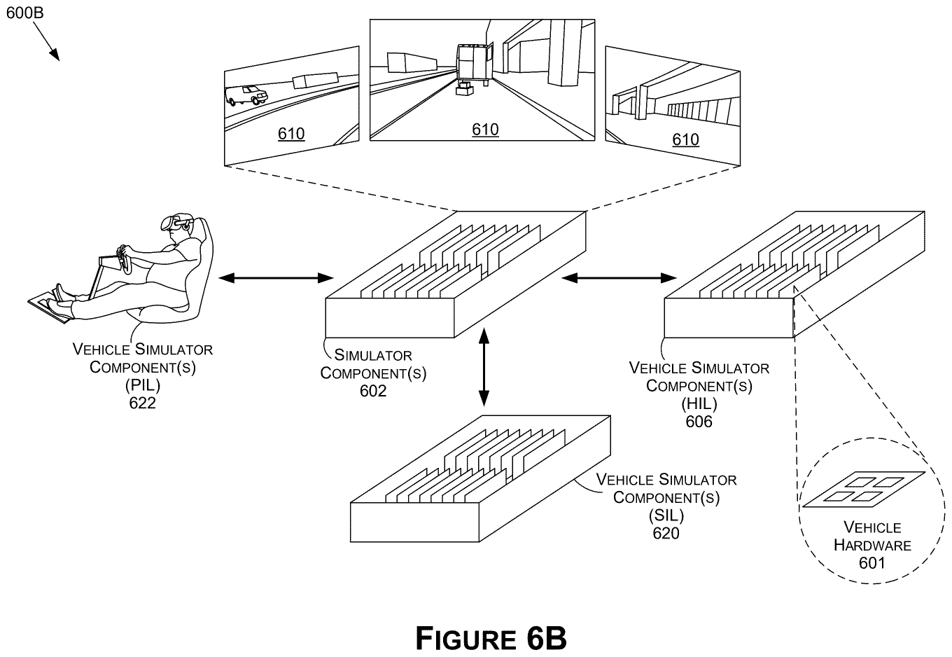

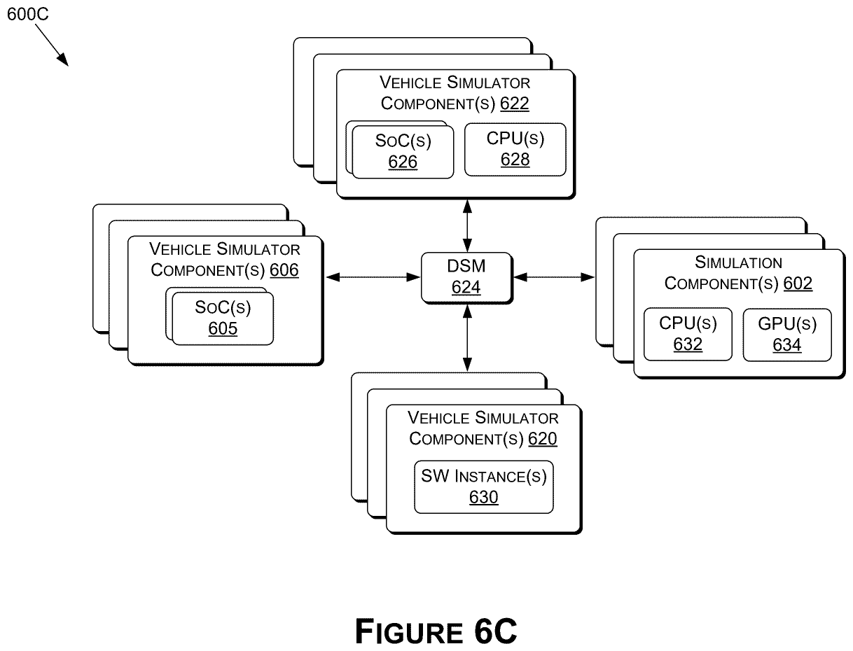

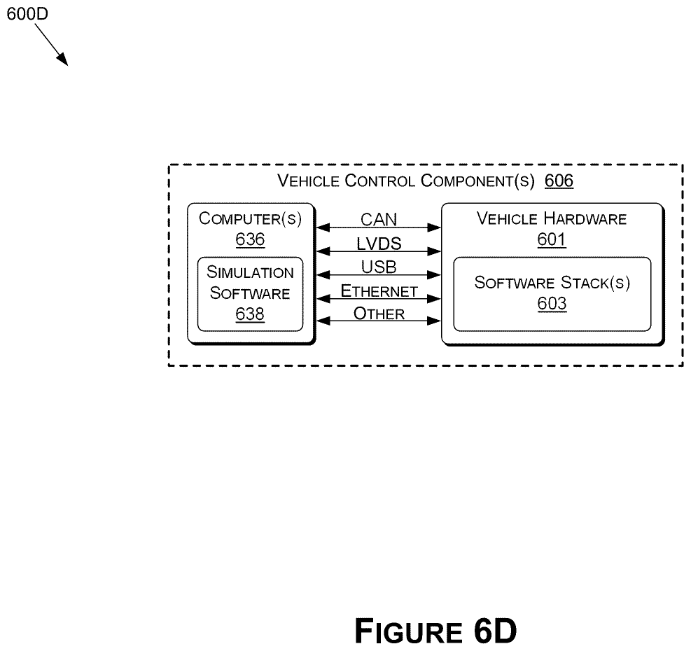

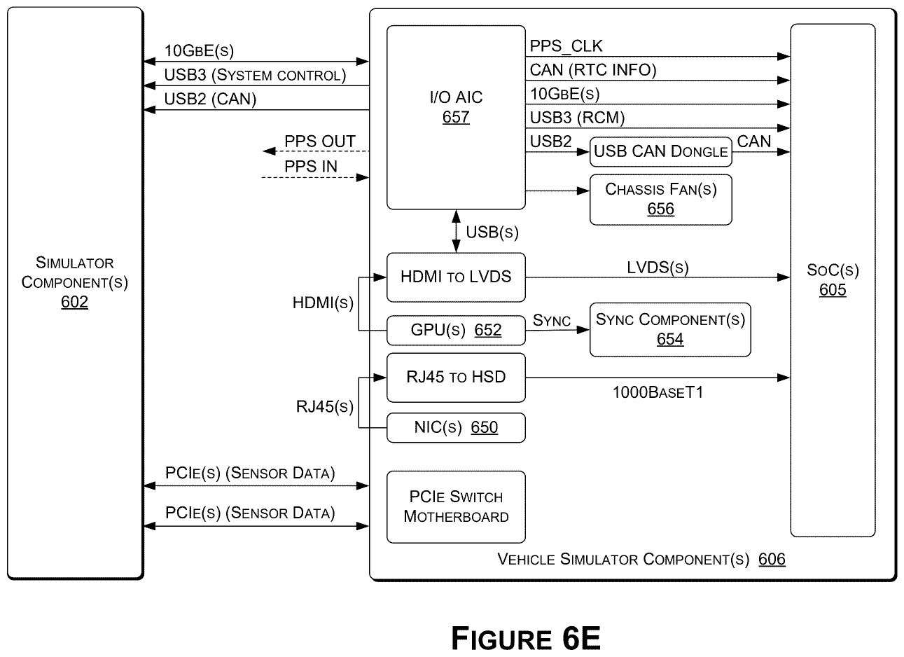

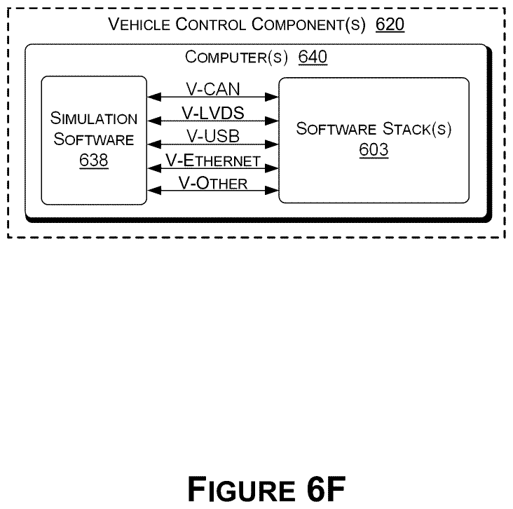

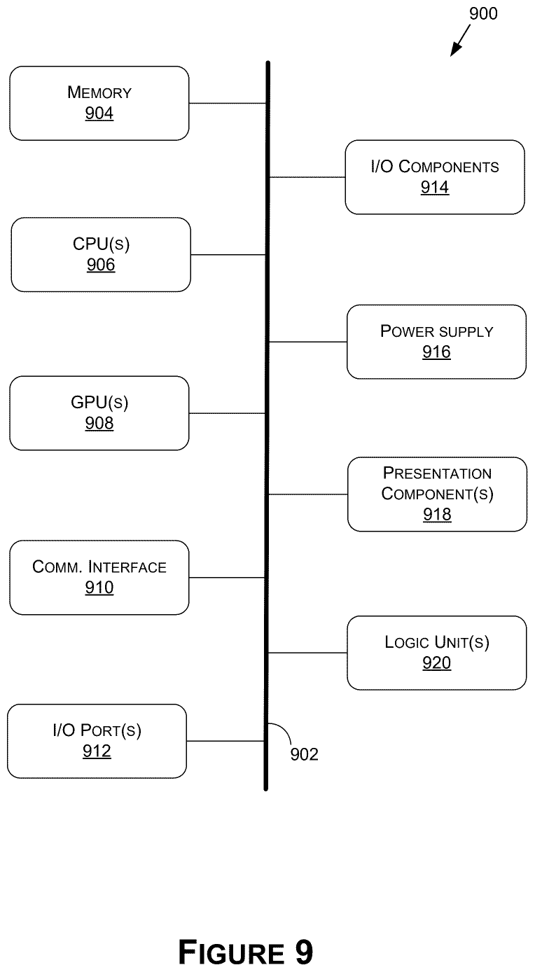

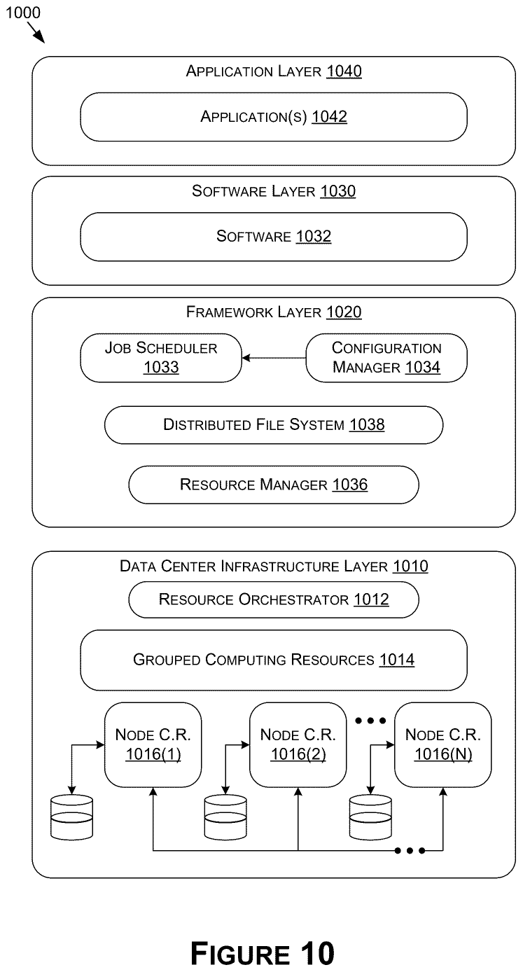

With reference to FIG. 1, FIG. 1 is an example data flow diagram for a process for a simulation platform 100, in accordance with some embodiments of the present disclosure. It should be understood that this and other arrangements described herein are set forth only as examples. Other arrangements and elements (e.g., machines, interfaces, functions, orders, groupings of functions, etc.) may be used in addition to or instead of those shown, and some elements may be omitted altogether. Further, many of the elements described herein are functional entities that may be implemented as discrete or distributed components or in conjunction with other components, and in any suitable combination and location. Various functions described herein as being performed by entities may be carried out by hardware, firmware, and/or software. For instance, various functions may be carried out by a processor comprising processing circuitry executing instructions stored in memory. In some embodiments, the various functions and operations of simulation platform 100 described herein may be implemented at least in part using a simulation system 600 such as represented by simulation systems 600A, 600B, 600C, and 600D in FIGS. 6A-6D, and described in more detail below. In some embodiments, the systems, methods, and processes described herein may be executed using similar components, features, and/or functionalities to those of example autonomous vehicle 800 of FIGS. 8A-8D, example computing device 900 of FIG. 9, and/or example data center 1000 of FIG. 10.

As shown in FIG. 1, the simulation platform 100 includes a simulation processor 130 that comprises a scene rendering engine 131 used to create realistic and dynamic virtual environments (e.g., virtual driving environments) for operating one or more ego agents that simulate ego machines such as, but not limited to, the example autonomous vehicle 800 of FIGS. 8A-8D. Scene rendering engine 131 may generate a virtual simulation environment that may model interactions between elements rendered within a scene (e.g., objects, terrain, surfaces, etc.) and one or more ego machines operating within the scene. For example, the scene rendering engine 131 may be used to execute and/or render a simulated driving environment within which one or more simulated machines may simulate travel across one or more roadway surfaces.

The scene rendering engine 131 may execute one or more algorithms using one or more graphics processing units (GPUs) (or other parallel processing circuitry, such as a parallel processing unit (PPU), a deep learning accelerator (DLA), a vector processing unit (VPU), a programmable vision accelerator (PVA), etc.) that may operate in conjunction with software executed on a central processing unit(s) (CPU(s)) coupled to memory. The GPUs may be programmed to execute kernels to implement one or more of the features and functions of the simulation processor 130 disclosed herein. In some embodiments, some features and functions of the simulation processor 130 may be distributed and performed by a combination of processors and/or cloud computing resources. In some embodiments, the simulation platform 100 comprises a simulation system such as, but not limited to, simulation systems 600A, 600B, 600C, and/or 600D in FIGS. 6A-F. The virtual simulation environment produced by the scene rendering engine 131 may comprise a simulated environment such as, but not limited to, the simulated environment 610 described with respect to FIGS. 6A-F.

More specifically, simulation processor 130 may execute one or more computer perception-based algorithms to generate data representing simulated sensor data corresponding to the sensor modality of one or more of the sensors of vehicle 800 described in FIGS. 8A-8D. In particular, the simulation processor 130 includes at least one ultrasonic sensor (USS) array simulation model 110 that may model the operation of one or more ultrasonic sensors of a simulated ego machine (e.g., ultrasonic sensor(s) 862 of vehicle 800) to produce an output of USS measurement data 126—which may indicate the relative position and/or distance of one or more elements within the simulation environment with respect to the simulated ego machine. Such USS measurement data 126 may then be used as an input to one or more systems, such as ego-machine perception and control systems 128, to navigate or otherwise operate the ego machine within the simulation environment. In some embodiments, USS measurement data 126 and/or runtime simulation outputs 140 based on USS measurement data 126 may be used in the process of training and/or validating machine learning models that are used to operate ego machines such as, but not limited to, vehicle 800. For example, the USS array simulation model 110 may output USS measurement data 126 for use as synthetic USS data for one or more USS sensors of an ego machine (such as vehicle 800 described with respect to FIGS. 8A-8D) that is using the simulation platform 100 to provide a simulated driving environment for training and/or testing components of the ego machine.

As illustrated in FIG. 1, in some embodiments, USS array simulation model 110 may comprise a ray preparation stage 112, a ray tracing-based energy transport engine 118, and a contribution ray processing stage.

The ray preparation stage 112 generates emitted broadband sonic ray data 116 (representing a set of USS emissions rays) based on sonic emission parameters 114 that characterize the sonic emissions of a physical sensor device that the USS array simulation model 110 is simulating. The ray preparation stage 112 takes sonic emission parameters 114, such as but not limited to ray density, pulse power, and/or membrane directivity, in order to prepare a set of rays that represent a sampling of a wave front of an emitted wave transmitted by an ultrasonic sensor. As previously discussed, sonic emission parameters 114 may be based, for example, on characteristics such as a shape and/or directivity of the membrane, and/or a gain/radiation pattern associated with emissions from a physical USS being modeled by the USS array simulation model 110. Ray density may indicate the density of the sampling of the simulated wave front—which determines the number and/or angular distribution of rays that are prepared by the ray preparation stage 112 to simulate the wave front of an emitted pulse. The ray preparation stage 112 may assign an initial energy level to each ray of the broadband sonic ray data 116 that is a fraction of the total pulse power parameter, as determined based on the gain pattern. Because simulations using a greater ray density use greater compute to execute in real time as compared to a lower ray density, in some embodiments, adjusting the ray density parameter may be used to optimize USS simulation to better accommodate execution on a particular set of hardware.

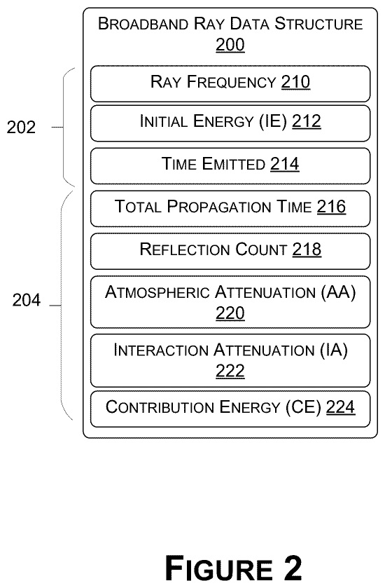

Each ray generated by the ray preparation stage 112 and included in the broadband sonic ray data 116 may be defined using a data structure, such as shown in FIG. 2, that stores properties describing various characteristics of the sample of the wave front represented by that ray. As shown in FIG. 2, a broadband ray data structure 200 may comprise a payload populated with a plurality of data elements. For a broadband ray data structure 200 corresponding with an initial ray emission produced from the ray preparation stage 112, the broadband ray data structure 200 may include data such as, but not limited to, ray frequency 210 (the frequency of the emitted wave being simulated), initial energy 212 (power data indicating an initial energy level of the ray as emitted from a sensor emitter), and/or a time emitted 214 (a timestamp indication of when the ray was emitted from the sensor emitter). In some embodiments, a corresponding broadband ray data structure 200 may be instantiated to represent individual respective rays generated by the ray preparation stage 112. That is, the broadband sonic ray data 116 may comprise a plurality of broadband ray data structures 200 where an individual broadband ray data structure 200 corresponds to an individual broadband sonic ray emission. The ray frequency 210, initial energy 212, and/or time emitted 214 may be referred to as ray emission data 202, because they indicate characteristics of a ray at the time the wave front comprising a set of rays is emitted from the simulated USS transmitter. As further discussed below, in some embodiments a broadband ray data structure 200 for a ray that has reflected from a surface within the simulation environment may include energy propagation data 204.

The tracking of rays that propagate between a USS emitter and one or more USS receivers of the USS simulation is performed using the ray tracing-based energy transport engine 118 based at least on the broadband sonic ray data 116. Based on the location of the simulated USS emitter within the simulation environment, and the location of one or more USS receivers in the simulation environment, the ray tracing-based energy transport engine 118 processes the broadband sonic ray data 116 to compute contribution ray data 122. The ray tracing-based energy transport engine 118 may compute the trajectory of individual rays based on the location and translation of the simulated USS emitter and the offset of the individual ray from the main axis of the emitter, and computes a resulting set of reflections from that individual ray generated by interactions with one or more objects in the simulation environment. Reflected rays that are reflected to the location of a USS receiver are used to define contribution ray data 122.

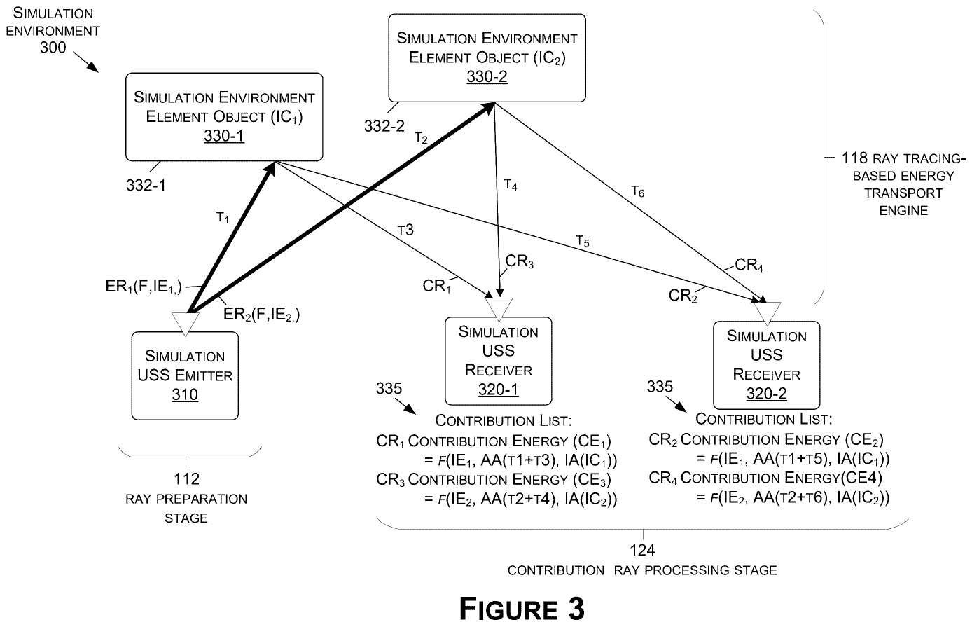

For example, referring to FIG. 3, FIG. 3 illustrates an example of a ray tracing-based energy transport performed by the ray tracing-based energy transport engine 118 based on a set of emitted rays, ER₁ and ER₂, prepared by the ray preparation stage 112. Within the context of the simulated environment, an ego machine may include a set of USS sensors that comprise at least a virtual USS emitter 310 and one or more virtual USS receivers 320 (shown as receivers 320-1 and 320-2). Although shown as separate devices, in some embodiments a virtual USS device may comprise an integration of both a virtual USS emitter 310 and a virtual USS receiver 320. The virtual USS emitter 310 and one or more virtual USS receivers 320 are mounted at preestablished positions and orientations on the ego machine, and the ego machine is located at a position and orientation known to the simulation processor 130 such that the global position coordinates and orientation of the virtual USS emitter 310 and one or more virtual USS receivers 320 within the context of the global coordinate system of the simulation environments may be readily determined by the simulation processor 130 and provided to the ray tracing-based energy transport engine 118. In some embodiments, the ray tracing-based energy transport engine 118 may input rendered environment data 120 from the scene rendering engine 131. The rendered environment data 120 describes elements of the simulated environment into which the set of emitted rays (e.g., ER₁ and ER₂) prepared by the ray preparation stage 112 are launched. For example, the rendered environment data 120 may include one or more of: the position and orientation of the virtual USS emitter 310 and one or more virtual USS receivers 320, and the position and orientation of one or more objects 330 (shown as objects 330-1 and 330-2) with which the set of emitted rays (e.g., ER and ER2) may interact (e.g., be absorbed and/or reflected by). As previously mentioned, the environment may comprise a dynamic environment wherein one or more of the objects 330 are moving within the environment. The rendered environment data 120 may define an atmospheric attenuation coefficient from which atmospheric attenuation of sonic wave energy may be computed. The rendered environment data 120 may define material characteristics of the surfaces (332-1 and 332-2) of the one or more objects 330 from which an incident attenuation coefficient (IC) may be derived to compute the incident attenuation of sonic wave energy of waves that are reflected by the surfaces 332-1 and 332-2. Based on the rendered environment data 120 and the emitted broadband sonic ray data 116, the ray tracing-based energy transport engine 118 may track the propagation of the set of emitted rays (e.g., ER₁ and ER₂) through the simulation environment, and track the resulting rays reflected rays from objects 330 that are received back at the USS receivers 320 as contribution rays (e.g., as shown by CR₁, CR₂, CR₃, and CR₄). In some embodiments, the ray tracing-based energy transport engine 118 applies vector algebra-based algorithms to compute one or more reflection rays based on, for example, the incident angle of an incoming ray that reflects off the surfaces of objects.

As an illustrative example, FIG. 3 depicts a set of emitted rays, ER₁ and ER₂, generated by the ray preparation stage 112 and launched into the simulation environment 300 by the simulation USS emitter 310. For each of the set of emitted rays, ER₁ and ER₂, the ray preparation stage 112 instantiates a broadband ray data structure 200 including ray emission data 202 such as a USS signal frequency (F), an initial energy (IE), and an emission time that the ray was transmitted. As shown in FIG. 3, a first emitted ray, ER₁, is launched with a frequency F and initial energy (IE1). The ray tracing-based energy transport engine 118 computes that ER₁ propagates away from simulation USS emitter 310 and towards object 330-1, and reflects from the surface 332-1 of object 330-1 as a scattered plurality of rays that include a first contribution ray (CR₁) received at the simulation USS receiver 320-1 and a second contribution ray (CR₂) received at the simulation USS receiver 320-2. Similarly, the ray tracing-based energy transport engine 118 computes that ER₂ propagates away from simulation USS emitter 310 and towards object 330-2, and reflects from the surface 332-2 of object 330-2 as a scattered plurality of rays that include a third contribution ray (CR₃) received at the simulation USS receiver 320-1 and a fourth contribution ray (CR₄) received at the simulation USS receiver 320-2.

For one or more (e.g., each) of the contribution rays, the ray tracing-based energy transport engine 118 produces an associated broadband ray data structure 200 that includes the ray emission data 202, and further populates the broadband ray data structure 200 with one or more items of energy propagation data 204 that may be computed based on the length (e.g., distance and/or duration) of the propagation paths and one or more object incidences experienced by a contribution ray between the USS transmitter 310 and a receiver 320.

In this example, considering the contribution rays CR₁ and CR₃ received at the first USS receiver 320-1, the contribution ray CR₁ originates from a parent emitted ray, ER₁, having an initial energy IE₁. The ray tracing-based energy transport engine 118 may compute energy propagation data 204 corresponding to the component of energy of ER₁ that is received at USS receiver 320-1 as contribution ray CR₁. The ray tracing-based energy transport engine 118 may compute, for example, a total propagation time 216 associated with the energy received with contribution ray CR₁ (e.g., a sum of the propagation time t₁ between the USS transmitter 310 and object 330-1, and the propagation time t₃ between the object 330-1 and USS receiver 320-1). Based on the total propagation time, the ray tracing-based energy transport engine 118 may apply the atmospheric attenuation coefficient to the initial energy IE₁ to compute an atmospheric attenuation 220 that represents the decrease in sonic energy from the initial energy IE₁ caused by atmospheric losses. The ray tracing-based energy transport engine 118 may compute an interaction attenuation 222 based on the incident attenuation coefficient (IC) for at least one of one or more objects that the energy received with contribution ray CR₁ has been reflected from. The ray tracing-based energy transport engine 118 may apply the one or more ICs to the initial energy IE₁ to compute an interaction attenuation 222 that represents the decrease in sonic energy from the initial energy IE₁ caused by incident attenuation incurred due to reflections. Because the amount of a ray's sonic energy reflected by the surface of an object may vary depending on the frequency of the sonic energy, in some embodiments an interaction attenuation 222 may be computed both as a function of the incident attenuation coefficient (IC) of the surface and the frequency (F) of the incoming ray. In some embodiments, the ray tracing-based energy transport engine 118 may record a reflection count 218 indicating the number of reflections experienced by a contribution ray (CR). The resulting contribution energy (CE₁) 224 of the contribution ray CR₁ may thus be computed by the ray tracing-based energy transport engine 118 based on subtracting the total atmospheric attenuation 220 and interaction attenuation 222 for CR₁ from the initial energy IE₁.

Similarly, the contribution ray CR₃ originates from a parent emitted ray ER₂ having an initial energy IE₂. The ray tracing-based energy transport engine 118 may compute energy propagation data 204 corresponding to the component of energy of ER₂ that is received at USS receiver 320-1 as contribution ray CR₃. The ray tracing-based energy transport engine 118 may compute, for example, a total propagation time 216 associated with the energy received with contribution ray CR₃ (e.g., a sum of the propagation time t₂ between the USS transmitter 310 and object 330-2, and the propagation time t₄ between the object 330-2 and USS receiver 320-1). Based on the total propagation time, the ray tracing-based energy transport engine 118 may apply the atmospheric attenuation coefficient to the initial energy IE₂ to compute an atmospheric attenuation 220 that represents the decrease in sonic energy from the initial energy IE₂ caused by atmospheric losses. The ray tracing-based energy transport engine 118 may compute an interaction attenuation 222 based on the incident attenuation coefficient (IC) for each of one or more objects that the energy received with contribution ray CR₃ has been reflected from. The ray tracing-based energy transport engine 118 may apply the one or more ICs to the initial energy IE₂ to compute an interaction attenuation 222 that represents the decrease in sonic energy from the initial energy IE₂ caused by incident attenuation incurred due to reflections. In some embodiments the interaction attenuation 222 may be computed both as a function of the incident attenuation coefficient (IC) of the surface and the frequency (F) of the incoming ray. The resulting contribution energy (CE₃) 224 of the contribution ray CR₃ may thus be computed by the ray tracing-based energy transport engine 118 based on subtracting the total atmospheric attenuation 220 and interaction attenuation 222 for CR₃ from the initial energy IE₂.

Next, considering the contribution rays CR₂ and CR₄ received at the second USS receiver 320-2, the contribution ray CR₂ originates from a parent emitted ray ER₁ having an initial energy IE₁. The ray tracing-based energy transport engine 118 may compute energy propagation data 204 corresponding to the component of energy of ER₁ that is received at USS receiver 320-2 as contribution ray CR₂. The ray tracing-based energy transport engine 118 may compute, for example, a total propagation time 216 associated with the energy received with contribution ray CR₂ (e.g., a sum of the propagation time t₁ between the USS transmitter 310 and object 330-1, and the propagation time t₅ between the object 330-1 and USS receiver 320-2). Based on the total propagation time, the ray tracing-based energy transport engine 118 may apply the atmospheric attenuation coefficient to the initial energy IE₁ to compute an atmospheric attenuation 220 that represents the decrease in sonic energy from the initial energy IE₁ caused by atmospheric losses. The ray tracing-based energy transport engine 118 may compute an interaction attenuation 222 based on the incident attenuation coefficient (IC) for one, some, or all, of one or more objects that the energy received with contribution ray CR₂ has been reflected from. The ray tracing-based energy transport engine 118 may apply the one or more ICs to the initial energy IE₁ to compute an interaction attenuation 222 that represents the decrease in sonic energy from the initial energy IE₁ caused by incident attenuation incurred due to reflections. An interaction attenuation 222 may be computed both as a function of the incident attenuation coefficient (IC) of the surface and the frequency (F) of the incoming ray. The resulting contribution energy (CE₂) 224 of the contribution ray CR₂ may thus be computed by the ray tracing-based energy transport engine 118 based on subtracting the total atmospheric attenuation 220 and interaction attenuation 222 for CR₂ from the initial energy IE₁.

Similarly, the contribution ray CR₄ originates from a parent emitted ray ER₂ having an initial energy IE₂. The ray tracing-based energy transport engine 118 may compute energy propagation data 204 corresponding to the component of energy of ER₂ that is received at USS receiver 320-2 as contribution ray CR₄. The ray tracing-based energy transport engine 118 may compute, for example, a total propagation time 216 associated with the energy received with contribution ray CR₄ (e.g., a sum of the propagation time t₂ between the USS transmitter 310 and object 330-2, and the propagation time t₆ between the object 330-2 and USS receiver 320-2). Based on the total propagation time, the ray tracing-based energy transport engine 118 may apply the atmospheric attenuation coefficient to the initial energy IE₂ to compute an atmospheric attenuation 220 that represents the decrease in sonic energy from the initial energy IE₂ caused by atmospheric losses. The ray tracing-based energy transport engine 118 may compute an interaction attenuation 222 based on the incident attenuation coefficient (IC) for each of one or more objects that the energy received with contribution ray CR₄ has been reflected from. The ray tracing-based energy transport engine 118 may apply the one or more ICs to the initial energy IE₂ to compute an interaction attenuation 222 that represents the decrease in sonic energy from the initial energy IE₂ caused by incident attenuation incurred due to reflections. In some embodiments the interaction attenuation 222 may be computed both as a function of the incident attenuation coefficient (IC) of the surface and the frequency (F) of the incoming ray. The resulting contribution energy (CE₄) 224 of the contribution ray CR₄ may thus be computed by the ray tracing-based energy transport engine 118 based on subtracting the total atmospheric attenuation 220 and interaction attenuation 222 from the initial energy IE₂.

It should be understood that FIG. 3 provides a simplified example, and that in various embodiments, the set of emitted rays prepared by ray preparation stage 112 and launched into the simulation environment 300 by the simulation USS emitter 310 may include many thousands of emitted rays (ER), and that the simulation environment 300 may comprise many hundreds of objects 330 that produce reflections resulting in many thousands of contribution rays (CR) being received at the one or more USS receivers 320.

Returning to FIG. 1, based on the contribution energies of contribution rays received by the one or more USS receivers 320, the ray tracing-based energy transport engine 118 outputs contribution ray data 122 to the contribution ray processing stage 124. In some embodiments, the contribution ray data 122 may include the contribution energy, and/or one or more other items of data derived from the broadband ray data structure 200, for the contribution rays (CRs) being received at the one or more USS receivers 320. For example, in some embodiments, the contribution ray processing stage 124 may generate a contribution list (shown at 330 in FIG. 3) representing the contribution energy (CE) and/or other characteristics of a set of contribution rays received at that USS receiver 320. For the simplified example of FIG. 3, the contribution list 335 for USS receiver 320-1 may include the contribution rays CR₁ and CR₃, and the contribution list 335 for USS receiver 320-2 may include contribution rays CR₂ and CR₄.

Based on the contribution energy (CE) and/or other parameters embedded in the broadband ray data structure 200 the contribution ray processing stage 124 may assemble one or more acoustic wave envelopes representing a time-dependent gain function resulting from the aggregation of the contributions resulting from the emitted rays (ERs). The resulting waveforms may be output from the USS array simulation model 110 as USS measurement data 126—representing measurement data that may be used to simulate USS vehicle sensor inputs to other systems and virtual driving environments, including but not limited to hardware-in-the-loop simulations. USS measurement data 126 may then be used as an input to one or more systems, such as ego-machine perception and control systems 128, to navigate or otherwise operate the ego machine within the simulation environment—based on which the scene rendering engine 131 may update the rendered environment data 120.

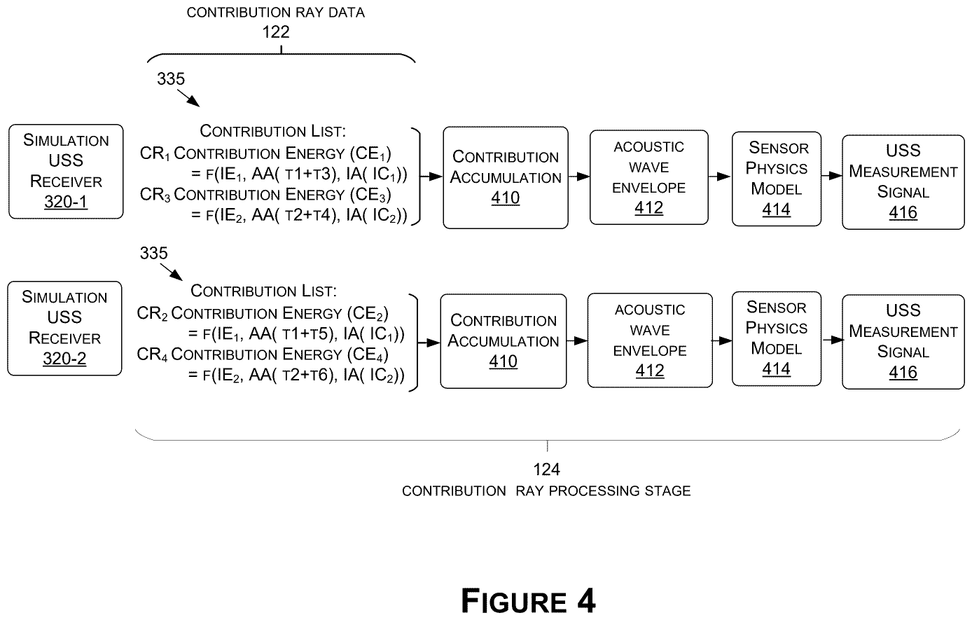

FIG. 4 provides an example data flow diagram illustrating the generation of USS measurement data 126 based on the contribution list 335 collected at each USS receiver 320 in response to the set of emitted rays (e.g., ER₁ and ER₂) prepared by the ray preparation stage 112 and propagated by the ray tracing-based energy transport engine 118. In some embodiments, the contribution ray processing stage 124 performs a contribution accumulation 410 based on the contribution list 335 collected at a USS receiver 320 to compute an acoustic wave envelope 412. As previously discussed, an ultrasonic sensor typically comprises a piezoelectric material membrane that receives reflections of the acoustic energy of a set of emitted rays in the form of contribution energies. The energies from those various contribution energies cause the membrane to vibrate in a distinct time-dependent pattern that is indicative of the time delay and energy levels of the various reflections as they interact with the membrane. In some embodiments, the contribution ray processing stage 124 accumulates the contribution energies received at a USS receiver 320 and constructs the acoustic wave envelope 412 representing an output waveform based on assigning each computed contribution energy to represent a component of the output waveform, and performing an energy summation over time by taking into account, for example, the contribution energy of each received contribution ray, the relative timing of each contribution ray as received at the USS receiver 320, and/or the frequency data for the set of emitted rays. The contribution ray processing stage 124 may apply the acoustic wave envelope 412 to a sensor physics model 414 that models the response of the membrane for that USS receiver 320 to an input waveform stimulus. That is, the sensor physics model 414 inputs the acoustic wave envelope 412 and computes an estimated representation of the electrical signal that would be produced by the USS receiver due to vibrations of the membrane caused by the acoustic wave envelope 412. The estimated electrical signal may be provided as a USS measurement signal 416 output, and the USS measurement data 126 may comprise, or be derived from, the USS measurement signal 416 from one or more of the USS receivers 320 that receive the contribution rays. The contribution ray processing stage therefore processes the aggregation of contribution energies based on a model that mimics a membrane vibration response to the reception of the contribution energies. In some embodiments, the USS measurement data 126 may comprise the individual USS measurement signals 416 computed for the distinct USS receivers 320. In some embodiments, the USS measurement data 126 may be computed from a set of individual USS measurement signals 416, for example by computing an aggregate acoustic wave envelope based on the known differences in positions between the USS receivers 320 and contribution ray propagation differences resulting from those differences in positions—to thus simulate a USS sensor comprising an array of USS receivers 320. In some embodiments, the contribution ray processing stage 124 may introduce noise to USS measurement signals 416, for example to simulate known device-specific characteristics and/or external noises. As an example, to produce a more realistic sensor output signal, the contribution ray processing stage 124 includes a thermal noise component that mimics thermal noise found in output signals from physical USS sensors and/or that mimics electromagnetic interference (EMI) in an electrical path picked up from an outside source. The USS measurement data 126 may be supplied as USS sensor data input to perception systems of an ego-machine simulation operating within the simulation environment—for example to determine the distance and/or position of objects within a proximity of the ego machine and used to assist in navigating the ego machine, for example, into or out of a parking space.

In some embodiments, the simulation platform 100 may generate a runtime simulation output 140, which may comprise a visual rendering of a scene and/or results of physical simulations of interactions between rigid bodies within the simulated environment. The runtime simulation output 140 may be displayed to a human-machine interface (HMI) 142 (e.g., a display screen) and/or output for subsequent processing. For example, runtime simulation outputs 140 from a simulated environment may be used in the process of training and/or validating machine learning models that are used to operate ego machines such as, but not limited to, autonomous and semi-autonomous vehicles (e.g., ego machine 800). For example, the simulation processor 130 may output runtime simulation output 140 for use as synthetic image data for training an ego machine (e.g., ego machine 800) that is using the simulation platform 100 to provide a simulated driving environment for training and/or testing components of the ego machine.

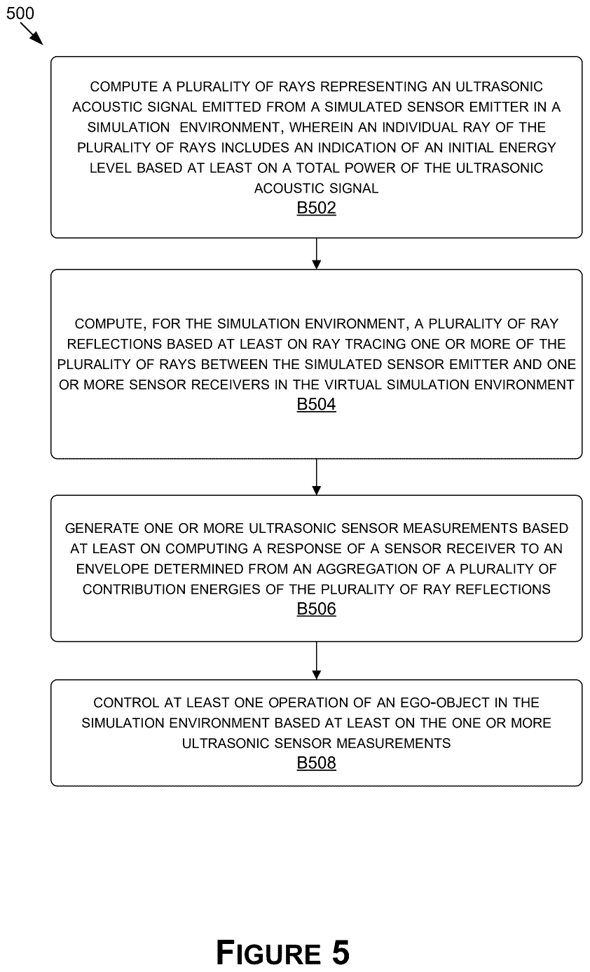

FIG. 5 is a flow diagram illustrating an example method for an ultrasonic sensor (USS) array simulation, in accordance with some embodiments of the present disclosure. It should be understood that the features and elements described herein with respect to the method 500 of FIG. 5 may be used in conjunction with, in combination with, or substituted for elements of any of the other embodiments discussed herein and vice versa. Further, it should be understood that the functions, structures, and other descriptions of elements for embodiments described in FIG. 5 may apply to like or similarly named or described elements across any of the figures and/or embodiments described herein and vice versa.

Each block of method 500, described herein, comprises a computing process that may be performed using any combination of hardware, firmware, and/or software. For instance, various functions may be carried out by a processor executing instructions stored in memory. The methods may also be embodied as computer-usable instructions stored on computer storage media. The methods may be provided by a standalone application, a service or hosted service (standalone or in combination with another hosted service), or a plug-in to another product, to name a few. In addition, method 500 is described, by way of example, with respect to the simulation platform 100 of FIG. 1. However, these methods may additionally or alternatively be executed by any one system, or any combination of systems, including, but not limited to, those described herein.

As discussed herein in greater detail, the method may include generating one or more output signals representing one or more ultrasonic sensor measurements based at least on computing a vibrational response of a sensor receiver to an acoustic wave envelope, wherein the acoustic wave envelope is determined based at least on aggregating a plurality of contribution energies, the plurality of contribution energies computed based at least on ray tracing a plurality of rays representing a sampling of a wave front of an ultrasonic acoustic signal emitted from a sensor emitter. In some embodiments, a method may include ray tracing a plurality of rays representing an ultrasonic acoustic signal emitted from a sensor emitter in a simulated environment, computing an aggregate contribution energy based at least on the ray-traced plurality of rays, computing an acoustic wave envelope based at least on the aggregate contribution energy, computing a vibrational response of a sensor receiver to the acoustic wave envelope, generating one or more output signals representing one or more simulated ultrasonic sensor measurements based at least on the vibrational response; and controlling an operation of a simulated ego-object in the simulated environment based at least on the one or more output signals.

The method 500, at block B502, includes computing a plurality of rays representing an ultrasonic acoustic signal emitted from a simulated sensor emitter in a simulation environment, wherein an individual ray of the plurality of rays includes an indication of an initial energy level based at least on a total power of the ultrasonic acoustic signal. The method may include computing the plurality of rays based at least on one or more input parameters, the one or more input parameters comprising at least one of: a ray density, a pulse power of the ultrasonic acoustic signal, and a gain pattern representing a membrane directivity or the sensor emitter. For example, as shown in FIG. 1, in some embodiments, USS array simulation model 110 may comprise a ray preparation stage 112, a ray tracing-based energy transport engine 118, and a contribution ray processing stage.

The ray preparation stage 112 generates emitted broadband sonic ray data 116 (representing a set of USS emissions rays) based on sonic emission parameters 114 that characterize the sonic emissions of a physical sensor device that the USS array simulation model 110 is simulating. The ray preparation stage 112 takes sonic emission parameters 114, such as but not limited to ray density, pulse power, and/or membrane directivity, in order to prepare a set of rays that represent a sampling of a wave front of an emitted wave transmitted by an ultrasonic sensor. Sonic emission parameters 114 may be based, for example, on characteristics such as a shape and/or directivity of the membrane, and/or a gain/radiation pattern associated with emissions from a physical USS being modeled by the USS array simulation model 110. The ray preparation stage 112 may assign an initial energy level to each ray of the broadband sonic ray data 116 that is a fraction of the total pulse power parameter, as determined based on the gain pattern.

The method 500, at block B504, includes computing, for the simulation environment, a plurality of ray reflections based at least on ray tracing one or more of the plurality of rays between the simulated sensor emitter and one or more sensor receivers in the virtual simulation environment. An individual ray reflection of the plurality of ray reflections may define a contribution ray having a contribution energy determined based on an attenuation of the initial energy level. In some embodiments, the method may compute an acoustic wave contribution energy associated with one or more ray reflections, the one or more ray reflections determined based at least on a ray tracing of one or more of a plurality of rays through a simulation environment between a sensor emitter and one or more sensor receivers. In some embodiments, the ray tracing of the one or more of the plurality of rays through the simulation environment may be computed based at least on a ray tracing-based energy transport engine that models sound wave reflections from one or more objects in the simulation environment. For example, the tracking of rays that propagate between a USS emitter and one or more USS receivers of the USS simulation may be performed using the ray tracing-based energy transport engine 118 based at least on the broadband sonic ray data 116, as illustrated in FIG. 3. Based on the location of the simulated USS emitter within the simulation environment, and the location of one or more USS receivers in the simulation environment, the ray tracing-based energy transport engine 118 processes the broadband sonic ray data 116 to compute contribution ray data 122. The ray tracing-based energy transport engine 118 may compute the trajectory of individual rays based on the location and translation of the simulated USS emitter and the offset of the individual ray from the main axis of the emitter, and computes a resulting set of reflections from that individual ray generated by interactions with one or more objects in the simulation environment. Reflected rays that are reflected to the location of a USS receiver are used to define contribution ray data 122. Based on the rendered environment data 120 and the emitted broadband sonic ray data 116, the ray tracing-based energy transport engine 118 may track the propagation of the set of emitted rays (e.g., ER₁ and ER₂) through the simulation environment, and track the resulting rays reflected rays from objects 330 that are received back at the USS receivers 320 as contribution rays (e.g., as shown by CR₁, CR₂, CR₃, and CR₄). In some embodiments, the ray tracing-based energy transport engine 118 applies vector algebra-based algorithms to compute one or more reflection rays based on, for example, the incident angle of an incoming ray that reflects off the surfaces of objects. In some embodiments, a total propagation associated with the contribution ray may be determined based on a total propagation time determined based at least on the ray tracing, and an atmospheric attenuation component of the attenuation computed based at least on a function of the total propagation distance and an atmospheric attenuation coefficient. The method may determine one or more object interaction attenuations for one or more object interactions associated with the contribution based at least on the ray tracing, and may compute an object interaction attenuation component of the attenuation based at least on an accumulation of the one or more object interaction attenuations. The one or more object interaction attenuations may be computed based at least on one or more material characteristics of one or more objects associated with the one or more object interactions and the indication of the frequency of the ultrasonic acoustic signal. In some embodiments, the simulation environment may include a plurality of USS devices that may be selectively configured into different sets of available simulated USS emitters and receivers. The simulation platform 100 may selectively define the sensor emitter and the one or more sensor receivers based at least on selecting a configuration of a set of ultrasonic sensor devices from the available simulated USS emitters and receivers that are to be simulated using the USS array simulation model 110.

The method 500, at block B506, includes generating one or more ultrasonic sensor measurements based at least on computing a response of a sensor receiver to an envelope determined from an aggregation of a plurality of contribution energies of the plurality of ray reflections. The method may comprise, for example, generating one or more ultrasonic sensor measurement output signals based at least on computing a vibrational response to an acoustic wave envelope determined from an aggregation of the acoustic wave contribution energy from individual ray reflections of the one or more ray reflections. The acoustic wave envelope may be determined using a time-dependent gain function computed from the aggregation. For example, in some embodiments, the contribution ray processing stage 124 accumulates the contribution energies received at a USS receiver 320 and constructs the acoustic wave envelope 412 representing an output waveform based on assigning each computed contribution energy to represent a component of the output waveform, and performing an energy summation over time by taking into account, for example, the contribution energy of each received contribution ray, the relative timing of each contribution ray as received at the USS receiver 320, and/or the frequency data for the set of emitted rays. The contribution ray processing stage 124 may apply the acoustic wave envelope 412 to a sensor physics model 414 that models the response of the membrane for that USS receiver 320 to an input waveform stimulus. That is, the sensor physics model 414 inputs the acoustic wave envelope 412 and computes an estimated representation of the electrical signal that would be produced by the USS receiver due to vibrations of the membrane caused by the acoustic wave envelope 412.

The ray tracing for the plurality of rays may be computed based on parallel processing of individual contributions to construct the acoustic wave envelope. In some embodiments, a bounding volume hierarchy (BVH) may be applied to interpolate ray positions for the ray tracing of the one or more of the plurality of rays. As such, in some embodiments, one or more operations of the pre-firing ray preparation, ray tracing-based energy transport, and/or contribution ray processing stage contribution processing may be executed by the simulation platform using parallel computing techniques, GPU acceleration, and/or similar techniques where large sets of individual contributions may be processed in parallel to construct the acoustic wave envelope associated with each of the one or more USS receivers. In some embodiments, for example, ray tracing-based energy transport and contribution ray processing stage contribution processing may be implemented using NVIDIA RTX™ ray-tracing and neural-rendering technologies. Embodiments may apply a bounding volume hierarchy (BVH)-based process (e.g., a hierarchical grouping of 3D objects, where each group is associated with a conservative bounding box) to interpolate ray positions during ray tracing to determine the contributions that reach a particular USS receiver. In some embodiments, the ultrasonic sensor array simulation model may simulate sensor crosstalk techniques by receiving contributions from a set of emitted rays at multiple simulated USS receivers, and use waveform reconstruction to produce a USS measurement data output from each simulated USS receiver. The perception systems executed within the simulation environment may then apply those sensor crosstalk techniques using the measurement data output from each simulated USS receiver to more accurately determine the position of objects within the simulation environments. The array may be reconfigurable by the simulation platform so that different configurations may define which devices operate as USS emitters and which operate as USS receivers.

The method 500, at block B508, includes controlling at least one operation of an ego-object in the simulation environment based at least on the one or more ultrasonic sensor measurements. As discussed herein, ultrasonic sensor measurements (e.g., USS measurement data 126) may be used as an input to one or more systems (e.g., ego-machine perception and control systems 128) to navigate or otherwise operate the ego machine within the simulation environment. In some embodiments, USS measurement data 126 and/or runtime simulation outputs 140 based on USS measurement data 126 may be used in the process of training and/or validating machine learning models that are used to operate ego machines such as, but not limited to, vehicle 800. For example, the USS array simulation model 110 may output USS measurement data 126 for use as synthetic USS data for one or more USS sensors of an ego machine (such as vehicle 800 described with respect to FIGS. 8A-8D) that is using the simulation platform 100 to provide a simulated driving environment for training and/or testing components of the ego machine.

In some embodiments, the systems and methods described herein may be performed within, or in conjunction with, a simulation environment (e.g., NVIDIA's DriveSIM) using simulated data (e.g., simulated sensor data of simulated sensors of a virtual or simulated machine). For example, simulated sensor data and/or map data may be used that includes the application of realistic road surface renderings to road surfaces within the simulation environment, and may use this information to perform operations (e.g., navigating) associated with the virtual machine within the environment. These simulated operations may be used to test performance of the underlying algorithms, systems, and/or processes prior to deploying them in the real world. In some instances, the simulation may be used to generate synthetic training data—e.g., training data including regions of interest and/or subregions of interest from within the simulation. The synthetic training data (in addition to or alternatively from real-world data) may then be processed to determine geometry and/or other information related to road surfaces, for example. In any example, such as where a simulation environment is used for testing, validation, training, etc., the simulation environment and/or associated training data may be rendered or otherwise generated using one or more light transport algorithms and/or sound transport algorithms—such as ray-tracing and/or path-tracing algorithms. In some embodiments, the simulation environment and/or one or more objects, features, or components thereof may be generated or managed within a three-dimensional (3D) content collaboration platform (e.g., NVIDIA's Omniverse) for industrial digitalization, generative physical artificial intellegence (AI), and/or other use cases, applications, or services. For example, the content collaboration platform or system may include a system for using or developing universal scene descriptor (USD) (e.g., OpenUSD) data for managing objects, features, scenes, etc., within a simulated environment, digital environment, etc. The platform may include real physics simulation, such as using NVIDIA's PhysX SDK, in order to simulate real physics and physical interactions with simulations hosted by the platform. The platform may integrate OpenUSD along with ray tracing/path tracing/sound transport simulation/light transport simulation (e.g., NVIDIA's RTX rendering technologies) into software tools and simulation workflows for building, training, deploying, or testing AI systems—such as systems for testing, validating, training (e.g., machine learning models, neural networks, etc.), and/or other tasks related to automotive, robot, machine, or other applications.

The systems and methods described herein may be used by, without limitation, non-autonomous vehicles, semi-autonomous vehicles (e.g., in one or more adaptive driver assistance systems (ADAS)), piloted and un-piloted robots or robotic platforms, warehouse vehicles, off-road vehicles, vehicles coupled to one or more trailers, flying vessels, boats, shuttles, emergency response vehicles, motorcycles, electric or motorized bicycles, aircraft, construction vehicles, trains, underwater craft, remotely operated vehicles such as drones, and/or other vehicle types. Further, the systems and methods described herein may be used for a variety of purposes, by way of example and without limitation, for machine control, machine locomotion, machine driving, synthetic data generation, model training, perception, augmented reality, virtual reality, mixed reality, robotics, security and surveillance, simulation and digital twinning, autonomous or semi-autonomous machine applications, deep learning, environment simulation, object or actor simulation and/or digital twinning, data center processing, conversational AI, light transport simulation and/or sound transport simulation (e.g., ray-tracing, path tracing, etc.), collaborative content creation for 3D assets, cloud computing, generative AI, and/or any other suitable applications.

Disclosed embodiments may be comprised in a variety of different systems such as automotive systems (e.g., a control system for an autonomous or semi-autonomous machine, a perception system for an autonomous or semi-autonomous machine), systems implemented using a robot, aerial systems, medial systems, boating systems, smart area monitoring systems, systems for performing deep learning operations, systems for performing simulation operations, systems for performing digital twin operations, systems implemented using an edge device, systems incorporating one or more virtual machines (VMs), systems for performing synthetic data generation operations, systems implemented at least partially in a data center, systems for performing conversational AI operations, systems implementing one or more language models - such as one or more large language models (LLMs) ) and/or one or more vision language models (VLMs), systems for performing light and/or sound transport simulation, systems for performing collaborative content creation for 3D assets, systems implemented at least partially using cloud computing resources, and/or other types of systems.

### Example Simulation System

In some embodiments, the USS measurement data 126 produced by the USS array simulation model 110 may be used as a source of virtual sensor data in a simulated environment to test one or more autonomous or semi-autonomous driving software stacks. For example, the simulation system 600—e.g., represented by simulation systems 600A, 600B, 600C, and 600D in FIGS. 6A-D, and described in more detail below—may generate a global simulation that simulates a virtual world or environment (e.g., a simulated environment) that may include artificial intelligence (AI) vehicles or other objects (e.g., pedestrians, animals, etc.), hardware-in-the-loop (HIL) vehicles or other objects, software-in-the-loop (SIL) vehicles or other objects, and/or person-in-the-loop (PIL) vehicles or other objects. The simulation platform 100 and/or simulation processor 130 may be implemented at least in part based on simulation system 600. The global simulation may be maintained within an engine (e.g., a game engine), or other software-development environment, that may include a rendering engine (e.g., for 2D and/or 3D graphics), a physics engine (e.g., for collision detection, collision response, etc.), sound, scripting, animation, AI, networking, streaming, memory management, threading, localization support, scene graphs, cinematics, and/or other features. In some examples, as described herein, one or more vehicles or objects within the simulation system 600 (e.g., HIL objects, SIL objects, PIL objects, AI objects, etc.) may be maintained within their own instance of the engine. In such examples, a virtual sensor for each virtual object may include its own instance of the engine (e.g., an instance for a virtual camera, a second instance for a virtual LIDAR sensor, a third instance for another virtual LIDAR sensor, etc.). As such, an instance of the engine may be used for processing sensor data for each virtual sensor with respect to the virtual sensor's perception of the global simulation. As such, for a virtual camera, the instance may be used for processing image data with respect to the virtual camera's field of view in the simulated environment. As another example, for a virtual IMU sensor, the instance may be used for processing IMU data (e.g., representative of orientation) for the object in the simulated environment.

AI controlled agents or other objects within the simulation may include pedestrians, animals, third-party vehicles, vehicles, and/or other object types. The agents executed within the simulated environment may be controlled using artificial intelligence (e.g., machine learning such as neural networks, rules-based control, a combination thereof, etc.) in a way that simulates, or emulates, how corresponding real-world objects would behave. In some examples, the rules, or actions, for agents may be learned from one or more HIL objects, SIL objects, and/or PIL objects. In an example where an agent in the simulated environment corresponds to a pedestrian, the bot may be trained to act like a pedestrian in any of a number of different situations or environments (e.g., running, walking, jogging, not paying attention, on the phone, raining, snowing, in a city, in a suburban area, in a rural community, etc.). As such, when the simulated environment is used for testing vehicle performance (e.g., for HIL or SIL embodiments), the bot (e.g., the pedestrian) may behave as a real-world pedestrian would (e.g., by jaywalking in rainy or dark conditions, failing to heed stop signs or traffic lights, etc.), in order to more accurately simulate a real-world environment. This method may be used for any agent in the simulated environment, such as vehicles, bicyclists, or motorcycles, whose agents may also be trained to behave as real-world objects would (e.g., weaving in and out of traffic, swerving, changing lanes with no signal or suddenly, braking unexpectedly, etc.).

The AI objects that may be distant from the vehicle of interest (e.g., the ego-vehicle in the simulated environment) may be represented in a simplified form—such as a radial distance function, or list of points at known positions in a plane, with associated instantaneous motion vectors. As such, the AI objects may be modeled similarly to how AI agents may be modeled in videogame engines.

HIL vehicles or objects may use hardware that is used in the physical vehicles or objects to at least assist in some of the control of the HIL vehicles or objects in the simulated environment. For example, a vehicle controlled in a HIL environment may use one or more SoCs 804 (FIG. 8C), CPU(s) 818, GPU(s) 820, etc., in a data flow loop for controlling the vehicle in the simulated environment. In some examples, the hardware from the vehicles may be an NVIDIA DRIVE AGX Pegasus™ compute platform and/or an NVIDIA DRIVE PX Xavier™ compute platform. For example, the vehicle hardware (e.g., vehicle hardware 601) may include some or all of the components and/or functionality described in U.S. Non-Provisional Ser. No. 16/186,473, filed on Nov. 9, 2018, which is hereby incorporated by reference in its entirety. In such examples, at least some of the control decisions may be generated using the hardware that is configured for installation within a real-world autonomous vehicle (e.g., the vehicle 800) to execute at least a portion of a software stack(s) 603 (e.g., an autonomous driving software stack).

SIL vehicles or objects may use software to simulate or emulate the hardware from the HIL vehicles or objects. For example, instead of using the actual hardware that may be configured for use in physical vehicles (e.g., the vehicle 800), software, hardware, or a combination thereof may be used to simulate or emulate the actual hardware (e.g., simulate the SoC(s) 605).

PIL vehicles or objects may use one or more hardware components that allow a remote operator (e.g., a human, a robot, etc.) to control the PIL vehicle or object within the simulated environment. For example, a person or robot may control the PIL vehicle using a remote control system (e.g., including one or more pedals, a steering wheel, a VR system, etc.), such as the remote control system described in U.S. Non-Provisional Ser. No. 16/366,506 , filed on Mar. 27, 2019, and hereby incorporated by reference in its entirety. In some examples, the remote operator may control autonomous driving level 0, 1, or 2 (e.g., according to the Society of Automotive Engineers document J3016) virtual vehicles using a VR headset and a CPU(s) (e.g., an X86 processor), a GPU(s), or a combination thereof. In other examples, the remote operator may control advanced AI-assisted level 2, 3, or 4 vehicles modeled using one or more advanced SoC platforms. In some examples, the PIL vehicles or objects may be recorded and/or tracked, and the recordings and/or tracking data may be used to train or otherwise at least partially contribute to the control of AI objects, such as those described herein.

Now referring to FIG. 6A, FIG. 6A is an example illustration of a simulation system 600A, in accordance with some embodiments of the present disclosure. The simulation system 600A may generate a simulated environment 610 (e.g., a simulated driving environment, such as but not limited to the simulation environment 300 discussed herein) that may include agents such as AI objects 612 (e.g., AI objects 612A and 612B), HIL objects 614, SIL objects 616, PIL objects 618, and/or other object types. The simulated environment 610 may include features of a driving environment, such as roads, bridges, tunnels, street signs, stop lights, crosswalks, buildings, trees and foliage, the sun, the moon, reflections, shadows, etc., in an effort to simulate a real-world environment accurately within the simulated environment 610. In some examples, the features of the driving environment within the simulated environment 610 may be more true-to-life by including chips, paint, graffiti, wear and tear, damage, etc. Although described with respect to a driving environment, this is not intended to be limiting, and the simulated environment may include an indoor environment (e.g., for a robot, a drone, etc.), an aerial environment (e.g., for a UAV, a drone, an airplane, etc.), an aquatic environment (e.g., for a boat, a ship, a submarine, etc.), and/or another environment type.

The simulated environment 610 may be generated using virtual data, real-world data, or a combination thereof. For example, the simulated environment may include real-world data augmented or changed using virtual data to generate combined data that may be used to simulate certain scenarios or situations with different and/or added elements (e.g., additional AI objects, environmental features, weather conditions, etc.). For example, pre-recorded video may be augmented or changed to include additional pedestrians, obstacles, and/or the like, such that the virtual objects (e.g., executing the software stack(s) 603 as HIL objects and/or SIL objects) may be tested against variations in the real-world data.

The simulated environment may be generated using rasterization, ray-tracing, using DNNs such as generative adversarial networks (GANs), another rendering technique, and/or a combination thereof. For example, in order to create more true-to-life, realistic lighting conditions (e.g., shadows, reflections, glare, global illumination, ambient occlusion, etc.), the simulation system 600A may use real-time ray-tracing. In one or more embodiments, one or more hardware accelerators may be used by the simulation system 600A to perform real-time ray-tracing. The ray-tracing may be used to simulate LIDAR sensor for accurate generation of LIDAR data. For example, ray casting may be used in an effort to simulate LIDAR reflectivity. In another example, virtual LIDAR data may be generated using a learned sensor model, as described in more detail above. In any example, ray-tracing techniques used by the simulation system 600A may include one or more techniques described in U.S. Provisional Patent Application No. 62/644,385, filed Mar. 17, 2018, U.S. Provisional Ser. No. 62/644,386 , filed Mar. 17, 2018, U.S. Provisional Ser. No. 62/644,601, filed Mar. 19, 2018, and U.S. Provisional Application No. 62/644,806, filed Mar. 19, 2018, U.S. Non-Provisional Ser. No. 16/354,983, filed on Mar. 15, 2019, and/or U.S. Non-Provisional Ser. No. 16/355,214, filed on Mar. 15, 2019, each of which is hereby incorporated by reference in its entirety.

In some examples, a simulated environment as described herein (e.g., by simulation platform 100) may be rendered, at least in part, using one or more DNNs, such as generative adversarial neural networks (GANs). For example, real-world data may be collected, such as real-world data captured by autonomous vehicles (e.g., camera(s), LIDAR sensor(s), RADAR sensor(s), etc.), robots, and/or other objects, as well as real-world data that may be captured by any sensors (e.g., images or video pulled from data stores, online resources such as search engines, etc.). The real-world data may then be segmented, classified, and/or categorized, such as by labeling differing portions of the real-world data based on class (e.g., for an image of a landscape, portions of the image—such as pixels or groups of pixels—may be labeled as car, sky, tree, road, building, water, waterfall, vehicle, bus, truck, sedan, etc.). A GAN (or other DNN or machine learning model) may then be trained using the segmented, classified, and/or categorized data to generate new versions of the different types of objects, landscapes, and/or other features as graphics within the simulated environment.

The simulator component(s) 602 of the simulation system 600 may communicate with vehicle simulator component(s) 606 over a wired and/or wireless connection. In some examples, the connection may be a wired connection using one or more sensor switches 608, where the sensor switches may provide low-voltage differential signaling (LVDS) output. For example, the sensor data (e.g., image data) may be transmitted over an HDMI to LVDS connection between the simulator component(s) 602 and the vehicle simulator component(s) 606. The simulator component(s) 602 may include any number of compute nodes (e.g., computers, servers, etc.) interconnected in order to ensure synchronization of the world state. In some examples, as described herein, the communication between each of the compute nodes (e.g., the vehicle simulator component(s) compute nodes and the simulator component(s) compute nodes) may be managed by a distributed shared memory (DSM) system (e.g., DSM 624 of FIG. 6C) using a distributed shared memory protocol (e.g., a coherence protocol). The DSM may include a combination of hardware (cache coherence circuits, network interfaces, etc.) and software. This shared memory architecture may separate memory into shared parts distributed among nodes and main memory, or distributing all memory between all nodes. In some examples, InfiniBand (IB) interfaces and associated communications standards may be used. For example, the communication between and among different nodes of the simulation system 600 (and/or 700) may use IB.

The simulator component(s) 602 may include one or more GPUs 604. The virtual vehicle being simulated may include any number of sensors (e.g., virtual or simulated sensors) that may correspond to one or more of the sensors described herein at least with respect to FIGS. 8A-8C. Any or all of the sensors of the simulator component(s) 602 may be implemented using a corresponding learned sensor model, as described in more detail above. In some examples, each sensor of the vehicle may correspond to, or be hosted by, one of the GPUs 604. For example, processing for a LIDAR sensor may be executed on a first GPU 604, processing for a wide-view camera may be executed on a second GPU 604, processing for a RADAR sensor may be executed on a third GPU, and so on. As such, the processing of each sensor with respect to the simulated environment may be capable of executing in parallel with each other sensor using a plurality of GPUs 604 to enable real-time simulation. In other examples, two or more sensors may correspond to, or be hosted by, one of the GPUs 604. In such examples, the two or more sensors may be processed by separate threads on the GPU 604 and may be processed in parallel. In other examples, the processing for a single sensor may be distributed across more than one GPU. In addition to, or alternatively from, the GPU(s) 604, one or more TPUs, CPUs, and/or other processor types may be used for processing the sensor data.

Vehicle simulator component(s) 606 may include a compute node of the simulation system 600A that corresponds to a single vehicle represented in the simulated environment 610. Each other vehicle (e.g., 614, 618, 616, etc.) may include a respective node of the simulation system. As a result, the simulation system 600A may be scalable to any number of vehicles or objects as each vehicle or object may be hosted by, or managed by, its own node in the system 600A. In the illustration of FIG. 6A, the vehicle simulator component(s) 606 may correspond to a HIL vehicle (e.g., because the vehicle hardware 601 is used). However, this is not intended to be limiting and, as illustrated in FIGS. 6B and 6C, the simulation system 600 may include SIL vehicles, HIL vehicles, PIL vehicles, and/or AI vehicles. The simulator component(s) 602 (e.g., simulator host device) may include one or more compute nodes of the simulation system 600A, and may host the simulation of the environment with respect to each actor (e.g., with respect to each HIL, SIL, PIL, and AI actors), as well as hosting the rendering and management of the environment or world state (e.g., the road, signs, trees, foliage, sky, sun, lighting, etc.). In some examples, the simulator component(s) 602 may include a server(s) and associated components (e.g., CPU(s), GPU(s), computers, etc.) that may host a simulator (e.g., NVIDIA's DRIVE™ Constellation AV Simulator).

The vehicle hardware 601, as described herein, may correspond to the vehicle hardware that may be used in a physical vehicle 800. However, in the simulation system 600A, the vehicle hardware 601 may be incorporated into the vehicle simulator component(s) 606. As such, because the vehicle hardware 601 may be configured for installation within the vehicle 800, the simulation system 600A may be specifically configured to use the vehicle hardware 601 within a node (e.g., of a server platform) of the simulation system 600A. For example, similar interfaces used in the physical vehicle 800 may need to be used by the vehicle simulator component(s) 606 to communicate with the vehicle hardware 601. In some examples, the interfaces may include: (1) CAN interfaces, including a PCAN adapter, (2) Ethernet interfaces, including RAW UDP sockets with IP address, origin, VLA, and/or source IP all preserved, (3) Serial interfaces, with a USB to serial adapter, (4) camera interfaces, (5) InfiniBand (IB) interfaces, and/or other interface types.

In examples, once the sensor data representative of a field(s) of view of the sensor(s) of the vehicle in the simulated environment has been generated and/or processed (e.g., using one or more codecs, as described herein), the sensor data (and/or encoded sensor data) may be used by the software stack(s) 603 (e.g., the autonomous driving software stack) executed on the vehicle hardware 601 to perform one or more operations (e.g., generate one or more controls, route planning, detecting objects, identifying drivable free-space, monitoring the environment for obstacle avoidance, etc.). As a result, the identical, or substantially identical, hardware components used by the vehicle 800 (e.g., a physical vehicle) to execute the autonomous driving software stack in real-world environments may be used to execute the autonomous driving software stack in the simulated environment 610. The use of the vehicle hardware 601 in the simulation system 600A thus provides for a more accurate simulation of how the vehicle 800 will perform in real-world situations, scenarios, and environments without having to actually find and test the vehicle 800 in the real-world. This may reduce the amount of driving time required for testing the hardware/software combination used in the physical vehicle 800 and may reduce safety risks by not requiring actual real-world testing (especially for dangerous situations, such as other vehicles driving erratically or at unsafe speeds, children playing in the street, ice on a bridge, etc.).

In addition to the vehicle hardware 601, the vehicle simulator component(s) 606 may manage the simulation of the vehicle (or other object) using additional hardware, such as a computer—e.g., an X86 box. In some examples, additional processing for virtual sensors (e.g., learned sensor models) of the virtual object may be executed using the vehicle simulation component(s) 606. In such examples, at least some of the processing may be performed by the simulator component(s) 602, and other of the processing may be executed by the vehicle simulator component(s) 606 (or 620, or 622, as described herein). In other examples, the processing of the virtual sensors may be executed entirely on the vehicle simulator component(s) 606.

Now referring to FIG. 6B, FIG. 6B is another example illustration of a simulation system 600B, in accordance with some embodiments of the present disclosure. The simulation system 600B may include the simulator component(s) 602 (as one or more compute nodes), the vehicle simulator component(s) 606 (as one or more compute nodes) for a HIL object(s), the vehicle simulator component(s) 620 (as one or more compute nodes) for a SIL object(s), the vehicle simulator component(s) 606 (as one or more compute nodes) for a PIL object(s), and/or additional component(s) (or compute nodes) for AI objects and/or other object types. Each of the PIL, HIL, SIL, AI, and/or other object type compute nodes may communicate with the simulator component(s) 602 to capture from the global simulation at least data that corresponds to the respective object within the simulate environment 610.

For example, the vehicle simulator component(s) 622 may receive (e.g., retrieve, obtain, etc.), from the global simulation (e.g., represented by the simulated environment 610) hosted by the simulator component(s) 602, data that corresponds to, is associated with, and/or is required by the vehicle simulator component(s) 622 to perform one or more operations by the vehicle simulator component(s) 622 for the PIL object. In such an example, data (e.g., virtual sensor data corresponding to a field(s) of view of virtual camera(s) of the virtual vehicle, virtual LIDAR data, virtual RADAR data, virtual location data, virtual IMU data, etc.) corresponding to each sensor of the PIL object may be received from the simulator component(s) 602. This data may be used to generate an instance of the simulated environment corresponding to the field of view of a remote operator of the virtual vehicle controlled by the remote operator, and the portion of the simulated environment may be projected on a display (e.g., a display of a VR headset, a computer or television display, etc.) for assisting the remote operator in controlling the virtual vehicle through the simulated environment 610. The controls generated or input by the remote operator using the vehicle simulator component(s) 622 may be transmitted to the simulator component(s) 602 for updating a state of the virtual vehicle within the simulated environment 610.

As another example, the vehicle simulator component(s) 620 may receive (e.g., retrieve, obtain, etc.), from the global simulation hosted by the simulator component(s) 602, data that corresponds to, is associated with, and/or is required by the vehicle simulator component(s) 620 to perform one or more operations by the vehicle simulator component(s) 620 for the SIL object. In such an example, data (e.g., virtual sensor data corresponding to a field(s) of view of virtual camera(s) of the virtual vehicle, virtual LIDAR data, virtual RADAR data, virtual location data, virtual IMU data, etc.) corresponding to each sensor of the SIL object may be received from the simulator component(s) 602. This data may be used to generate an instance of the simulated environment for each sensor (e.g., a first instance from a field of view of a first virtual camera of the virtual vehicle, a second instance from a field of view of a second virtual camera, a third instance from a field of view of a virtual LIDAR sensor, etc.). The instances of the simulated environment may thus be used to generate sensor data for each sensor by the vehicle simulator component(s) 620. In some examples, the sensor data may be encoded using one or more codecs (e.g., each sensor may use its own codec, or each sensor type may use its own codec) in order to generate encoded sensor data that may be understood or familiar to an autonomous driving software stack simulated or emulated by the vehicle simulator component(s) 620. For example, a first vehicle manufacturer may use a first type of LIDAR data, a second vehicle manufacturer may use a second type of LIDAR data, etc., and thus the codecs may customize the sensor data to the types of sensor data used by the manufacturers. As a result, the simulation system 600 may be universal, customizable, and/or useable by any number of different sensor types depending on the types of sensors and the corresponding data types used by different manufacturers. In any example, the sensor data and/or encoded sensor data may be used by an autonomous driving software stack to perform one or more operations (e.g., object detection, path planning, control determinations, actuation types, etc.). For example, the sensor data and/or encoded data may be used as inputs to one or more DNNs of the autonomous driving software stack, and the outputs of the one or more DNNs may be used for updating a state of the virtual vehicle within the simulated environment 610. As such, the reliability and efficacy of the autonomous driving software stack, including one or more DNNs, may be tested, fine-tuned, verified, and/or validated within the simulated environment.

In yet another example, the vehicle simulator component(s) 606 may receive (e.g., retrieve, obtain, etc.), from the global simulation hosted by the simulator component(s) 602, data that corresponds to, is associated with, and/or is required by the vehicle simulator component(s) 606 to perform one or more operations by the vehicle simulator component(s) 606 for the HIL object. In such an example, data (e.g., virtual sensor data corresponding to a field(s) of view of virtual camera(s) of the virtual vehicle, virtual LIDAR data, virtual RADAR data, virtual location data, virtual IMU data, etc.) corresponding to each sensor of the HIL object may be received from the simulator component(s) 602. This data may be used to generate an instance of the simulated environment for each sensor (e.g., a first instance from a field of view of a first virtual camera of the virtual vehicle, a second instance from a field of view of a second virtual camera, a third instance from a field of view of a virtual LIDAR sensor, etc.). The instances of the simulated environment may thus be used to generate sensor data for each sensor by the vehicle simulator component(s) 620 (e.g., using a corresponding learned sensor model). In some examples, the sensor data may be encoded using one or more codecs (e.g., each sensor may use its own codec, or each sensor type may use its own codec) in order to generate encoded sensor data that may be understood or familiar to an autonomous driving software stack executing on the vehicle hardware 601 of the vehicle simulator component(s) 620. Similar to the SIL object described herein, the sensor data and/or encoded sensor data may be used by an autonomous driving software stack to perform one or more operations (e.g., object detection, path planning, control determinations, actuation types, etc.).

Now referring to FIG. 6C, FIG. 6C is another example illustration of a simulation system 600C, in accordance with some embodiments of the present disclosure. The simulation system 600C may include distributed shared memory (DSM) system 624, the simulator component(s) 602 (as one or more compute nodes), the vehicle simulator component(s) 606 (as one or more compute nodes) for a HIL object(s), the vehicle simulator component(s) 620 (as one or more compute nodes) for a SIL object(s), the vehicle simulator component(s) 606 (as one or more compute nodes) for a PIL object(s), and/or additional component(s) (or compute nodes) for AI objects and/or other object types (not shown). The simulation system 600C may include any number of HIL objects (e.g., each including its own vehicle simulator component(s) 606), any number of SIL objects (e.g., each including its own vehicle simulator component(s) 620), any number of PIL objects (e.g., each including its own vehicle simulator component(s) 622), and/or any number of AI objects (not shown, but may be hosted by the simulation component(s) 602 and/or separate compute nodes, depending on the embodiment).

The vehicle simulator component(s) 606 may include one or more SoC(s) 605 (or other components) that may be configured for installation and use within a physical vehicle. As such, as described herein, the simulation system 600C may be configured to use the SoC(s) 605 and/or other vehicle hardware 601 by using specific interfaces for communicating with the SoC(s) 605 and/or other vehicle hardware. The vehicle simulator component(s) 620 may include one or more software instances 630 that may be hosted on one or more GPUs and/or CPUs to simulate or emulate the SoC(s) 605. The vehicle simulator component(s) 622 may include one or more SoC(s) 626, one or more CPU(s) 628 (e.g., X86 boxes), and/or a combination thereof, in addition to the component(s) that may be used by the remote operator (e.g., keyboard, mouse, joystick, monitors, VR systems, steering wheel, pedals, in-vehicle components, such as light switches, blinkers, HMI display(s), etc., and/or other component(s)).

The simulation component(s) 602 may include any number of CPU(s) 632 (e.g., X86 boxes), GPU(s), and/or a combination thereof. The CPU(s) 632 may host the simulation software for maintaining the global simulation, and the GPU(s) 634 may be used for rendering, physics, and/or other functionality for generating the simulated environment 610.

As described herein, the simulation system 600C may include the DSM 624. The DSM 624 may use one or more distributed shared memory protocols to maintain the state of the global simulation using the state of each of the objects (e.g., HIL objects, SIL objects, PIL objects, AI objects, etc.). As such, each of the compute nodes corresponding to the vehicle simulator component(s) 606, 620, and/or 622 may be in communication with the simulation component(s) 602 via the DSM 624. By using the DSM 624 and the associated protocols, real-time simulation may be possible. For example, as opposed to how network protocols (e.g., TCP, UDP, etc.) are used in massive multiplayer online (MMO) games, the simulation system 600 may use a distributed shared memory protocol to maintain the state of the global simulation and each instance of the simulation (e.g., by each vehicle, object, and/or sensor) in real-time.

Now referring to FIG. 6D, FIG. 6D is an example illustration of a hardware-in-the-loop configuration, in accordance with some embodiments of the present disclosure. The vehicle simulator component(s) 606 may include the vehicle hardware 601, as described herein, and may include one or more computer(s) 636, one or more GPU(s) (not shown), and/or one or more CPU(s) (not shown). The computer(s) 636, GPU(s), and/or CPU(s) may manage or host the simulation software 638, or instance thereof, executing on the vehicle simulator component(s) 606. The vehicle hardware 601 may execute the software stack(s) 603 (e.g., an autonomous driving software stack, an IX software stack, etc.).

As described herein, by using the vehicle hardware 601, the other vehicle simulator component(s) 606 within the simulation environment 600 may need to be configured for communication with the vehicle hardware 601. For example, because the vehicle hardware 601 may be configured for installation within a physical vehicle (e.g., the vehicle 800), the vehicle hardware 601 may be configured to communicate over one or more connection types and/or communication protocols that are not standard in computing environments (e.g., in server-based platforms, in general-purpose computers, etc.). For example, a CAN interface, LVDS interface, USB interface, Ethernet interface, InfiniBand (IB) interface, and/or other interfaces may be used by the vehicle hardware 601 to communicate signals with other components of the physical vehicle. As such, in the simulation system 600, the vehicle simulator component(s) 606 (and/or other component(s) of the simulation system 600 in addition to, or alternative from, the vehicle simulator component(s) 606) may need to be configured for use with the vehicle hardware 601. In order to accomplish this, one or more CAN interfaces, LVDS interfaces, USB interfaces, Ethernet interfaces, and/or other interface may be used to provide for communication (e.g., over one or more communication protocols, such as LVDS) between vehicle hardware 601 and the other component(s) of the simulation system 600.

In some examples, the virtual vehicle that may correspond to the vehicle simulator component(s) 606 within the simulation system 600 may be modeled as a game object within an instance of a game engine. In addition, each of the virtual sensors of the virtual vehicle may be interfaced using sockets within the virtual vehicle's software stack(s) 603 executed on the vehicle hardware 601. In some examples, each of the virtual sensors of the virtual vehicle may include an instance of the game engine, in addition to the instance of the game engine associated with the simulation software 638 for the virtual vehicle. In examples where the vehicle simulator component(s) 606 include a plurality of GPUs, each of the sensors may be executed on a single GPU. In other examples, multiple sensors may be executed on a single GPU, or at least as many sensors as feasible to ensure real-time generation of the virtual sensor data.

Using HIL objects in the simulator system 600 may provide for a scalable solution that may simulate or emulate various driving conditions for autonomous software and hardware systems (e.g., NVIDIA's DRIVE AGX Pegasus™ compute platform and/or DRIVE PX Xavier™ compute platform). Some benefits of HIL objects may include the ability to test DNNs faster than real-time, the ability to scale verification with computing resources (e.g., rather than vehicles or test tracks), the ability to perform deterministic regression testing (e.g., the real-world environment is never the same twice, but a simulated environment can be), optimal ground truth labeling (e.g., no hand-labeling required), the ability to test scenarios difficult to produce in the real-world, rapid generation of test permutations, and the ability to test a larger space of permutations in simulation as compared to real-world.

Now referring to FIG. 6E, FIG. 6E is an example illustration of a hardware-in-the-loop configuration, in accordance with some embodiments of the present disclosure. The HIL configuration of FIG. 6E may include vehicle simulator component(s) 606, including the SoC(s) 605, a chassis fan(s) 656 and/or water-cooling system. The HIL configuration may include a two-box solution (e.g., the simulator component(s) 602 in a first box and the vehicle simulator component(s) 606 in a second box). Using this approach may reduce the amount of space the system occupies as well as reduce the number of external cables in data centers (e.g., by including multiple components together with the SoC(s) 605 in the vehicle simulator component(s) 606 e.g., the first box). The vehicle simulator component(s) 606 may include one or more GPUs 652 (e.g., NVIDIA QUADRO GPU(s)) that may provide, in an example, non-limiting embodiment, 8 DP/HDMI video streams that may be synchronized using sync component(s) 654 (e.g., through a QUADRO Sync II Card). These GPU(s) 652 (and/or other GPU types) may provide the sensor input to the SoC(s) 605 (e.g., to the vehicle hardware 601). In some examples, the vehicle simulator component(s) 606 may include a network interface (e.g., one or more network interface cards (NICs) 650) that may simulate or emulate RADAR sensors, LIDAR sensors, and/or IMU sensors (e.g., by providing 8 Gigabit ports with precision time protocol (PTP) support). In addition, the vehicle simulator component(s) 606 may include an input/output (I/O) analog integrated circuit 657. Registered Jack (RJ) interfaces (e.g., RJ45), high speed data (HSD) interfaces, USB interfaces, pulse per second (PPS) clocks, Ethernet (e.g., 10Gb Ethernet (GbE)) interfaces, CAN interfaces, HDMI interfaces, and/or other interface types may be used to effectively transmit and communication data between and among the various component(s) of the system.

Now referring to FIG. 6F, FIG. 6F is an example illustration of a software-in-the-loop configuration, in accordance with some embodiments of the present disclosure. The vehicle simulator component(s) 620 may include computer(s) 640, GPU(s) (not shown), CPU(s) (not shown), and/or other components. The computer(s) 640, GPU(s), and/or CPU(s) may manage or host the simulation software 638, or instance thereof, executing on the vehicle simulator component(s) 620, and may host the software stack(s) 603. For example, the vehicle simulator component(s) 620 may simulate or emulate, using software, the vehicle hardware 601 in an effort to execute the software stack(s) 603 as accurately as possible.

In order to increase accuracy in SIL embodiments, the vehicle simulator component(s) 620 may be configured to communicate over one or more virtual connection types and/or communication protocols that are not standard in computing environments. For example, a virtual CAN interface, virtual LVDS interface, virtual USB interface, virtual Ethernet interface, and/or other virtual interfaces may be used by the computer(s) 640, CPU(s), and/or GPU(s) of the vehicle simulator component(s) 620 to provide for communication (e.g., over one or more communication protocols, such as LVDS) between the software stack(s) 603 and the simulation software 638 within the simulation system 600. For example, the virtual interfaces may include middleware that may be used to provide a continuous feedback loop with the software stack(s) 603. As such, the virtual interfaces may simulate or emulate the communications between the vehicle hardware 601 and the physical vehicle using one or more software protocols, hardware (e.g., CPU(s), GPU(s), computer(s) 640, etc.), or a combination thereof.

The computer(s) 640 in some examples, may include X86 CPU hardware, and one or more X86 CPUs may execute both the simulation software 638 and the software stack(s) 603. In other examples, the computer(s) 640 may include GPU hardware (e.g., an NVIDIA DGX system and/or cloud-based NVIDIA Tesla servers).

In some examples, the virtual vehicle that may correspond to the vehicle simulator component(s) 620 within the simulation system 600 may be modeled as a game object within an instance of a game engine. In addition, each of the virtual sensors of the virtual vehicle may be interfaced using sockets within the virtual vehicle's software stack(s) 603 executed on the vehicle simulator component(s) 620. In some examples, each of the virtual sensors of the virtual vehicle may include an instance of the game engine, in addition to the instance of the game engine associated with the simulation software 638 for the virtual vehicle. In examples where the vehicle simulator component(s) 606 include a plurality of GPUs, each of the sensors may be executed on a single GPU. In other examples, multiple sensors may be executed on a single GPU, or at least as many sensors as feasible to ensure real-time generation of the virtual sensor data.

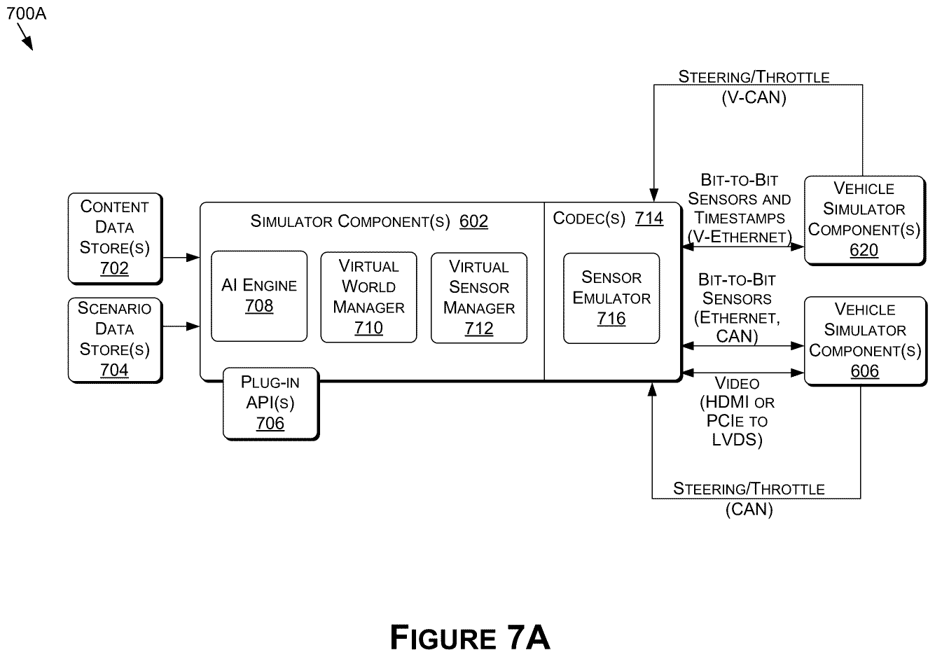

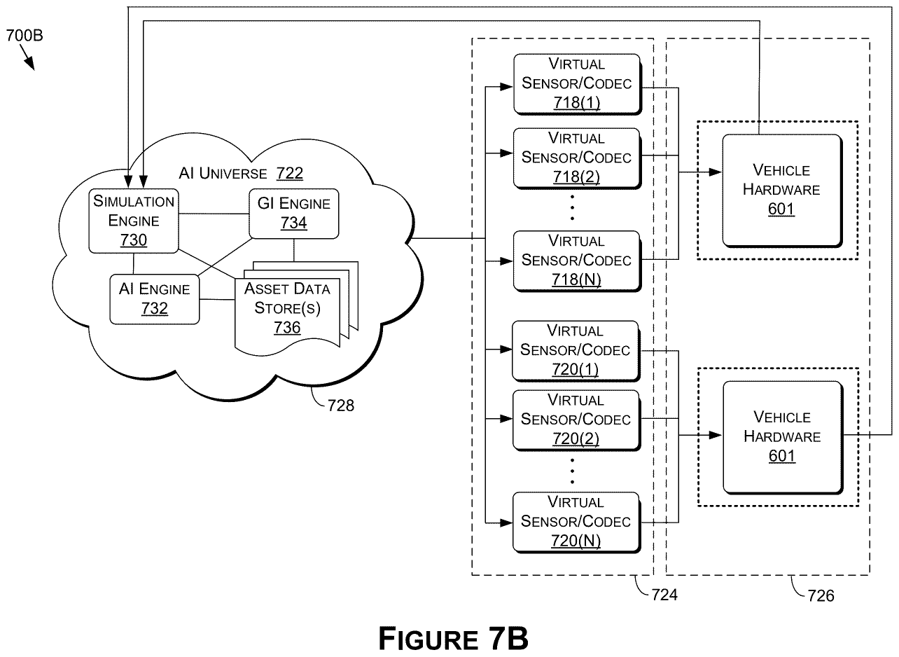

Now referring to FIG. 7A, FIG. 7A is an example illustration of a simulation system 700 at runtime, in accordance with some embodiments of the present disclosure (e.g., simulation platform 100). Some or all of the components of the simulation system 700 may be used in the simulation system 600, and some or all of the components of the simulation system 600 may be used in the simulation system 700. As such, components, features, and/or functionality described with respect to the simulation system 600 may be associated with the simulation system 700 (and/or simulation platform 100), and vice versa. In addition, each of the simulation systems 700A and 700B (FIG. 7B) may include similar and/or shared components, features, and/or functionality.

The simulation system 700A (e.g., representing one example of simulation system 700) may include the simulator component(s) 602, codec(s) 714, content data store(s) 702, scenario data store(s) 704, vehicle simulator component(s) 620 (e.g., for a SIL object), and vehicle simulator component(s) 606 (e.g., for a HIL object). The content data store(s) 702 may include detailed content information for modeling cars, trucks, people, bicyclists, signs, buildings, trees, curbs, and/or other features of the simulated environment. The scenario data store(s) 704 may include scenario information that may include dangerous scenario information (e.g., that is unsafe to test in the real-world environment), such as a child in an intersection.

The simulator component(s) 602 may include an AI engine 708 that simulates traffic, pedestrians, weather, and/or other AI features of the simulated environment. The simulator component(s) 602 may include a virtual world manager 710 that manages the world state for the global simulation. The simulator component(s) 602 may further include a virtual sensor manger 712 that may mange the virtual sensors (any or all of which may be implemented using a corresponding learned sensor model). The AI engine 708 may model traffic similar to how traffic is modeled in an automotive video game, and may be done using a game engine, as described herein. In other examples, custom AI may be used to provide the determinism and computational level of detail necessary for large-scale reproducible automotive simulation. In some examples, traffic may be modeled using SIL objects, HIL objects, PIL objects, AI objects, and/or combination thereof. The system 700 may create a subclass of an AI controller that examines map data, computes a route, and drives the route while avoiding other cars. The AI controller may compute desired steering, acceleration, and/or braking, and may apply those values to the virtual objects. The vehicle properties used may include mass, max RPM, torque curves, and/or other properties. A physics engine may be used to determine states of AI objects. As described herein, for vehicles or other objects that may be far away and may not have an impact on a current sensor(s), the system may choose not to apply physics for those objects and only determine locations and/or instantaneous motion vectors. Ray-casting may be used for each wheel to ensure that the wheels of the vehicles are in contact. In some examples, traffic AI may operate according to a script (e.g., rules-based traffic). Traffic AI maneuvers for virtual objects may include lateral lane changes (e.g., direction, distance, duration, shape, etc.), longitudinal movement (e.g., matching speed, relative target, delta to target, absolute value), route following, and/or path following. The triggers for the traffic AI maneuvers may be time-based (e.g., three seconds), velocity-based (e.g., at sixty mph), proximity-based to map (e.g., within twenty feet of intersection), proximity-based to actor (e.g., within twenty feet of another object), lane clear, and/or others.

The AI engine 708 may model pedestrian AI similar to traffic AI, described herein, but for pedestrians. The pedestrians may be modeled similar to real pedestrians, and the system 700 may infer pedestrian conduct based on learned behaviors.

The simulator component(s) 602 may be used to adjust the time of day such that street lights turn on and off, headlights turn on and off, shadows, glares, and/or sunsets are considered, etc. In some examples, only lights within a threshold distance to the virtual object may be considered to increase efficiency.

Weather may be accounted for by the simulator component(s) 602 (e.g., by the virtual world manager 710). The weather may be used to update the coefficients of friction for the driving surfaces, and temperature information may be used to update tire interaction with the driving surfaces. Where rain or snow are present, the system 700 may generate meshes to describe where rainwater and snow may accumulate based on the structure of the scene, and the meshes may be employed when rain or snow are present in the simulation.

In some examples, as described herein, at least some of the simulator component(s) 602 may alternatively be included in the vehicle simulator component(s) 620 and/or 606. For example, the vehicle simulator component(s) 620 and/or the vehicle simulator component(s) 606 may include the virtual sensor manager 712 for managing each of the sensors of the associated virtual object. In addition, one or more of the codecs 714 may be included in the vehicle simulator component(s) 620 and/or the vehicle simulator component(s) 606. In such examples, the virtual sensor manager 712 may generate sensor data corresponding to a sensor of the virtual object (e.g., using a learned sensor model), and the sensor data may be used by sensor emulator 716 of the codec(s) 714 to encode the sensor data according to the sensor data format or type used by the software stack(s) 603 (e.g., the software stack(s) 603 executing on the vehicle simulator component(s) 620 and/or the vehicle simulator component(s) 606).

The codec(s) 714 may provide an interface to the software stack(s) 603. The codec(s) 714 (and/or other codec(s) described herein) may include an encoder/decoder framework. The codec(s) 714 may include CAN steering, throttle requests, and/or may be used to send sensor data to the software stack(s) 603 in SIL and HIL embodiments. The codec(s) 714 may be beneficial to the simulation systems described herein (e.g., 600 and 700). For example, as data (e.g., USS measurement data 126) is produced by the simulation platform 100 and/or the simulation systems 600 and 700, the data may be transmitted to the software stack(s) 603 such that the following standards may be met. The data may be transferred to the software stack(s) 603 such that minimal impact is introduced to the software stack(s) 603 and/or the vehicle hardware 601 (in HIL embodiments). This may result in more accurate simulations as the software stack(s) 603 and/or the vehicle hardware 601 may be operating in an environment that closely resembles deployment in a real-world environment. The data may be transmitted to the software stack(s) 603 such that the simulator and/or re-simulator may be agnostic to the actual hardware configuration of the system under test. This may reduce development overhead due to bugs or separate code paths depending on the simulation configuration. The data may be transmitted to the software stack(s) 603 such that the data may match (e.g., bit-to-bit) the data sent from a physical sensor of a physical vehicle (e.g., the vehicle 800). The data may be transmitted to efficiently in both SIL and HIL embodiments.

The sensor emulator 716 may emulate at least cameras, LIDAR sensors, and/or RADAR sensors, any or all of which may be implemented using a corresponding learned sensor model. Using a learned sensor model may obviate the need to model the sensor using ray-tracing, although in some embodiments, ray-tracing may additionally or alternatively be used. With respect to LIDAR sensors, some LIDAR sensors report tracked objects. As such, for each frame represented by the virtual sensor data, the simulator component(s) 602 may create a list of all tracked objects (e.g., trees, vehicles, pedestrians, foliage, etc.) within range of the virtual object having the virtual LIDAR sensors, and may cast virtual rays toward the tracked objects. When a significant number of rays strike a tracked object, that object may be added to the report of the LIDAR data. In some examples, the LIDAR sensors may be modeled using simple ray-casting without reflection, adjustable field of view, adjustable noise, and/or adjustable drop-outs. LIDAR with moving parts, limited fields of view, and/or variable resolutions may be simulated. For example, the LIDAR sensors may be modeled as solid state LIDAR and/or as Optix-based LIDAR. In examples, using Optix-based LIDAR, the rays may bounce from water, reflective materials, and/or windows. Texture may be assigned to roads, signs, and/or vehicles to model laser reflection at the wavelengths corresponding to the textures. RADAR may be implemented similarly to LIDAR. As described herein, RADAR and/or LIDAR may be simulated using learned sensors, ray-tracing techniques, and/or otherwise.

In some examples, the vehicle simulator component(s) 606, 620, and/or 622 may include a feedback loop with the simulator component(s) 602 (and/or the component(s) that generate the virtual sensor data). The feedback loop may be used to provide information for updating the virtual sensor data capture or generation. For example, for virtual cameras, the feedback loop may be based on sensor feedback, such as changes to exposure responsive to lighting conditions (e.g., increase exposure in dim lighting conditions so that the image data may be processed by the DNNs properly). As another example, for virtual LIDAR sensors, the feedback loop may be representative of changes to energy level (e.g., to boost energy to produce more useable or accurate LIDAR data).

GNNS sensors (e.g., GPS sensors) may be simulated within the simulation space to generate real-world coordinates. In order to this, noise functions may be used to approximate inaccuracy. As with any virtual sensors described herein, the virtual sensor data may be generated using a learned sensor model or otherwise, and transmitted to the software stack(s) 603 using the codec(s) 714 to be converted to a bit-to-bit correct signal (e.g., corresponding accurately to the signals generated by the physical sensors of the physical vehicles).

One or more plugin application programming interfaces (APIs) 706 may be used. The plugin APIs 706 may include first-party and/or third-party plugins. For example, third parties may customize the simulation system 700B using their own plugin APIs 706 for providing custom information, such as performance timings, suspension dynamics, tire dynamics, etc.

The plugin APIs 706 may include an ego-dynamics component(s) (not shown) that may receive information from the simulator component(s) 602 including position, velocity, car state, and/or other information, and may provide information to the simulator component(s) 602 including performance timings, suspension dynamics, tire dynamics, and/or other information. For examples, the simulator component(s) 602 may provide CAN throttle, steering, and the driving surface information to the ego-dynamics component(s). In some examples, the ego-dynamics component(s) may include an off-the-shelf vehicle dynamics package (e.g., IPG CARMAKER or VIRTUAL TEST DRIVE), while in other examples the ego-dynamics component(s) may be customized and/or received (e.g., from a first-party and/or a third-party).

The plugin APIs 706 may include a key performance indicator (KPI) API. The KPI API may receive CAN data, ground truth, and/or virtual object state information (e.g., from the software stack(s) 603) from the simulator component(s) 602 and may generate and/or provide a report (in real-time) that includes KPI's and/or commands to save state, restore state, and/or apply changes.

Now referring to FIG. 7B, FIG. 7B includes a cloud-based architecture for a simulation system 700B, in accordance with some embodiment of the present disclosure. The simulation system 700B may, at least partly, reside in the cloud and may communicate over one or more networks, such as but not limited to those described herein (e.g., with respect to network 890 of FIG. 8D), with one or more GPU platforms 724 (e.g., that may include GPUs, CPUs, TPUS, and/or other processor types) and/or one or more HIL platforms 726 (e.g., which may include some or all of the components from the vehicle simulator component(s) 606, described herein).

A simulated environment 728 (e.g., which may be similar to the simulated environment 610 described herein) may be modeled by interconnected components including a simulation engine 730, an AI engine 732, a global illumination (GI) engine 734, an asset data store(s) 736, and/or other components. In some examples, these component(s) may be used to model a simulated environment (e.g., a virtual world) in a virtualized interactive platform (e.g., similar to a massive multiplayer online (MMO) game environment. The simulated environment may further include physics, traffic simulation, weather simulation, and/or other features and simulations for the simulated environment. GI engine 734 may calculate GI once and share the calculation with each of the nodes 718(1)-718(N) and 720(1)-720(N) (e.g., the calculation of GI may be view independent). The simulated environment 728 may include an AI universe 722 that provides data to GPU platforms 724 (e.g., GPU servers) that may create renderings for each sensor of the vehicle (e.g., at the virtual sensor/codec(s) 718 for a first virtual object and at the virtual sensor codec(s) 720 for a second virtual object). For example, the GPU platform 724 may receive data about the simulated environment 728 and may create sensor inputs for each of 718(1)-718(N), 720(1)-720(N), and/or virtual sensor/codec pairs corresponding to other virtual objects (depending on the embodiment). In examples where the virtual objects are simulated using HIL objects, the sensor inputs may be provided to the vehicle hardware 601 which may use the software stack(s) 603 to perform one or more operations and/or generate one or more commands, such as those described herein. In some examples, as described herein, the virtual sensor data from each of the virtual sensors may be encoded using a codec prior to being used by (or transmitted to) the software stack(s) 603. In addition, in some examples, each of the sensors may be executed on its own GPU within the GPU platform 724, while in other examples, two or more sensors may share the same GPU within the GPU platform 724.

The one or more operations or commands may be transmitted to the simulation engine 730 which may update the behavior of one or more of the virtual objects based on the operations and/or commands. For example, the simulation engine 730 may use the AI engine 732 to update the behavior of the AI agents as well as the virtual objects in the simulated environment 728. The simulation engine 730 may then update the object data and characteristics (e.g., within the asset data store(s) 736), may update the GI (and/or other aspects such as reflections, shadows, etc.), and then may generate and provide updated sensor inputs to the GPU platform 724. This process may repeat until a simulation is completed.

### Example Autonomous Vehicle

FIG. 8A is an illustration of an example autonomous vehicle 800, in accordance with some embodiments of the present disclosure. The autonomous vehicle 800 (alternatively referred to herein as the “vehicle 800”) may include, without limitation, a passenger vehicle, such as a car, a truck, a bus, a first responder vehicle, a shuttle, an electric or motorized bicycle, a motorcycle, a fire truck, a police vehicle, an ambulance, a boat, a construction vehicle, an underwater craft, a robotic vehicle, a drone, an airplane, a vehicle coupled to a trailer (e.g., a semi-tractor-trailer truck used for hauling cargo), and/or another type of vehicle (e.g., that is unmanned and/or that accommodates one or more passengers). Autonomous vehicles are generally described in terms of automation levels, defined by the National Highway Traffic Safety Administration (NHTSA), a division of the US Department of Transportation, and the Society of Automotive Engineers (SAE) “Taxonomy and Definitions for Terms Related to Driving Automation Systems for On-Road Motor Vehicles” (Standard No. J3016-201806, published on Jun. 15, 2018, Standard No. J3016-201609, published on Sep. 30, 2016, and previous and future versions of this standard). The vehicle 800 may be capable of functionality in accordance with one or more of Level 3-Level 5 of the autonomous driving levels. The vehicle 800 may be capable of functionality in accordance with one or more of Level 1-Level 5 of the autonomous driving levels. For example, the vehicle 800 may be capable of driver assistance (Level 1), partial automation (Level 2), conditional automation (Level 3), high automation (Level 4), and/or full automation (Level 5), depending on the embodiment. The term “autonomous,” as used herein, may include any and/or all types of autonomy for the vehicle 800 or other machine, such as being fully autonomous, being highly autonomous, being conditionally autonomous, being partially autonomous, providing assistive autonomy, being semi-autonomous, being primarily autonomous, or other designation.

The vehicle 800 may include components such as a chassis, a vehicle body, wheels (e.g., 2, 4, 6, 8, 18, etc.), tires, axles, and other components of a vehicle. The vehicle 800 may include a propulsion system 850, such as an internal combustion engine, hybrid electric power plant, an all-electric engine, and/or another propulsion system type. The propulsion system 850 may be connected to a drive train of the vehicle 800, which may include a transmission, to allow the propulsion of the vehicle 800. The propulsion system 850 may be controlled in response to receiving signals from the throttle/accelerator 852.

A steering system 854, which may include a steering wheel, may be used to steer the vehicle 800 (e.g., along a desired path or route) when the propulsion system 850 is operating (e.g., when the vehicle is in motion). The steering system 854 may receive signals from a steering actuator 856. The steering wheel may be optional for full automation (Level 5) functionality.

The brake sensor system 846 may be used to operate the vehicle brakes in response to receiving signals from the brake actuators 848 and/or brake sensors.

Controller(s) 836, which may include one or more system on chips (SoCs) 804 (FIG. 8C) and/or GPU(s), may provide signals (e.g., representative of commands) to one or more components and/or systems of the vehicle 800. For example, the controller(s) may send signals to operate the vehicle brakes via one or more brake actuators 848, to operate the steering system 854 via one or more steering actuators 856, to operate the propulsion system 850 via one or more throttle/accelerators 852. The controller(s) 836 may include one or more onboard (e.g., integrated) computing devices (e.g., supercomputers) that process sensor signals, and output operation commands (e.g., signals representing commands) to allow autonomous driving and/or to assist a human driver in driving the vehicle 800. The controller(s) 836 may include a first controller 836 for autonomous driving functions, a second controller 836 for functional safety functions, a third controller 836 for artificial intelligence functionality (e.g., computer vision), a fourth controller 836 for infotainment functionality, a fifth controller 836 for redundancy in emergency conditions, and/or other controllers. In some examples, a single controller 836 may handle two or more of the above functionalities, two or more controllers 836 may handle a single functionality, and/or any combination thereof.

The controller(s) 836 may provide the signals for controlling one or more components and/or systems of the vehicle 800 in response to sensor data received from one or more sensors (e.g., sensor inputs). The sensor data may be received from, for example and without limitation, global navigation satellite systems (“GNSS”) sensor(s) 858 (e.g., Global Positioning System sensor(s)), RADAR sensor(s) 860, ultrasonic sensor(s) 862, LiDAR sensor(s) 864, inertial measurement unit (IMU) sensor(s) 866 (e.g., accelerometer(s), gyroscope(s), magnetic compass(es), magnetometer(s), etc.), microphone(s) 896, stereo camera(s) 868, wide-view camera(s) 870 (e.g., fisheye cameras), infrared camera(s) 872, surround camera(s) 874 (e.g., 360 degree cameras), long-range and/or mid-range camera(s) 898, speed sensor(s) 844 (e.g., for measuring the speed of the vehicle 800), vibration sensor(s) 842, steering sensor(s) 840, brake sensor(s) (e.g., as part of the brake sensor system 846), one or more occupant monitoring system (OMS) sensor(s) 801 (e.g., one or more interior cameras), and/or other sensor types.

One or more of the controller(s) 836 may receive inputs (e.g., represented by input data) from an instrument cluster 832 of the vehicle 800 and provide outputs (e.g., represented by output data, display data, etc.) via a human-machine interface (HMI) display 834, an audible annunciator, a loudspeaker, and/or via other components of the vehicle 800. The outputs may include information such as vehicle velocity, speed, time, map data (e.g., the High Definition (“HD”) map 822 of FIG. 8C), location data (e.g., the vehicle's 800 location, such as on a map), direction, location of other vehicles (e.g., an occupancy grid), information about objects and status of objects as perceived by the controller(s) 836, etc. For example, the HMI display 834 may display information about the presence of one or more objects (e.g., a street sign, caution sign, traffic light changing, etc.), and/or information about driving maneuvers the vehicle has made, is making, or will make (e.g., changing lanes now, taking exit 34B in two miles, etc.).

The vehicle 800 further includes a network interface 824 which may use one or more wireless antenna(s) 826 and/or modem(s) to communicate over one or more networks. For example, the network interface 824 may be capable of communication over Long-Term Evolution (“LTE”), Wideband Code Division Multiple Access (“WCDMA”), Universal Mobile Telecommunications System (“UMTS”), Global System for Mobile communication (“GSM”), IMT-CDMA Multi-Carrier (“CDMA2000”), etc. The wireless antenna(s) 826 may also allow communication between objects in the environment (e.g., vehicles, mobile devices, etc.), using local area network(s), such as Bluetooth, Bluetooth Low Energy (“LE”), Z-Wave, ZigBee, etc., and/or low power wide-area network(s) (“LPWANs”), such as LoRaWAN, SigFox, etc.

FIG. 8B is an example of camera locations and fields of view for the example autonomous vehicle 800 of FIG. 8A, in accordance with some embodiments of the present disclosure. The cameras and respective fields of view are one example embodiment and are not intended to be limiting. For example, additional and/or alternative cameras may be included and/or the cameras may be located at different locations on the vehicle 800.

The camera types for the cameras may include, but are not limited to, digital cameras that may be adapted for use with the components and/or systems of the vehicle 800. The camera(s) may operate at automotive safety integrity level (ASIL) B and/or at another ASIL. The camera types may be capable of any image capture rate, such as 60 frames per second (fps), 120 fps, 240 fps, etc., depending on the embodiment. The cameras may be capable of using rolling shutters, global shutters, another type of shutter, or a combination thereof. In some examples, the color filter array may include a red clear clear clear (RCCC) color filter array, a red clear clear blue (RCCB) color filter array, a red blue green clear (RBGC) color filter array, a Foveon X3 color filter array, a Bayer sensors (RGGB) color filter array, a monochrome sensor color filter array, and/or another type of color filter array. In some embodiments, clear pixel cameras, such as cameras with an RCCC, an RCCB, and/or an RBGC color filter array, may be used in an effort to increase light sensitivity.

In some examples, one or more of the camera(s) may be used to perform advanced driver assistance systems (ADAS) functions (e.g., as part of a redundant or fail-safe design). For example, a Multi-Function Mono Camera may be installed to provide functions including lane departure warning, traffic sign assist and intelligent headlamp control. One or more of the camera(s) (e.g., all of the cameras) may record and provide image data (e.g., video) simultaneously.

One or more of the cameras may be mounted in a mounting assembly, such as a custom designed (three dimensional (“3D”) printed) assembly, in order to cut out stray light and reflections from within the car (e.g., reflections from the dashboard reflected in the windshield mirrors) which may interfere with the camera's image data capture abilities. With reference to wing-mirror mounting assemblies, the wing-mirror assemblies may be custom 3D printed so that the camera mounting plate matches the shape of the wing-mirror. In some examples, the camera(s) may be integrated into the wing-mirror. For side-view cameras, the camera(s) may also be integrated within the four pillars at each corner of the cabin.

Cameras with a field of view that include portions of the environment in front of the vehicle 800 (e.g., front-facing cameras) may be used for surround view, to help identify forward facing paths and obstacles, as well aid in, with the help of one or more controllers 836 and/or control SoCs, providing information critical to generating an occupancy grid and/or determining the preferred vehicle paths. Front-facing cameras may be used to perform many of the same ADAS functions as LiDAR, including emergency braking, pedestrian detection, and collision avoidance. Front-facing cameras may also be used for ADAS functions and systems including Lane Departure Warnings (“LDW”), Autonomous Cruise Control (“ACC”), and/or other functions such as traffic sign recognition.

A variety of cameras may be used in a front-facing configuration, including, for example, a monocular camera platform that includes a complementary metal oxide semiconductor (“CMOS”) color imager. Another example may be a wide-view camera(s) 870 that may be used to perceive objects coming into view from the periphery (e.g., pedestrians, crossing traffic or bicycles). Although only one wide-view camera is illustrated in FIG. 8B, there may be any number (including zero) of wide-view cameras 870 on the vehicle 800. In addition, any number of long-range camera(s) 898 (e.g., a long-view stereo camera pair) may be used for depth-based object detection, especially for objects for which a neural network has not yet been trained. The long-range camera(s) 898 may also be used for object detection and classification, as well as basic object tracking.

Any number of stereo cameras 868 may also be included in a front-facing configuration. In at least one embodiment, one or more of stereo camera(s) 868 may include an integrated control unit comprising a scalable processing unit, which may provide a programmable logic (“FPGA”) and a multi-core micro-processor with an integrated Controller Area Network (“CAN”) or Ethernet interface on a single chip. Such a unit may be used to generate a 3D map of the vehicle's environment, including a distance estimate for all the points in the image. An alternative stereo camera(s) 868 may include a compact stereo vision sensor(s) that may include two camera lenses (one each on the left and right) and an image processing chip that may measure the distance from the vehicle to the target object and use the generated information (e.g., metadata) to activate the autonomous emergency braking and lane departure warning functions. Other types of stereo camera(s) 868 may be used in addition to, or alternatively from, those described herein.

Cameras with a field of view that include portions of the environment to the side of the vehicle 800 (e.g., side-view cameras) may be used for surround view, providing information used to create and update the occupancy grid, as well as to generate side impact collision warnings. For example, surround camera(s) 874 (e.g., four surround cameras 874 as illustrated in FIG. 8B) may be positioned to on the vehicle 800. The surround camera(s) 874 may include wide-view camera(s) 870, fisheye camera(s), 360 degree camera(s), and/or the like. Four example, four fisheye cameras may be positioned on the vehicle's front, rear, and sides. In an alternative arrangement, the vehicle may use three surround camera(s) 874 (e.g., left, right, and rear), and may leverage one or more other camera(s) (e.g., a forward-facing camera) as a fourth surround view camera.

Cameras with a field of view that include portions of the environment to the rear of the vehicle 800 (e.g., rear-view cameras) may be used for park assistance, surround view, rear collision warnings, and creating and updating the occupancy grid. A wide variety of cameras may be used including, but not limited to, cameras that are also suitable as a front-facing camera(s) (e.g., long-range and/or mid-range camera(s) 898, stereo camera(s) 868), infrared camera(s) 872, etc.), as described herein.

Cameras with a field of view that include portions of the interior environment within the cabin of the vehicle 800 (e.g., one or more OMS sensor(s) 801) may be used as part of an occupant monitoring system (OMS) such as, but not limited to, a driver monitoring system (DMS). For example, OMS sensors (e.g., the OMS sensor(s) 801) may be used (e.g., by the controller(s) 836) to track an occupant's and/or driver's gaze direction, head pose, and/or blinking. This gaze information may be used to determine a level of attentiveness of the occupant or driver (e.g., to detect drowsiness, fatigue, and/or distraction), and/or to take responsive action to prevent harm to the occupant or operator. In some embodiments, data from OMS sensors may be used to allow gaze-controlled operations triggered by driver and/or non-driver occupants such as, but not limited to, adjusting cabin temperature and/or airflow, opening and closing windows, controlling cabin lighting, controlling entertainment systems, adjusting mirrors, adjusting seat positions, and/or other operations. In some embodiments, an OMS may be used for applications such as determining when objects and/or occupants have been left behind in a vehicle cabin (e.g., by detecting occupant presence after the driver exits the vehicle).

FIG. 8C is a block diagram of an example system architecture for the example autonomous vehicle 800 of FIG. 8A, in accordance with some embodiments of the present disclosure. It should be understood that this and other arrangements described herein are set forth only as examples. Other arrangements and elements (e.g., machines, interfaces, functions, orders, groupings of functions, etc.) may be used in addition to or instead of those shown, and some elements may be omitted altogether. Further, many of the elements described herein are functional entities that may be implemented as discrete or distributed components or in conjunction with other components, and in any suitable combination and location. Various functions described herein as being performed by entities may be carried out by hardware, firmware, and/or software. For instance, various functions may be carried out by a processor executing instructions stored in memory.

Each of the components, features, and systems of the vehicle 800 in FIG. 8C are illustrated as being connected via bus 802. The bus 802 may include a Controller Area Network (CAN) data interface (alternatively referred to herein as a “CAN bus”). A CAN may be a network inside the vehicle 800 used to aid in control of various features and functionality of the vehicle 800, such as actuation of brakes, acceleration, braking, steering, windshield wipers, etc. A CAN bus may be configured to have dozens or even hundreds of nodes, each with its own unique identifier (e.g., a CAN ID). The CAN bus may be read to find steering wheel angle, ground speed, engine revolutions per minute (RPMs), button positions, and/or other vehicle status indicators. The CAN bus may be ASIL B compliant.

Although the bus 802 is described herein as being a CAN bus, this is not intended to be limiting. For example, in addition to, or alternatively from, the CAN bus, FlexRay and/or Ethernet may be used. Additionally, although a single line is used to represent the bus 802, this is not intended to be limiting. For example, there may be any number of busses 802, which may include one or more CAN busses, one or more FlexRay busses, one or more Ethernet busses, and/or one or more other types of busses using a different protocol. In some examples, two or more busses 802 may be used to perform different functions, and/or may be used for redundancy. For example, a first bus 802 may be used for collision avoidance functionality and a second bus 802 may be used for actuation control. In any example, each bus 802 may communicate with any of the components of the vehicle 800, and two or more busses 802 may communicate with the same components. In some examples, each SoC 804, each controller 836, and/or each computer within the vehicle may have access to the same input data (e.g., inputs from sensors of the vehicle 800), and may be connected to a common bus, such the CAN bus.

The vehicle 800 may include one or more controller(s) 836, such as those described herein with respect to FIG. 8A. The controller(s) 836 may be used for a variety of functions. The controller(s) 836 may be coupled to any of the various other components and systems of the vehicle 800, and may be used for control of the vehicle 800, artificial intelligence of the vehicle 800, infotainment for the vehicle 800, and/or the like.

The vehicle 800 may include a system(s) on a chip (SoC) 804. The SoC 804 may include CPU(s) 806, GPU(s) 808, processor(s) 810, cache(s) 812, accelerator(s) 814, data store(s) 816, and/or other components and features not illustrated. The SoC(s) 804 may be used to control the vehicle 800 in a variety of platforms and systems. For example, the SoC(s) 804 may be combined in a system (e.g., the system of the vehicle 800) with an HD map 822 which may obtain map refreshes and/or updates via a network interface 824 from one or more servers (e.g., server(s) 878 of FIG. 8D).

The CPU(s) 806 may include a CPU cluster or CPU complex (alternatively referred to herein as a “CCPLEX”). The CPU(s) 806 may include multiple cores and/or L2 caches. For example, in some embodiments, the CPU(s) 806 may include eight cores in a coherent multi-processor configuration. In some embodiments, the CPU(s) 806 may include four dual-core clusters where each cluster has a dedicated L2 cache (e.g., a 2 MB L2 cache). The CPU(s) 806 (e.g., the CCPLEX) may be configured to support simultaneous cluster operation allowing any combination of the clusters of the CPU(s) 806 to be active at any given time.

The CPU(s) 806 may implement power management capabilities that include one or more of the following features: individual hardware blocks may be clock-gated automatically when idle to save dynamic power; each core clock may be gated when the core is not actively executing instructions due to execution of WFI/WFE instructions; each core may be independently power-gated; each core cluster may be independently clock-gated when all cores are clock-gated or power-gated; and/or each core cluster may be independently power-gated when all cores are power-gated. The CPU(s) 806 may further implement an enhanced algorithm for managing power states, where allowed power states and expected wakeup times are specified, and the hardware/microcode determines the best power state to enter for the core, cluster, and CCPLEX. The processing cores may support simplified power state entry sequences in software with the work offloaded to microcode.

The GPU(s) 808 may include an integrated GPU (alternatively referred to herein as an “iGPU”). The GPU(s) 808 may be programmable and may be efficient for parallel workloads. The GPU(s) 808, in some examples, may use an enhanced tensor instruction set. The GPU(s) 808 may include one or more streaming microprocessors, where each streaming microprocessor may include an L1 cache (e.g., an L1 cache with at least 96 KB storage capacity), and two or more of the streaming microprocessors may share an L2 cache (e.g., an L2 cache with a 512 KB storage capacity). In some embodiments, the GPU(s) 808 may include at least eight streaming microprocessors. The GPU(s) 808 may use compute application programming interface(s) (API(s)). In addition, the GPU(s) 808 may use one or more parallel computing platforms and/or programming models (e.g., NVIDIA's CUDA).

The GPU(s) 808 may be power-optimized for best performance in automotive and embedded use cases. For example, the GPU(s) 808 may be fabricated on a Fin field-effect transistor (FinFET). However, this is not intended to be limiting and the GPU(s) 808 may be fabricated using other semiconductor manufacturing processes. Each streaming microprocessor may incorporate a number of mixed-precision processing cores partitioned into multiple blocks. For example, and without limitation, 64 PF32 cores and 32 PF64 cores may be partitioned into four processing blocks. In such an example, each processing block may be allocated 16 FP32 cores, 8 FP64 cores, 16 INT32 cores, two mixed-precision NVIDIA TENSOR COREs for deep learning matrix arithmetic, an L0 instruction cache, a warp scheduler, a dispatch unit, and/or a 64 KB register file. In addition, the streaming microprocessors may include independent parallel integer and floating-point data paths to provide for efficient execution of workloads with a mix of computation and addressing calculations. The streaming microprocessors may include independent thread scheduling capability to allow finer-grain synchronization and cooperation between parallel threads. The streaming microprocessors may include a combined L1 data cache and shared memory unit in order to improve performance while simplifying programming.

The GPU(s) 808 may include a high bandwidth memory (HBM) and/or a 16 GB HBM2 memory subsystem to provide, in some examples, about 900 GB/second peak memory bandwidth. In some examples, in addition to, or alternatively from, the HBM memory, a synchronous graphics random-access memory (SGRAM) may be used, such as a graphics double data rate type five synchronous random-access memory (GDDR5).

The GPU(s) 808 may include unified memory technology including access counters to allow for more accurate migration of memory pages to the processor that accesses them most frequently, thereby improving efficiency for memory ranges shared between processors. In some examples, address translation services (ATS) support may be used to allow the GPU(s) 808 to access the CPU(s) 806 page tables directly. In such examples, when the GPU(s) 808 memory management unit (MMU) experiences a miss, an address translation request may be transmitted to the CPU(s) 806. In response, the CPU(s) 806 may look in its page tables for the virtual-to-physical mapping for the address and transmits the translation back to the GPU(s) 808. As such, unified memory technology may allow a single unified virtual address space for memory of both the CPU(s) 806 and the GPU(s) 808, thereby simplifying the GPU(s) 808 programming and porting of applications to the GPU(s) 808. In some embodiments, one or more functions of the simulation processor 130, such as the USS array simulation model 110 may be implemented using code executed by CPU(s) 806 and/or GPU(s) 808.

In addition, the GPU(s) 808 may include an access counter that may keep track of the frequency of access of the GPU(s) 808 to memory of other processors. The access counter may help ensure that memory pages are moved to the physical memory of the processor that is accessing the pages most frequently.

The SoC(s) 804 may include any number of cache(s) 812, including those described herein. For example, the cache(s) 812 may include an L3 cache that is available to both the CPU(s) 806 and the GPU(s) 808 (e.g., that is connected both the CPU(s) 806 and the GPU(s) 808). The cache(s) 812 may include a write-back cache that may keep track of states of lines, such as by using a cache coherence protocol (e.g., MEI, MESI, MSI, etc.). The L3 cache may include 4 MB or more, depending on the embodiment, although smaller cache sizes may be used.

The SoC(s) 804 may include an arithmetic logic unit(s) (ALU(s)) which may be leveraged in performing processing with respect to any of the variety of tasks or operations of the vehicle 800—such as processing DNNs. In addition, the SoC(s) 804 may include a floating point unit(s) (FPU(s))—or other math coprocessor or numeric coprocessor types—for performing mathematical operations within the system. For example, the SoC(s) 804 may include one or more FPUs integrated as execution units within a CPU(s) 806 and/or GPU(s) 808.

The SoC(s) 804 may include one or more accelerators 814 (e.g., hardware accelerators, software accelerators, or a combination thereof). For example, the SoC(s) 804 may include a hardware acceleration cluster that may include optimized hardware accelerators and/or large on-chip memory. The large on-chip memory (e.g., 4MB of SRAM), may allow the hardware acceleration cluster to accelerate neural networks and other calculations. The hardware acceleration cluster may be used to complement the GPU(s) 808 and to off-load some of the tasks of the GPU(s) 808 (e.g., to free up more cycles of the GPU(s) 808 for performing other tasks). As an example, the accelerator(s) 814 may be used for targeted workloads (e.g., perception, convolutional neural networks (CNNs), etc.) that are stable enough to be amenable to acceleration. The term “CNN,” as used herein, may include all types of CNNs, including region-based or regional convolutional neural networks (RCNNs) and Fast RCNNs (e.g., as used for object detection).

The accelerator(s) 814 (e.g., the hardware acceleration cluster) may include a deep learning accelerator(s) (DLA). The DLA(s) may include one or more Tensor processing units (TPUs) that may be configured to provide an additional ten trillion operations per second for deep learning applications and inferencing. The TPUs may be accelerators configured to, and optimized for, performing image processing functions (e.g., for CNNs, RCNNs, etc.). The DLA(s) may further be optimized for a specific set of neural network types and floating point operations, as well as inferencing. The design of the DLA(s) may provide more performance per millimeter than a general-purpose GPU, and vastly exceeds the performance of a CPU. The TPU(s) may perform several functions, including a single-instance convolution function, supporting, for example, INT8, INT16, and FP16 data types for both features and weights, as well as post-processor functions.

The DLA(s) may quickly and efficiently execute neural networks, especially CNNs, on processed or unprocessed data for any of a variety of functions, including, for example and without limitation: a CNN for object identification and detection using data from camera sensors; a CNN for distance estimation using data from camera sensors; a CNN for emergency vehicle detection and identification and detection using data from microphones; a CNN for facial recognition and vehicle owner identification using data from camera sensors; and/or a CNN for security and/or safety related events.

The DLA(s) may perform any function of the GPU(s) 808, and by using an inference accelerator, for example, a designer may target either the DLA(s) or the GPU(s) 808 for any function. For example, the designer may focus processing of CNNs and floating point operations on the DLA(s) and leave other functions to the GPU(s) 808 and/or other accelerator(s) 814.

The accelerator(s) 814 (e.g., the hardware acceleration cluster) may include a programmable vision accelerator(s) (PVA), which may alternatively be referred to herein as a computer vision accelerator. The PVA(s) may be designed and configured to accelerate computer vision algorithms for the advanced driver assistance systems (ADAS), autonomous driving, and/or augmented reality (AR) and/or virtual reality (VR) applications. The PVA(s) may provide a balance between performance and flexibility. For example, each PVA(s) may include, for example and without limitation, any number of reduced instruction set computer (RISC) cores, direct memory access (DMA), and/or any number of vector processors.

The RISC cores may interact with image sensors (e.g., the image sensors of any of the cameras described herein), image signal processor(s), and/or the like. Each of the RISC cores may include any amount of memory. The RISC cores may use any of a number of protocols, depending on the embodiment. In some examples, the RISC cores may execute a real-time operating system (RTOS). The RISC cores may be implemented using one or more integrated circuit devices, application specific integrated circuits (ASICs), and/or memory devices. For example, the RISC cores may include an instruction cache and/or a tightly coupled RAM.

The DMA may allow components of the PVA(s) to access the system memory independently of the CPU(s) 806. The DMA may support any number of features used to provide optimization to the PVA including, but not limited to, supporting multi-dimensional addressing and/or circular addressing. In some examples, the DMA may support up to six or more dimensions of addressing, which may include block width, block height, block depth, horizontal block stepping, vertical block stepping, and/or depth stepping.

The vector processors may be programmable processors that may be designed to efficiently and flexibly execute programming for computer vision algorithms and provide signal processing capabilities. In some examples, the PVA may include a PVA core and two vector processing subsystem partitions. The PVA core may include a processor subsystem, DMA engine(s) (e.g., two DMA engines), and/or other peripherals. The vector processing subsystem may operate as the primary processing engine of the PVA, and may include a vector processing unit (VPU), an instruction cache, and/or vector memory (e.g., VMEM). A VPU core may include a digital signal processor such as, for example, a single instruction, multiple data (SIMD), very long instruction word (VLIW) digital signal processor. The combination of the SIMD and VLIW may enhance throughput and speed.

Each of the vector processors may include an instruction cache and may be coupled to dedicated memory. As a result, in some examples, each of the vector processors may be configured to execute independently of the other vector processors. In other examples, the vector processors that are included in a particular PVA may be configured to employ data parallelism. For example, in some embodiments, the plurality of vector processors included in a single PVA may execute the same computer vision algorithm, but on different regions of an image. In other examples, the vector processors included in a particular PVA may simultaneously execute different computer vision algorithms, on the same image, or even execute different algorithms on sequential images or portions of an image. Among other things, any number of PVAs may be included in the hardware acceleration cluster and any number of vector processors may be included in each of the PVAs. In addition, the PVA(s) may include additional error correcting code (ECC) memory, to enhance overall system safety.

The accelerator(s) 814 (e.g., the hardware acceleration cluster) may include a computer vision network on-chip and SRAM, for providing a high-bandwidth, low latency SRAM for the accelerator(s) 814. In some examples, the on-chip memory may include at least 4MB SRAM, consisting of, for example and without limitation, eight field-configurable memory blocks, that may be accessible by both the PVA and the DLA. Each pair of memory blocks may include an advanced peripheral bus (APB) interface, configuration circuitry, a controller, and a multiplexer. Any type of memory may be used. The PVA and DLA may access the memory via a backbone that provides the PVA and DLA with high-speed access to memory. The backbone may include a computer vision network on-chip that interconnects the PVA and the DLA to the memory (e.g., using the APB).

The computer vision network on-chip may include an interface that determines, before transmission of any control signal/address/data, that both the PVA and the DLA provide ready and valid signals. Such an interface may provide for separate phases and separate channels for transmitting control signals/addresses/data, as well as burst-type communications for continuous data transfer. This type of interface may comply with ISO 26262 or IEC 61508 standards, although other standards and protocols may be used.

In some examples, the SoC(s) 804 may include a real-time ray-tracing hardware accelerator, such as described in U.S. patent application Ser. No. 16/101,232, filed on Aug. 10, 2018. The real-time ray-tracing hardware accelerator may be used to quickly and efficiently determine the positions and extents of objects (e.g., within a world model), to generate real-time visualization simulations, for RADAR signal interpretation, for sound propagation synthesis and/or analysis, for simulation of SONAR systems, for general wave propagation simulation, for comparison to LiDAR data for purposes of localization and/or other functions, and/or for other uses. In some embodiments, one or more tree traversal units (TTUs) may be used for executing one or more ray-tracing related operations.

The accelerator(s) 814 (e.g., the hardware accelerator cluster) have a wide array of uses for autonomous driving. The PVA may be a programmable vision accelerator that may be used for key processing stages in ADAS and autonomous vehicles. The PVA's capabilities are a good match for algorithmic domains needing predictable processing, at low power and low latency. As such, the PVA performs well on semi-dense or dense regular computation, even on small data sets, which need predictable run-times with low latency and low power. Thus, in the context of platforms for autonomous vehicles, the PVAs are designed to run classic computer vision algorithms, as they are efficient at object detection and operating on integer math.

For example, according to one embodiment of the technology, the PVA is used to perform computer stereo vision. A semi-global matching-based algorithm may be used in some examples, although this is not intended to be limiting. Many applications for Level 3-5 autonomous driving require motion estimation/stereo matching on-the-fly (e.g., structure from motion, pedestrian recognition, lane detection, etc.). The PVA may perform computer stereo vision function on inputs from two monocular cameras.

In some examples, the PVA may be used to perform dense optical flow. According to process raw RADAR data (e.g., using a 4D Fast Fourier Transform) to provide Processed RADAR. In other examples, the PVA is used for time of flight depth processing, by processing raw time of flight data to provide processed time of flight data, for example.

The DLA may be used to run any type of network to enhance control and driving safety, including for example, a neural network that outputs a measure of confidence for each object detection. Such a confidence value may be interpreted as a probability, or as providing a relative “weight” of each detection compared to other detections. This confidence value enables the system to make further decisions regarding which detections should be considered as true positive detections rather than false positive detections. For example, the system may set a threshold value for the confidence and consider only the detections exceeding the threshold value as true positive detections. In an automatic emergency braking (AEB) system, false positive detections would cause the vehicle to automatically perform emergency braking, which is obviously undesirable. Therefore, only the most confident detections should be considered as triggers for AEB. The DLA may run a neural network for regressing the confidence value. The neural network may take as its input at least some subset of parameters, such as bounding box dimensions, ground plane estimate obtained (e.g. from another subsystem), inertial measurement unit (IMU) sensor 866 output that correlates with the vehicle 800 orientation, distance, 3D location estimates of the object obtained from the neural network and/or other sensors (e.g., LiDAR sensor(s) 864 or RADAR sensor(s) 860), among others.

The SoC(s) 804 may include data store(s) 816 (e.g., memory). The data store(s) 816 may be on-chip memory of the SoC(s) 804, which may store neural networks to be executed on the GPU and/or the DLA. In some examples, the data store(s) 816 may be large enough in capacity to store multiple instances of neural networks for redundancy and safety. The data store(s) 816 may comprise L2 or L3 cache(s) 812. Reference to the data store(s) 816 may include reference to the memory associated with the PVA, DLA, and/or other accelerator(s) 814, as described herein.

The SoC(s) 804 may include one or more processor(s) 810 (e.g., embedded processors). The processor(s) 810 may include a boot and power management processor that may be a dedicated processor and subsystem to handle boot power and management functions and related security enforcement. The boot and power management processor may be a part of the SoC(s) 804 boot sequence and may provide runtime power management services. The boot power and management processor may provide clock and voltage programming, assistance in system low power state transitions, management of SoC(s) 804 thermals and temperature sensors, and/or management of the SoC(s) 804 power states. Each temperature sensor may be implemented as a ring-oscillator whose output frequency is proportional to temperature, and the SoC(s) 804 may use the ring-oscillators to detect temperatures of the CPU(s) 806, GPU(s) 808, and/or accelerator(s) 814. If temperatures are determined to exceed a threshold, the boot and power management processor may enter a temperature fault routine and put the SoC(s) 804 into a lower power state and/or put the vehicle 800 into a chauffeur to safe stop mode (e.g., bring the vehicle 800 to a safe stop).

The processor(s) 810 may further include a set of embedded processors that may serve as an audio processing engine. The audio processing engine may be an audio subsystem that enables full hardware support for multi-channel audio over multiple interfaces, and a broad and flexible range of audio I/O interfaces. In some examples, the audio processing engine is a dedicated processor core with a digital signal processor with dedicated RAM.

The processor(s) 810 may further include an always on processor engine that may provide necessary hardware features to support low power sensor management and wake use cases. The always on processor engine may include a processor core, a tightly coupled RAM, supporting peripherals (e.g., timers and interrupt controllers), various I/O controller peripherals, and routing logic.

The processor(s) 810 may further include a safety cluster engine that includes a dedicated processor subsystem to handle safety management for automotive applications. The safety cluster engine may include two or more processor cores, a tightly coupled RAM, support peripherals (e.g., timers, an interrupt controller, etc.), and/or routing logic. In a safety mode, the two or more cores may operate in a lockstep mode and function as a single core with comparison logic to detect any differences between their operations.

The processor(s) 810 may further include a real-time camera engine that may include a dedicated processor subsystem for handling real-time camera management.

The processor(s) 810 may further include a high-dynamic range signal processor that may include an image signal processor that is a hardware engine that is part of the camera processing pipeline.

The processor(s) 810 may include a video image compositor that may be a processing block (e.g., implemented on a microprocessor) that implements video post-processing functions needed by a video playback application to produce the final image for the player window. The video image compositor may perform lens distortion correction on wide-view camera(s) 870, surround camera(s) 874, and/or on in-cabin monitoring camera sensors. In-cabin monitoring camera sensor is preferably monitored by a neural network running on another instance of the Advanced SoC, configured to identify in cabin events and respond accordingly. An in-cabin system may perform lip reading to activate cellular service and place a phone call, dictate emails, change the vehicle's destination, activate or change the vehicle's infotainment system and settings, or provide voice-activated web surfing. Certain functions are available to the driver only when the vehicle is operating in an autonomous mode, and are disabled otherwise.

The video image compositor may include enhanced temporal noise reduction for both spatial and temporal noise reduction. For example, where motion occurs in a video, the noise reduction weights spatial information appropriately, decreasing the weight of information provided by adjacent frames. Where an image or portion of an image does not include motion, the temporal noise reduction performed by the video image compositor may use information from the previous image to reduce noise in the current image.

The video image compositor may also be configured to perform stereo rectification on input stereo lens frames. The video image compositor may further be used for user interface composition when the operating system desktop is in use, and the GPU(s) 808 is not required to continuously render new surfaces. Even when the GPU(s) 808 is powered on and active doing 3D rendering, the video image compositor may be used to offload the GPU(s) 808 to improve performance and responsiveness.

The SoC(s) 804 may further include a mobile industry processor interface (MIPI) camera serial interface for receiving video and input from cameras, a high-speed interface, and/or a video input block that may be used for camera and related pixel input functions. The SoC(s) 804 may further include an input/output controller(s) that may be controlled by software and may be used for receiving I/O signals that are uncommitted to a specific role.

The SoC(s) 804 may further include a broad range of peripheral interfaces to allow communication with peripherals, audio codecs, power management, and/or other devices. The SoC(s) 804 may be used to process data from cameras (e.g., connected over Gigabit Multimedia Serial Link and Ethernet), sensors (e.g., LiDAR sensor(s) 864, RADAR sensor(s) 860, etc. that may be connected over Ethernet), data from bus 802 (e.g., speed of vehicle 800, steering wheel position, etc.), data from GNSS sensor(s) 858 (e.g., connected over Ethernet or CAN bus). The SoC(s) 804 may further include dedicated high-performance mass storage controllers that may include their own DMA engines, and that may be used to free the CPU(s) 806 from routine data management tasks.

The SoC(s) 804 may be an end-to-end platform with a flexible architecture that spans automation levels 3-5, thereby providing a comprehensive functional safety architecture that leverages and makes efficient use of computer vision and ADAS techniques for diversity and redundancy, provides a platform for a flexible, reliable driving software stack, along with deep learning tools. The SoC(s) 804 may be faster, more reliable, and even more energy-efficient and space-efficient than conventional systems. For example, the accelerator(s) 814, when combined with the CPU(s) 806, the GPU(s) 808, and the data store(s) 816, may provide for a fast, efficient platform for level 3-5 autonomous vehicles.

The technology thus provides capabilities and functionality that cannot be achieved by conventional systems. For example, computer vision algorithms may be executed on CPUs, which may be configured using high-level programming language, such as the C programming language, to execute a wide variety of processing algorithms across a wide variety of visual data. However, CPUs are oftentimes unable to meet the performance requirements of many computer vision applications, such as those related to execution time and power consumption, for example. In particular, many CPUs are unable to execute complex object detection algorithms in real-time, which is a requirement of in-vehicle ADAS applications, and a requirement for practical Level 3-5 autonomous vehicles.

In contrast to conventional systems, by providing a CPU complex, GPU complex, and a hardware acceleration cluster, the technology described herein allows for multiple neural networks to be performed simultaneously and/or sequentially, and for the results to be combined together to allow Level 3-5 autonomous driving functionality. For example, a CNN executing on the DLA or dGPU (e.g., the GPU(s) 820) may include a text and word recognition, allowing the supercomputer to read and understand traffic signs, including signs for which the neural network has not been specifically trained. The DLA may further include a neural network that is able to identify, interpret, and provides semantic understanding of the sign, and to pass that semantic understanding to the path planning modules running on the CPU Complex.

As another example, multiple neural networks may be run simultaneously, as is required for Level 3, 4, or 5 driving. For example, a warning sign consisting of “Caution: flashing lights indicate icy conditions,” along with an electric light, may be independently or collectively interpreted by several neural networks. The sign itself may be identified as a traffic sign by a first deployed neural network (e.g., a neural network that has been trained), the text “Flashing lights indicate icy conditions” may be interpreted by a second deployed neural network, which informs the vehicle's path planning software (preferably executing on the CPU Complex) that when flashing lights are detected, icy conditions exist. The flashing light may be identified by operating a third deployed neural network over multiple frames, informing the vehicle's path-planning software of the presence (or absence) of flashing lights. All three neural networks may run simultaneously, such as within the DLA and/or on the GPU(s) 808.

In some examples, a CNN for facial recognition and vehicle owner identification may use data from camera sensors to identify the presence of an authorized driver and/or owner of the vehicle 800. The always on sensor processing engine may be used to unlock the vehicle when the owner approaches the driver door and turn on the lights, and, in security mode, to disable the vehicle when the owner leaves the vehicle. In this way, the SoC(s) 804 provide for security against theft and/or carjacking.

In another example, a CNN for emergency vehicle detection and identification may use data from microphones 896 to detect and identify emergency vehicle sirens. In contrast to conventional systems, that use general classifiers to detect sirens and manually extract features, the SoC(s) 804 use the CNN for classifying environmental and urban sounds, as well as classifying visual data. In a preferred embodiment, the CNN running on the DLA is trained to identify the relative closing speed of the emergency vehicle (e.g., by using the Doppler Effect). The CNN may also be trained to identify emergency vehicles specific to the local area in which the vehicle is operating, as identified by GNSS sensor(s) 858. Thus, for example, when operating in Europe the CNN will seek to detect European sirens, and when in the United States the CNN will seek to identify only North American sirens. Once an emergency vehicle is detected, a control program may be used to execute an emergency vehicle safety routine, slowing the vehicle, pulling over to the side of the road, parking the vehicle, and/or idling the vehicle, with the assistance of ultrasonic sensors 862, until the emergency vehicle(s) passes.

The vehicle may include a CPU(s) 818 (e.g., discrete CPU(s), or dCPU(s)), that may be coupled to the SoC(s) 804 via a high-speed interconnect (e.g., PCIe). The CPU(s) 818 may include an X86 processor, for example. The CPU(s) 818 may be used to perform any of a variety of functions, including arbitrating potentially inconsistent results between ADAS sensors and the SoC(s) 804, and/or monitoring the status and health of the controller(s) 836 and/or infotainment SoC 830, for example.

The vehicle 800 may include a GPU(s) 820 (e.g., discrete GPU(s), or dGPU(s)), that may be coupled to the SoC(s) 804 via a high-speed interconnect (e.g., NVIDIA's NVLINK). The GPU(s) 820 may provide additional artificial intelligence functionality, such as by executing redundant and/or different neural networks, and may be used to train and/or update neural networks based on input (e.g., sensor data) from sensors of the vehicle 800.

The vehicle 800 may further include the network interface 824 which may include one or more wireless antennas 826 (e.g., one or more wireless antennas for different communication protocols, such as a cellular antenna, a Bluetooth antenna, etc.). The network interface 824 may be used to allow wireless connectivity over the Internet with the cloud (e.g., with the server(s) 878 and/or other network devices), with other vehicles, and/or with computing devices (e.g., client devices of passengers). To communicate with other vehicles, a direct link may be established between the two vehicles and/or an indirect link may be established (e.g., across networks and over the Internet). Direct links may be provided using a vehicle-to-vehicle communication link. The vehicle-to-vehicle communication link may provide the vehicle 800 information about vehicles in proximity to the vehicle 800 (e.g., vehicles in front of, on the side of, and/or behind the vehicle 800). This functionality may be part of a cooperative adaptive cruise control functionality of the vehicle 800.

The network interface 824 may include a SoC that provides modulation and demodulation functionality and enables the controller(s) 836 to communicate over wireless networks. The network interface 824 may include a radio frequency front-end for up-conversion from baseband to radio frequency, and down conversion from radio frequency to baseband. The frequency conversions may be performed through well-known processes, and/or may be performed using super-heterodyne processes. In some examples, the radio frequency front end functionality may be provided by a separate chip. The network interface may include wireless functionality for communicating over LTE, WCDMA, UMTS, GSM, CDMA2000, Bluetooth, Bluetooth LE, Wi-Fi, Z-Wave, ZigBee, LoRaWAN, and/or other wireless protocols.

The vehicle 800 may further include data store(s) 828 which may include off-chip (e.g., off the SoC(s) 804) storage. The data store(s) 828 may include one or more storage elements including RAM, SRAM, DRAM, VRAM, Flash, hard disks, and/or other components and/or devices that may store at least one bit of data.

The vehicle 800 may further include GNSS sensor(s) 858. The GNSS sensor(s) 858 (e.g., GPS, assisted GPS sensors, differential GPS (DGPS) sensors, etc.), to assist in mapping, perception, occupancy grid generation, and/or path planning functions. Any number of GNSS sensor(s) 858 may be used, including, for example and without limitation, a GPS using a USB connector with an Ethernet to Serial (RS-232) bridge.

The vehicle 800 may further include RADAR sensor(s) 860. The RADAR sensor(s) 860 may be used by the vehicle 800 for long-range vehicle detection, even in darkness and/or severe weather conditions. RADAR functional safety levels may be ASIL B. The RADAR sensor(s) 860 may use the CAN and/or the bus 802 (e.g., to transmit data generated using the RADAR sensor(s) 860) for control and to access object tracking data, with access to Ethernet to access raw data in some examples. A wide variety of RADAR sensor types may be used. For example, and without limitation, the RADAR sensor(s) 860 may be suitable for front, rear, and side RADAR use. In some example, Pulse Doppler RADAR sensor(s) are used.

The RADAR sensor(s) 860 may include different configurations, such as long range with narrow field of view, short range with wide field of view, short range side coverage, etc. In some examples, long-range RADAR may be used for adaptive cruise control functionality. The long-range RADAR systems may provide a broad field of view realized by two or more independent scans, such as within a 250 m range. The RADAR sensor(s) 860 may help in distinguishing between static and moving objects, and may be used by ADAS systems for emergency brake assist and forward collision warning. Long-range RADAR sensors may include monostatic multimodal RADAR with multiple (e.g., six or more) fixed RADAR antennae and a high-speed CAN and FlexRay interface. In an example with six antennae, the central four antennae may create a focused beam pattern, designed to record the vehicle's 800 surroundings at higher speeds with minimal interference from traffic in adjacent lanes. The other two antennae may expand the field of view, making it possible to quickly detect vehicles entering or leaving the vehicle's 800 lane.

Mid-range RADAR systems may include, as an example, a range of up to 860 m (front) or 80 m (rear), and a field of view of up to 42 degrees (front) or 850 degrees (rear). Short-range RADAR systems may include, without limitation, RADAR sensors designed to be installed at both ends of the rear bumper. When installed at both ends of the rear bumper, such a RADAR sensor systems may create two beams that constantly monitor the blind spot in the rear and next to the vehicle.

Short-range RADAR systems may be used in an ADAS system for blind spot detection and/or lane change assist.

The vehicle 800 may further include ultrasonic sensor(s) 862. The ultrasonic sensor(s) 862, which may be positioned at the front, back, and/or the sides of the vehicle 800, may be used for park assist and/or to create and update an occupancy grid. A wide variety of ultrasonic sensor(s) 862 may be used, and different ultrasonic sensor(s) 862 may be used for different ranges of detection (e.g., 2.5 m, 4 m). The ultrasonic sensor(s) 862 may operate at functional safety levels of ASIL B. In some embodiments, the USS array simulation model 110 described herein may produce USS measurement data simulating measurement data as produced by one or more of such ultrasonic sensor(s) 862.

The vehicle 800 may include LiDAR sensor(s) 864. The LiDAR sensor(s) 864 may be used for object and pedestrian detection, emergency braking, collision avoidance, and/or other functions. The LiDAR sensor(s) 864 may be functional safety level ASIL B. In some examples, the vehicle 800 may include multiple LiDAR sensors 864 (e.g., two, four, six, etc.) that may use Ethernet (e.g., to provide data to a Gigabit Ethernet switch).

In some examples, the LiDAR sensor(s) 864 may be capable of providing a list of objects and their distances for a 360-degree field of view. Commercially available LiDAR sensor(s) 864 may have an advertised range of approximately 800 m, with an accuracy of 2 cm-3 cm, and with support for a 800 Mbps Ethernet connection, for example. In some examples, one or more non-protruding LiDAR sensors 864 may be used. In such examples, the LiDAR sensor(s) 864 may be implemented as a small device that may be embedded into the front, rear, sides, and/or corners of the vehicle 800. The LiDAR sensor(s) 864, in such examples, may provide up to a 120-degree horizontal and 35-degree vertical field-of-view, with a 200 m range even for low-reflectivity objects. Front-mounted LiDAR sensor(s) 864 may be configured for a horizontal field of view between 45 degrees and 135 degrees.

In some examples, LiDAR technologies, such as 3D flash LiDAR, may also be used. 3D Flash LiDAR uses a flash of a laser as a transmission source, to illuminate vehicle surroundings up to approximately 200 m. A flash LiDAR unit includes a receptor, which records the laser pulse transit time and the reflected light on each pixel, which in turn corresponds to the range from the vehicle to the objects. Flash LiDAR may allow for highly accurate and distortion-free images of the surroundings to be generated with every laser flash. In some examples, four flash LiDAR sensors may be deployed, one at each side of the vehicle 800. Available 3D flash LiDAR systems include a solid-state 3D staring array LiDAR camera with no moving parts other than a fan (e.g., a non-scanning LiDAR device). The flash LiDAR device may use a 5 nanosecond class I (eye-safe) laser pulse per frame and may capture the reflected laser light in the form of 3D range point clouds and co-registered intensity data. By using flash LiDAR, and because flash LiDAR is a solid-state device with no moving parts, the LiDAR sensor(s) 864 may be less susceptible to motion blur, vibration, and/or shock.

The vehicle may further include IMU sensor(s) 866. The IMU sensor(s) 866 may be located at a center of the rear axle of the vehicle 800, in some examples. The IMU sensor(s) 866 may include, for example and without limitation, an accelerometer(s), a magnetometer(s), a gyroscope(s), a magnetic compass(es), and/or other sensor types. In some examples, such as in six-axis applications, the IMU sensor(s) 866 may include accelerometers and gyroscopes, while in nine-axis applications, the IMU sensor(s) 866 may include accelerometers, gyroscopes, and magnetometers.

In some embodiments, the IMU sensor(s) 866 may be implemented as a miniature, high performance GPS-Aided Inertial Navigation System (GPS/INS) that combines micro-electro-mechanical systems (MEMS) inertial sensors, a high-sensitivity GPS receiver, and advanced Kalman filtering algorithms to provide estimates of position, velocity, and attitude. As such, in some examples, the IMU sensor(s) 866 may allow the vehicle 800 to estimate heading without requiring input from a magnetic sensor by directly observing and correlating the changes in velocity from GPS to the IMU sensor(s) 866. In some examples, the IMU sensor(s) 866 and the GNSS sensor(s) 858 may be combined in a single integrated unit.

The vehicle may include microphone(s) 896 placed in and/or around the vehicle 800. The microphone(s) 896 may be used for emergency vehicle detection and identification, among other things.

The vehicle may further include any number of camera types, including stereo camera(s) 868, wide-view camera(s) 870, infrared camera(s) 872, surround camera(s) 874, long-range and/or mid-range camera(s) 898, and/or other camera types. The cameras may be used to capture image data around an entire periphery of the vehicle 800. The types of cameras used depends on the embodiments and requirements for the vehicle 800, and any combination of camera types may be used to provide the necessary coverage around the vehicle 800. In addition, the number of cameras may differ depending on the embodiment. For example, the vehicle may include six cameras, seven cameras, ten cameras, twelve cameras, and/or another number of cameras. The cameras may support, as an example and without limitation, Gigabit Multimedia Serial Link (GMSL) and/or Gigabit Ethernet. Each of the camera(s) is described with more detail herein with respect to FIG. 8A and FIG. 8B.

The vehicle 800 may further include vibration sensor(s) 842. The vibration sensor(s) 842 may measure vibrations of components of the vehicle, such as the axle(s). For example, changes in vibrations may indicate a change in road surfaces. In another example, when two or more vibration sensors 842 are used, the differences between the vibrations may be used to determine friction or slippage of the road surface (e.g., when the difference in vibration is between a power-driven axle and a freely rotating axle).

The vehicle 800 may include an ADAS system 838. The ADAS system 838 may include a SoC, in some examples. The ADAS system 838 may include autonomous/adaptive/automatic cruise control (ACC), cooperative adaptive cruise control (CACC), forward crash warning (FCW), automatic emergency braking (AEB), lane departure warnings (LDW), lane keep assist (LKA), blind spot warning (BSW), rear cross-traffic warning (RCTW), collision warning systems (CWS), lane centering (LC), and/or other features and functionality.

The ACC systems may use RADAR sensor(s) 860, LiDAR sensor(s) 864, and/or a camera(s). The ACC systems may include longitudinal ACC and/or lateral ACC. Longitudinal ACC monitors and controls the distance to the vehicle immediately ahead of the vehicle 800 and automatically adjust the vehicle speed to maintain a safe distance from vehicles ahead. Lateral ACC performs distance keeping, and advises the vehicle 800 to change lanes when necessary. Lateral ACC is related to other ADAS applications such as LCA and CWS.

CACC uses information from other vehicles that may be received via the network interface 824 and/or the wireless antenna(s) 826 from other vehicles via a wireless link, or indirectly, over a network connection (e.g., over the Internet). Direct links may be provided by a vehicle-to-vehicle (V2V) communication link, while indirect links may be infrastructure-to-vehicle (I2V) communication link. In general, the V2V communication concept provides information about the immediately preceding vehicles (e.g., vehicles immediately ahead of and in the same lane as the vehicle 800), while the I2V communication concept provides information about traffic further ahead. CACC systems may include either or both I2V and V2V information sources. Given the information of the vehicles ahead of the vehicle 800, CACC may be more reliable and it has potential to improve traffic flow smoothness and reduce congestion on the road.

FCW systems are designed to alert the driver to a hazard, so that the driver may take corrective action. FCW systems use a front-facing camera and/or RADAR sensor(s) 860, coupled to a dedicated processor, DSP, FPGA, and/or ASIC, that is electrically coupled to driver feedback, such as a display, speaker, and/or vibrating component. FCW systems may provide a warning, such as in the form of a sound, visual warning, vibration and/or a quick brake pulse.

AEB systems detect an impending forward collision with another vehicle or other object, and may automatically apply the brakes if the driver does not take corrective action within a specified time or distance parameter. AEB systems may use front-facing camera(s) and/or RADAR sensor(s) 860, coupled to a dedicated processor, DSP, FPGA, and/or ASIC. When the AEB system detects a hazard, it typically first alerts the driver to take corrective action to avoid the collision and, if the driver does not take corrective action, the AEB system may automatically apply the brakes in an effort to prevent, or at least mitigate, the impact of the predicted collision. AEB systems, may include techniques such as dynamic brake support and/or crash imminent braking.

LDW systems provide visual, audible, and/or tactile warnings, such as steering wheel or seat vibrations, to alert the driver when the vehicle 800 crosses lane markings. A LDW system does not activate when the driver indicates an intentional lane departure, by activating a turn signal. LDW systems may use front-side facing cameras, coupled to a dedicated processor, DSP, FPGA, and/or ASIC, that is electrically coupled to driver feedback, such as a display, speaker, and/or vibrating component.

LKA systems are a variation of LDW systems. LKA systems provide steering input or braking to correct the vehicle 800 if the vehicle 800 starts to exit the lane.

BSW systems detects and warn the driver of vehicles in an automobile's blind spot. BSW systems may provide a visual, audible, and/or tactile alert to indicate that merging or changing lanes is unsafe. The system may provide an additional warning when the driver uses a turn signal. BSW systems may use rear-side facing camera(s) and/or RADAR sensor(s) 860, coupled to a dedicated processor, DSP, FPGA, and/or ASIC, that is electrically coupled to driver feedback, such as a display, speaker, and/or vibrating component.

RCTW systems may provide visual, audible, and/or tactile notification when an object is detected outside the rear-camera range when the vehicle 800 is backing up. Some RCTW systems include AEB to ensure that the vehicle brakes are applied to avoid a crash. RCTW systems may use one or more rear-facing RADAR sensor(s) 860, coupled to a dedicated processor, DSP, FPGA, and/or ASIC, that is electrically coupled to driver feedback, such as a display, speaker, and/or vibrating component.

Conventional ADAS systems may be prone to false positive results which may be annoying and distracting to a driver, but typically are not catastrophic, because the ADAS systems alert the driver and allow the driver to decide whether a safety condition truly exists and act accordingly. However, in an autonomous vehicle 800, the vehicle 800 itself must, in the case of conflicting results, decide whether to heed the result from a primary computer or a secondary computer (e.g., a first controller 836 or a second controller 836). For example, in some embodiments, the ADAS system 838 may be a backup and/or secondary computer for providing perception information to a backup computer rationality module. The backup computer rationality monitor may run a redundant diverse software on hardware components to detect faults in perception and dynamic driving tasks. Outputs from the ADAS system 838 may be provided to a supervisory MCU. If outputs from the primary computer and the secondary computer conflict, the supervisory MCU must determine how to reconcile the conflict to ensure safe operation.

In some examples, the primary computer may be configured to provide the supervisory MCU with a confidence score, indicating the primary computer's confidence in the chosen result. If the confidence score exceeds a threshold, the supervisory MCU may follow the primary computer's direction, regardless of whether the secondary computer provides a conflicting or inconsistent result. Where the confidence score does not meet the threshold, and where the primary and secondary computer indicate different results (e.g., the conflict), the supervisory MCU may arbitrate between the computers to determine the appropriate outcome.

The supervisory MCU may be configured to run a neural network(s) that is trained and configured to determine, based on outputs from the primary computer and the secondary computer, conditions under which the secondary computer provides false alarms. Thus, the neural network(s) in the supervisory MCU may learn when the secondary computer's output may be trusted, and when it cannot. For example, when the secondary computer is a RADAR-based FCW system, a neural network(s) in the supervisory MCU may learn when the FCW system is identifying metallic objects that are not, in fact, hazards, such as a drainage grate or manhole cover that triggers an alarm. Similarly, when the secondary computer is a camera-based LDW system, a neural network in the supervisory MCU may learn to override the LDW when bicyclists or pedestrians are present and a lane departure is, in fact, the safest maneuver. In embodiments that include a neural network(s) running on the supervisory MCU, the supervisory MCU may include at least one of a DLA or GPU suitable for running the neural network(s) with associated memory. In preferred embodiments, the supervisory MCU may comprise and/or be included as a component of the SoC(s) 804.

In other examples, ADAS system 838 may include a secondary computer that performs ADAS functionality using traditional rules of computer vision. As such, the secondary computer may use classic computer vision rules (if-then), and the presence of a neural network(s) in the supervisory MCU may improve reliability, safety and performance. For example, the diverse implementation and intentional non-identity makes the overall system more fault-tolerant, especially to faults caused by software (or software-hardware interface) functionality. For example, if there is a software bug or error in the software running on the primary computer, and the non-identical software code running on the secondary computer provides the same overall result, the supervisory MCU may have greater confidence that the overall result is correct, and the bug in software or hardware on primary computer is not causing material error.

In some examples, the output of the ADAS system 838 may be fed into the primary computer's perception block and/or the primary computer's dynamic driving task block. For example, if the ADAS system 838 indicates a forward crash warning due to an object immediately ahead, the perception block may use this information when identifying objects. In other examples, the secondary computer may have its own neural network which is trained and thus reduces the risk of false positives, as described herein.

The vehicle 800 may further include the infotainment SoC 830 (e.g., an in-vehicle infotainment system (IVI)). Although illustrated and described as a SoC, the infotainment system may not be a SoC, and may include two or more discrete components. The infotainment SoC 830 may include a combination of hardware and software that may be used to provide audio (e.g., music, a personal digital assistant, navigational instructions, news, radio, etc.), video (e.g., TV, movies, streaming, etc.), phone (e.g., hands-free calling), network connectivity (e.g., LTE, Wi-Fi, etc.), and/or information services (e.g., navigation systems, rear-parking assistance, a radio data system, vehicle related information such as fuel level, total distance covered, brake fuel level, oil level, door open/close, air filter information, etc.) to the vehicle 800. For example, the infotainment SoC 830 may radios, disk players, navigation systems, video players, USB and Bluetooth connectivity, carputers, in-car entertainment, Wi-Fi, steering wheel audio controls, hands free voice control, a heads-up display (HUD), an HMI display 834, a telematics device, a control panel (e.g., for controlling and/or interacting with various components, features, and/or systems), and/or other components. The infotainment SoC 830 may further be used to provide information (e.g., visual and/or audible) to a user(s) of the vehicle, such as information from the ADAS system 838, autonomous driving information such as planned vehicle maneuvers, trajectories, surrounding environment information (e.g., intersection information, vehicle information, road information, etc.), and/or other information.

The infotainment SoC 830 may include GPU functionality. The infotainment SoC 830 may communicate over the bus 802 (e.g., CAN bus, Ethernet, etc.) with other devices, systems, and/or components of the vehicle 800. In some examples, the infotainment SoC 830 may be coupled to a supervisory MCU such that the GPU of the infotainment system may perform some self-driving functions in the event that the primary controller(s) 836 (e.g., the primary and/or backup computers of the vehicle 800) fail. In such an example, the infotainment SoC 830 may put the vehicle 800 into a chauffeur to safe stop mode, as described herein.

The vehicle 800 may further include an instrument cluster 832 (e.g., a digital dash, an electronic instrument cluster, a digital instrument panel, etc.). The instrument cluster 832 may include a controller and/or supercomputer (e.g., a discrete controller or supercomputer). The instrument cluster 832 may include a set of instrumentation such as a speedometer, fuel level, oil pressure, tachometer, odometer, turn indicators, gearshift position indicator, seat belt warning light(s), parking-brake warning light(s), engine-malfunction light(s), airbag (SRS) system information, lighting controls, safety system controls, navigation information, etc. In some examples, information may be displayed and/or shared among the infotainment SoC 830 and the instrument cluster 832. As such, the instrument cluster 832 may be included as part of the infotainment SoC 830, or vice versa.

FIG. 8D is a system diagram for communication between cloud-based server(s) and the example autonomous vehicle 800 of FIG. 8A, in accordance with some embodiments of the present disclosure. The system 876 may include server(s) 878, network(s) 890, and vehicles, including the vehicle 800. The server(s) 878 may include a plurality of GPUs 884(A)-884(H) (collectively referred to herein as GPUs 884), PCIe switches 882(A)-882(D) (collectively referred to herein as PCIe switches 882), and/or CPUs 880(A)-880(B) (collectively referred to herein as CPUs 880). The GPUs 884, the CPUs 880, and the PCIe switches may be interconnected with high-speed interconnects such as, for example and without limitation, NVLink interfaces 888 developed by NVIDIA and/or PCIe connections 886. In some examples, the GPUs 884 are connected via NVLink and/or NVSwitch SoC and the GPUs 884 and the PCIe switches 882 are connected via PCIe interconnects. Although eight GPUs 884, two CPUs 880, and two PCIe switches are illustrated, this is not intended to be limiting. Depending on the embodiment, each of the server(s) 878 may include any number of GPUs 884, CPUs 880, and/or PCIe switches. For example, the server(s) 878 may each include eight, sixteen, thirty-two, and/or more GPUs 884. In some embodiments, one or more functions of the simulation processor 130, such as the USS array simulation model 110 may be implemented using code executed by CPU(s) 884 and/or GPU(s) 884.

The server(s) 878 may receive, over the network(s) 890 and from the vehicles, image data representative of images showing unexpected or changed road conditions, such as recently commenced road-work. The server(s) 878 may transmit, over the network(s) 890 and to the vehicles, neural networks 892, updated neural networks 892, and/or map information 894, including information regarding traffic and road conditions. The updates to the map information 894 may include updates for the HD map 822, such as information regarding construction sites, potholes, detours, flooding, and/or other obstructions. In some examples, the neural networks 892, the updated neural networks 892, and/or the map information 894 may have resulted from new training and/or experiences represented in data received from any number of vehicles in the environment, and/or based on training performed at a datacenter (e.g., using the server(s) 878 and/or other servers).

The server(s) 878 may be used to train machine learning models (e.g., neural networks) based on training data. The training data may be generated using the vehicles, and/or may be generated in a simulation (e.g., using a game engine). In some examples, the training data is tagged (e.g., where the neural network benefits from supervised learning) and/or undergoes other pre-processing, while in other examples the training data is not tagged and/or pre-processed (e.g., where the neural network does not require supervised learning). Training may be executed according to any one or more classes of machine learning techniques, including, without limitation, classes such as: supervised training, semi-supervised training, unsupervised training, self-learning, reinforcement learning, federated learning, transfer learning, feature learning (including principal component and cluster analyses), multi-linear subspace learning, manifold learning, representation learning (including spare dictionary learning), rule-based machine learning, anomaly detection, and any variants or combinations therefor. Once the machine learning models are trained, the machine learning models may be used by the vehicles (e.g., transmitted to the vehicles over the network(s) 890, and/or the machine learning models may be used by the server(s) 878 to remotely monitor the vehicles. In some embodiments, training data may comprise or otherwise be derived from USS measurement data 126 computed by the USS array simulation model 110.

In some examples, the server(s) 878 may receive data from the vehicles and apply the data to up-to-date real-time neural networks for real-time intelligent inferencing. The server(s) 878 may include deep-learning supercomputers and/or dedicated AI computers powered by GPU(s) 884, such as a DGX and DGX Station machines developed by NVIDIA. However, in some examples, the server(s) 878 may include deep learning infrastructure that use only CPU-powered datacenters.

The deep-learning infrastructure of the server(s) 878 may be capable of fast, real-time inferencing, and may use that capability to evaluate and verify the health of the processors, software, and/or associated hardware in the vehicle 800. For example, the deep-learning infrastructure may receive periodic updates from the vehicle 800, such as a sequence of images and/or objects that the vehicle 800 has located in that sequence of images (e.g., via computer vision and/or other machine learning object classification techniques). The deep-learning infrastructure may run its own neural network to identify the objects and compare them with the objects identified by the vehicle 800 and, if the results do not match and the infrastructure concludes that the AI in the vehicle 800 is malfunctioning, the server(s) 878 may transmit a signal to the vehicle 800 instructing a fail-safe computer of the vehicle 800 to assume control, notify the passengers, and complete a safe parking maneuver.

For inferencing, the server(s) 878 may include the GPU(s) 884 and one or more programmable inference accelerators (e.g., NVIDIA's TensorRT). The combination of GPU-powered servers and inference acceleration may make real-time responsiveness possible. In other examples, such as where performance is less critical, servers powered by CPUs, FPGAs, and other processors may be used for inferencing.

### Example Computing Device

FIG. 9 is a block diagram of an example computing device(s) 900 suitable for use in implementing some embodiments of the present disclosure. Computing device 900 may include an interconnect system 902 that directly or indirectly couples the following devices: memory 904, one or more central processing units (CPUs) 906, one or more graphics processing units (GPUs) 908, a communication interface 910, input/output (I/O) ports 912, input/output components 914, a power supply 916, one or more presentation components 918 (e.g., display(s)), and one or more logic units 920. In at least one embodiment, the computing device(s) 900 may comprise one or more virtual machines (VMs), and/or any of the components thereof may comprise virtual components (e.g., virtual hardware components). For non-limiting examples, one or more of the GPUs 908 may comprise one or more vGPUs, one or more of the CPUs 906 may comprise one or more vCPUs, and/or one or more of the logic units 920 may comprise one or more virtual logic units. As such, a computing device(s) 900 may include discrete components (e.g., a full GPU dedicated to the computing device 900), virtual components (e.g., a portion of a GPU dedicated to the computing device 900), or a combination thereof. In some embodiments, one or more functions of the simulation platform 100 described herein may be executed at least in part using computing device(s) 200.

Although the various blocks of FIG. 9 are shown as connected via the interconnect system 902 with lines, this is not intended to be limiting and is for clarity only. For example, in some embodiments, a presentation component 918, such as a display device, may be considered an I/O component 914 (e.g., if the display is a touch screen). As another example, the CPUs 906 and/or GPUs 908 may include memory (e.g., the memory 904 may be representative of a storage device in addition to the memory of the GPUs 908, the CPUs 906, and/or other components). As such, the computing device of FIG. 9 is merely illustrative. Distinction is not made between such categories as “workstation,” “server,” “laptop,” “desktop,” “tablet,” “client device,” “mobile device,” “hand-held device,” “game console,” “electronic control unit (ECU),” “virtual reality system,” and/or other device or system types, as all are contemplated within the scope of the computing device of FIG. 9.

The interconnect system 902 may represent one or more links or busses, such as an address bus, a data bus, a control bus, or a combination thereof. The interconnect system 902 may include one or more bus or link types, such as an industry standard architecture (ISA) bus, an extended industry standard architecture (EISA) bus, a video electronics standards association (VESA) bus, a peripheral component interconnect (PCI) bus, a peripheral component interconnect express (PCIe) bus, and/or another type of bus or link. In some embodiments, there are direct connections between components. As an example, the CPU 906 may be directly connected to the memory 904. Further, the CPU 906 may be directly connected to the GPU 908. Where there is direct, or point-to-point connection between components, the interconnect system 902 may include a PCIe link to carry out the connection. In these examples, a PCI bus need not be included in the computing device 900.

The memory 904 may include any of a variety of computer-readable media. The computer-readable media may be any available media that may be accessed by the computing device 900. The computer-readable media may include both volatile and nonvolatile media, and removable and non-removable media. By way of example, and not limitation, the computer-readable media may comprise computer-storage media and communication media.

The computer-storage media may include both volatile and nonvolatile media and/or removable and non-removable media implemented in any method or technology for storage of information such as computer-readable instructions, data structures, program modules, and/or other data types. For example, the memory 904 may store computer-readable instructions (e.g., that represent a program(s) and/or a program element(s), such as an operating system. Computer-storage media may include, but is not limited to, RAM, ROM, EEPROM, flash memory or other memory technology, CD-ROM, digital versatile disks (DVD) or other optical disk storage, magnetic cassettes, magnetic tape, magnetic disk storage or other magnetic storage devices, or any other medium which may be used to store the desired information and which may be accessed by computing device 900. As used herein, computer storage media does not comprise signals per se.

The computer storage media may embody computer-readable instructions, data structures, program modules, and/or other data types in a modulated data signal such as a carrier wave or other transport mechanism and includes any information delivery media. The term “modulated data signal” may refer to a signal that has one or more of its characteristics set or changed in such a manner as to encode information in the signal. By way of example, and not limitation, the computer storage media may include wired media such as a wired network or direct-wired connection, and wireless media such as acoustic, RF, infrared and other wireless media. Combinations of any of the above should also be included within the scope of computer-readable media.

The CPU(s) 906 may be configured to execute at least some of the computer-readable instructions to control one or more components of the computing device 900 to perform one or more of the methods and/or processes described herein. The CPU(s) 906 may each include one or more cores (e.g., one, two, four, eight, twenty-eight, seventy-two, etc.) that are capable of handling a multitude of software threads simultaneously. The CPU(s) 906 may include any type of processor, and may include different types of processors depending on the type of computing device 900 implemented (e.g., processors with fewer cores for mobile devices and processors with more cores for servers). For example, depending on the type of computing device 900, the processor may be an Advanced RISC Machines (ARM) processor implemented using Reduced Instruction Set Computing (RISC) or an x86 processor implemented using Complex Instruction Set Computing (CISC). The computing device 900 may include one or more CPUs 906 in addition to one or more microprocessors or supplementary co-processors, such as math co-processors.

In addition to or alternatively from the CPU(s) 906, the GPU(s) 908 may be configured to execute at least some of the computer-readable instructions to control one or more components of the computing device 900 to perform one or more of the methods and/or processes described herein. One or more of the GPU(s) 908 may be an integrated GPU (e.g., with one or more of the CPU(s) 906 and/or one or more of the GPU(s) 908 may be a discrete GPU. In embodiments, one or more of the GPU(s) 908 may be a coprocessor of one or more of the CPU(s) 906. The GPU(s) 908 may be used by the computing device 900 to render graphics (e.g., 3D graphics) or perform general purpose computations. For example, the GPU(s) 908 may be used for General-Purpose computing on GPUs (GPGPU). The GPU(s) 908 may include hundreds or thousands of cores that are capable of handling hundreds or thousands of software threads simultaneously. The GPU(s) 908 may generate pixel data for output images in response to rendering commands (e.g., rendering commands from the CPU(s) 906 received via a host interface). The GPU(s) 908 may include graphics memory, such as display memory, for storing pixel data or any other suitable data, such as GPGPU data. The display memory may be included as part of the memory 904. The GPU(s) 908 may include two or more GPUs operating in parallel (e.g., via a link). The link may directly connect the GPUs (e.g., using NVLINK) or may connect the GPUs through a switch (e.g., using NVSwitch). When combined together, each GPU 908 may generate pixel data or GPGPU data for different portions of an output or for different outputs (e.g., a first GPU for a first image and a second GPU for a second image). Each GPU may include its own memory, or may share memory with other GPUs.

In addition to or alternatively from the CPU(s) 906 and/or the GPU(s) 908, the logic unit(s) 920 may be configured to execute at least some of the computer-readable instructions to control one or more components of the computing device 900 to perform one or more of the methods and/or processes described herein. In embodiments, the CPU(s) 906, the GPU(s) 908, and/or the logic unit(s) 920 may discretely or jointly perform any combination of the methods, processes and/or portions thereof. One or more of the logic units 920 may be part of and/or integrated in one or more of the CPU(s) 906 and/or the GPU(s) 908 and/or one or more of the logic units 920 may be discrete components or otherwise external to the CPU(s) 906 and/or the GPU(s) 908. In embodiments, one or more of the logic units 920 may be a coprocessor of one or more of the CPU(s) 906 and/or one or more of the GPU(s) 908.

In some embodiments, one or more functions of the simulation processor 130, such as the USS array simulation model 110 may be implemented using code executed by one or more processors comprising processing circuitry such as CPU(s) 806, GPU(s) 808, and/or logic unit(s) 920.

Examples of the logic unit(s) 920 include one or more processing cores and/or components thereof, such as Data Processing Units (DPUs), Tensor Cores (TCs), Tensor Processing Units(TPUs), Pixel Visual Cores (PVCs), Vision Processing Units (VPUs), Graphics Processing Clusters (GPCs), Texture Processing Clusters (TPCs), Streaming Multiprocessors (SMs), Tree Traversal Units (TTUs), Artificial Intelligence Accelerators (AIAs), Deep Learning Accelerators (DLAs), Arithmetic-Logic Units (ALUs), Application-Specific Integrated Circuits (ASICs), Floating Point Units (FPUs), input/output (I/O) elements, peripheral component interconnect (PCI) or peripheral component interconnect express (PCIe) elements, and/or the like.

The communication interface 910 may include one or more receivers, transmitters, and/or transceivers that allow the computing device 900 to communicate with other computing devices via an electronic communication network, included wired and/or wireless communications. The communication interface 910 may include components and functionality to allow communication over any of a number of different networks, such as wireless networks (e.g., Wi-Fi, Z-Wave, Bluetooth, Bluetooth LE, ZigBee, etc.), wired networks (e.g., communicating over Ethernet or InfiniBand), low-power wide-area networks (e.g., LoRaWAN, SigFox, etc.), and/or the Internet. In one or more embodiments, logic unit(s) 920 and/or communication interface 910 may include one or more data processing units (DPUs) to transmit data received over a network and/or through interconnect system 902 directly to (e.g., a memory of) one or more GPU(s) 908.

The I/O ports 912 may allow the computing device 900 to be logically coupled to other devices including the I/O components 914, the presentation component(s) 918, and/or other components, some of which may be built in to (e.g., integrated in) the computing device 900. Illustrative I/O components 914 include a microphone, mouse, keyboard, joystick, game pad, game controller, satellite dish, scanner, printer, wireless device, etc. The I/O components 914 may provide a natural user interface (NUI) that processes air gestures, voice, or other physiological inputs generated by a user. In some instances, inputs may be transmitted to an appropriate network element for further processing. An NUI may implement any combination of speech recognition, stylus recognition, facial recognition, biometric recognition, gesture recognition both on screen and adjacent to the screen, air gestures, head and eye tracking, and touch recognition (as described in more detail below) associated with a display of the computing device 900. The computing device 900 may be include depth cameras, such as stereoscopic camera systems, infrared camera systems, RGB camera systems, touchscreen technology, and combinations of these, for gesture detection and recognition. Additionally, the computing device 900 may include accelerometers or gyroscopes (e.g., as part of an inertia measurement unit (IMU)) that allow detection of motion. In some examples, the output of the accelerometers or gyroscopes may be used by the computing device 900 to render immersive augmented reality or virtual reality.

The power supply 916 may include a hard-wired power supply, a battery power supply, or a combination thereof. The power supply 916 may provide power to the computing device 900 to allow the components of the computing device 900 to operate.

The presentation component(s) 918 may include a display (e.g., a monitor, a touch screen, a television screen, a heads-up-display (HUD), other display types, or a combination thereof), speakers, and/or other presentation components. The presentation component(s) 918 may receive data from other components (e.g., the GPU(s) 908, the CPU(s) 906, DPUs, etc.), and output the data (e.g., as an image, video, sound, etc.). In some embodiments, the HMI 142 may be implemented using one or more of the presentation component(s) 918.

### Example Data Center

FIG. 10 illustrates an example data center 1000 that may be used in at least one embodiments of the present disclosure. The data center 1000 may include a data center infrastructure layer 1010, a framework layer 1020, a software layer 1030, and/or an application layer 1040. In some embodiments, one or more functions of the simulation processor 130, such as the USS array simulation model 110 may be implemented using code executed using data center 1000.

As shown in FIG. 10, the data center infrastructure layer 1010 may include a resource orchestrator 1012, grouped computing resources 1014, and node computing resources (“node C.R.s”) 1016(1)-1016(N), where “N” represents any whole, positive integer. In at least one embodiment, node C.R.s 1016(1)-1016(N) may include, but are not limited to, any number of central processing units (CPUs) or other processors (including DPUs, accelerators, field programmable gate arrays (FPGAs), graphics processors or graphics processing units (GPUs), etc.), memory devices (e.g., dynamic read-only memory), storage devices (e.g., solid state or disk drives), network input/output (NW I/O) devices, network switches, virtual machines (VMs), power modules, and/or cooling modules, etc. In some embodiments, one or more node C.R.s from among node C.R.s 1016(1)-1016(N) may correspond to a server having one or more of the above-mentioned computing resources. In addition, in some embodiments, the node C.R.s 1016(1)-10161(N) may include one or more virtual components, such as vGPUs, vCPUs, and/or the like, and/or one or more of the node C.R.s 1016(1)-1016(N) may correspond to a virtual machine (VM).

In at least one embodiment, grouped computing resources 1014 may include separate groupings of node C.R.s 1016 housed within one or more racks (not shown), or many racks housed in data centers at various geographical locations (also not shown). Separate groupings of node C.R.s 1016 within grouped computing resources 1014 may include grouped compute, network, memory or storage resources that may be configured or allocated to support one or more workloads. In at least one embodiment, several node C.R.s 1016 including CPUs, GPUs, DPUs, and/or other processors may be grouped within one or more racks to provide compute resources to support one or more workloads. The one or more racks may also include any number of power modules, cooling modules, and/or network switches, in any combination.

The resource orchestrator 1012 may configure or otherwise control one or more node C.R.s 1016(1)-1016(N) and/or grouped computing resources 1014. In at least one embodiment, resource orchestrator 1012 may include a software design infrastructure (SDI) management entity for the data center 1000. The resource orchestrator 1012 may include hardware, software, or some combination thereof. In some embodiments, one or more functions of the simulation processor 130, such as the USS array simulation model 110 may be implemented using code executed by one or more node C.R.s 1016(1)-1016(N).

In at least one embodiment, as shown in FIG. 10, framework layer 1020 may include a job scheduler 1033, a configuration manager 1034, a resource manager 1036, and/or a distributed file system 1038. The framework layer 1020 may include a framework to support software 1032 of software layer 1030 and/or one or more application(s) 1042 of application layer 1040. The software 1032 or application(s) 1042 may respectively include web-based service software or applications, such as those provided by Amazon Web Services, Google Cloud and Microsoft Azure. The framework layer 1020 may be, but is not limited to, a type of free and open-source software web application framework such as Apache SparkTM (hereinafter “Spark”) that may use distributed file system 1038 for large-scale data processing (e.g., “big data”). In at least one embodiment, job scheduler 1033 may include a Spark driver to facilitate scheduling of workloads supported by various layers of data center 1000. The configuration manager 1034 may be capable of configuring different layers such as software layer 1030 and framework layer 1020 including Spark and distributed file system 1038 for supporting large-scale data processing. The resource manager 1036 may be capable of managing clustered or grouped computing resources mapped to or allocated for support of distributed file system 1038 and job scheduler 1033. In at least one embodiment, clustered or grouped computing resources may include grouped computing resource 1014 at data center infrastructure layer 1010. The resource manager 1036 may coordinate with resource orchestrator 1012 to manage these mapped or allocated computing resources.

In at least one embodiment, software 1032 included in software layer 1030 may include software used by at least portions of node C.R.s 1016(1)-1016(N), grouped computing resources 1014, and/or distributed file system 1038 of framework layer 1020. One or more types of software may include, but are not limited to, Internet web page search software, e-mail virus scan software, database software, and streaming video content software.

In at least one embodiment, application(s) 1042 included in application layer 1040 may include one or more types of applications used by at least portions of node C.R.s 1016(1)-1016(N), grouped computing resources 1014, and/or distributed file system 1038 of framework layer 1020. One or more types of applications may include, but are not limited to, any number of a genomics application, a cognitive compute, and a machine learning application, including training or inferencing software, machine learning framework software (e.g., PyTorch, TensorFlow, Caffe, etc.), and/or other machine learning applications used in conjunction with one or more embodiments. In some embodiments, one or more functions of the simulation processor 130, such as the USS array simulation model 110 may be implemented using software 1032 and/or application(s) 842.

In at least one embodiment, any of configuration manager 1034, resource manager 1036, and resource orchestrator 1012 may implement any number and type of self-modifying actions based on any amount and type of data acquired in any technically feasible fashion. Self-modifying actions may relieve a data center operator of data center 1000 from making possibly bad configuration decisions and possibly avoiding underutilized and/or poor performing portions of a data center.

The data center 1000 may include tools, services, software or other resources to train one or more machine learning models or predict or infer information using one or more machine learning models according to one or more embodiments described herein. For example, a machine learning model(s) may be trained by calculating weight parameters according to a neural network architecture using software and/or computing resources described above with respect to the data center 1000. In at least one embodiment, trained or deployed machine learning models corresponding to one or more neural networks may be used to infer or predict information using resources described above with respect to the data center 1000 by using weight parameters calculated through one or more training techniques, such as but not limited to those described herein.

In at least one embodiment, the data center 1000 may use CPUs, application-specific integrated circuits (ASICs), GPUs, FPGAs, and/or other hardware (or virtual compute resources corresponding thereto) to perform training and/or inferencing using above-described resources. Moreover, one or more software and/or hardware resources described above may be configured as a service to allow users to train or performing inferencing of information, such as image recognition, speech recognition, or other artificial intelligence services.

### Example Network Environments

Network environments suitable for use in implementing embodiments of the disclosure may include one or more client devices, servers, network attached storage (NAS), other backend devices, and/or other device types. The client devices, servers, and/or other device types (e.g., each device) may be implemented on one or more instances of the computing device(s) 900 of FIG. 9—e.g., each device may include similar components, features, and/or functionality of the computing device(s) 900. In addition, where backend devices (e.g., servers, NAS, etc.) are implemented, the backend devices may be included as part of a data center 1000, an example of which is described in more detail herein with respect to FIG. 10.

Components of a network environment may communicate with each other via a network(s), which may be wired, wireless, or both. The network may include multiple networks, or a network of networks. By way of example, the network may include one or more Wide Area Networks (WANs), one or more Local Area Networks (LANs), one or more public networks such as the Internet and/or a public switched telephone network (PSTN), and/or one or more private networks. Where the network includes a wireless telecommunications network, components such as a base station, a communications tower, or even access points (as well as other components) may provide wireless connectivity.

Compatible network environments may include one or more peer-to-peer network environments—in which case a server may not be included in a network environment—and one or more client-server network environments—in which case one or more servers may be included in a network environment. In peer-to-peer network environments, functionality described herein with respect to a server(s) may be implemented on any number of client devices.

In at least one embodiment, a network environment may include one or more cloud-based network environments, a distributed computing environment, a combination thereof, etc. A cloud-based network environment may include a framework layer, a job scheduler, a resource manager, and a distributed file system implemented on one or more of servers, which may include one or more core network servers and/or edge servers. A framework layer may include a framework to support software of a software layer and/or one or more application(s) of an application layer. The software or application(s) may respectively include web-based service software or applications. In embodiments, one or more of the client devices may use the web-based service software or applications (e.g., by accessing the service software and/or applications via one or more application programming interfaces (APIs)). The framework layer may be, but is not limited to, a type of free and open-source software web application framework such as that may use a distributed file system for large-scale data processing (e.g., “big data”).

A cloud-based network environment may provide cloud computing and/or cloud storage that carries out any combination of computing and/or data storage functions described herein (or one or more portions thereof). Any of these various functions may be distributed over multiple locations from central or core servers (e.g., of one or more data centers that may be distributed across a state, a region, a country, the globe, etc.). If a connection to a user (e.g., a client device) is relatively close to an edge server(s), a core server(s) may designate at least a portion of the functionality to the edge server(s). A cloud-based network environment may be private (e.g., limited to a single organization), may be public (e.g., available to many organizations), and/or a combination thereof (e.g., a hybrid cloud environment).

The client device(s) may include at least some of the components, features, and functionality of the example computing device(s) 900 described herein with respect to FIG. 9. By way of example and not limitation, a client device may be embodied as a Personal Computer (PC), a laptop computer, a mobile device, a smartphone, a tablet computer, a smart watch, a wearable computer, a Personal Digital Assistant (PDA), an MP3 player, a virtual reality headset, a Global Positioning System (GPS) or device, a video player, a video camera, a surveillance device or system, a vehicle, a boat, a flying vessel, a virtual machine, a drone, a robot, a handheld communications device, a hospital device, a gaming device or system, an entertainment system, a vehicle computer system, an embedded system controller, a remote control, an appliance, a consumer electronic device, a workstation, an edge device, any combination of these delineated devices, or any other suitable device.

The disclosure may be described in the general context of computer code or machine-useable instructions, including computer-executable instructions such as program modules, being executed by a computer or other machine, such as a personal data assistant or other handheld device. Generally, program modules including routines, programs, objects, components, data structures, etc., refer to code that perform particular tasks or implement particular abstract data types. The disclosure may be practiced in a variety of system configurations, including hand-held devices, consumer electronics, general-purpose computers, more specialty computing devices, etc. The disclosure may also be practiced in distributed computing environments where tasks are performed by remote-processing devices that are linked through a communications network.

As used herein, a recitation of “and/or” with respect to two or more elements should be interpreted to mean only one element, or a combination of elements. For example, “element A, element B, and/or element C” may include only element A, only element B, only element C, element A and element B, element A and element C, element B and element C, or elements A, B, and C. In addition, “at least one of element A or element B” may include at least one of element A, at least one of element B, or at least one of element A and at least one of element B. Further, “at least one of element A and element B” may include at least one of element A, at least one of element B, or at least one of element A and at least one of element B.

The subject matter of the present disclosure is described with specificity herein to meet statutory requirements. However, the description itself is not intended to limit the scope of this disclosure. Rather, the inventors have contemplated that the claimed subject matter might also be embodied in other ways, to include different steps or combinations of steps similar to the ones described in this document, in conjunction with other present or future technologies. Moreover, although the terms “step” and/or “block” may be used herein to connote different elements of methods employed, the terms should not be interpreted as implying any particular order among or between various steps herein disclosed unless and except when the order of individual steps is explicitly described.

What is claimed is:

1. One or more processors comprising processing circuitry to:
compute a plurality of rays representing an ultrasonic acoustic signal emitted from a simulated sensor emitter in a simulation environment, wherein an individual ray of the plurality of rays includes an indication of an initial energy level based at least on a total power of the ultrasonic acoustic signal;
compute, for the simulation environment, a plurality of ray reflections based at least on ray tracing one or more of the plurality of rays between the simulated sensor emitter and one or more sensor receivers in the virtual simulation environment;
generate one or more ultrasonic sensor measurements based at least on computing a response of a sensor receiver to an envelope determined from an aggregation of a plurality of contribution energies of the plurality of ray reflections; and
control at least one operation of an ego-object in the simulation environment based at least on the one or more ultrasonic sensor measurements.

2. The one or more processors of claim 1, wherein the one or more processors are further to:
determine a total propagation associated with the contribution ray based at least on a total propagation time determined based at least on the ray tracing; and
compute an atmospheric attenuation component of the attenuation based at least on a function of the total propagation and an atmospheric attenuation coefficient.

3. The one or more processors of claim 1, wherein the one or more processors are further to:
determine one or more object interaction attenuations for one or more object interactions associated with the contribution ray based at least on the ray tracing; and
compute an object interaction attenuation component of the attenuation based at least on an accumulation of the one or more object interaction attenuations.

4. The one or more processors of claim 3, wherein the one or more processors are further to:
compute the one or more object interaction attenuations based at least on one or more material characteristics of one or more objects associated with the one or more object interactions, and an indication of a frequency of the ultrasonic acoustic signal.

5. The one or more processors of claim 1, wherein the one or more processors are further to:
compute the ray tracing of the one or more of the plurality of rays through the simulation environment based at least on an engine that models sound wave reflections from one or more objects in the simulation environment.

6. The one or more processors of claim 1, wherein the one or more processors are further to:
compute the plurality of rays based at least on one or more input parameters, the one or more input parameters comprising at least one of:
a ray density;
a pulse power of the ultrasonic acoustic signal; and
a gain pattern representing a membrane directivity or the simulated sensor emitter.

7. The one or more processors of claim 1, wherein the one or more processors are further to:
determine the envelope using a time-dependent gain function computed from the aggregation of the plurality of contribution energies.

8. The one or more processors of claim 1, wherein the one or more processors are further to:
selectively define the simulated sensor emitter and the one or more sensor receivers based at least on selecting a configuration of a set of ultrasonic sensor devices.

9. The one or more processors of claim 1, wherein the one or more processors are further to:
perform parallel processing of individual contributions to construct the envelope based at least on the plurality of contribution energies of the plurality of wave reflections.

10. The one or more processors of claim 1, wherein an individual ray reflection of the plurality of ray reflections defines a contribution ray having a contribution energy determined based at least on an attenuation of the initial energy level.

11. The one or more processors of claim 1, wherein the processing circuitry is comprised in at least one of:
a control system for an autonomous or semi-autonomous machine;
a perception system for an autonomous or semi-autonomous machine;
a system for performing simulation operations;
a system for performing digital twin operations;
a system for performing light transport simulation;
a system for performing sound transport simulation;
a system for performing content creation for three-dimensional assets;
a system for performing collaborative content creation for three-dimensional assets;
a system for performing deep learning operations;
a system for performing remote operations;
a system for performing real-time streaming;
a system for generating or presenting one or more of augmented reality content, virtual reality content, or mixed reality content;
a system implemented using an edge device;
a system implemented using a robot;
a system for performing conversational AI operations;
a system implementing one or more language models;
a system implementing one or more large language models (LLMs);
a system implementing one or more vision language models (VLMs);
a system for generating synthetic data;
a system for generating synthetic data using AI;
a system incorporating one or more virtual machines (VMs);
a system implemented at least partially in a data center; or
a system implemented at least partially using cloud computing resources.

12. A system comprising one or more processors to:
compute an acoustic wave contribution energy associated with one or more ray reflections, the one or more ray reflections determined based at least on ray tracing one or more of a plurality of simulated rays between a sensor emitter and one or more sensor receivers in a simulation environment; and
generate one or more ultrasonic sensor measurement output signals based at least on computing a vibrational response to an acoustic wave envelope determined from an aggregation of the acoustic wave contribution energy from individual ray reflections of the one or more ray reflections.

13. The one or more processors of claim 12, wherein the one or more processors are further to:
compute the plurality of simulated rays based at least on one or more input parameters, the one or more input parameters comprising at least one of:
a ray density of the plurality of simulated rays;
a pulse power of an ultrasonic acoustic signal represented by the plurality of simulated rays; and
a gain pattern representing a membrane directivity or the sensor emitter.

14. The system of claim 12, wherein the one or more processors are further to:
compute the plurality of simulated rays, wherein the plurality of simulated rays represent a sampling of a wave front of an ultrasonic acoustic signal emitted from the sensor emitter, wherein an individual ray of the plurality of simulated rays includes an indication of an initial energy level based at least on a total power of the ultrasonic acoustic signal; and
determine the acoustic wave contribution energy based at least on an attenuation of the initial energy level.

15. The system of claim 14, wherein an individual ray reflection of the one or more ray reflections defines a contribution ray associated with the acoustic wave contribution energy, wherein the one or more processors are further to:
determine a total propagation distance associated with the contribution ray using a total propagation time determined based at least on the ray tracing; and
compute an atmospheric attenuation component of the attenuation based at least on a function of the total propagation distance and an atmospheric attenuation coefficient.

16. The system of claim 14, wherein an individual ray reflection of the one or more ray reflections defines a contribution ray associated with the acoustic wave contribution energy, wherein the one or more processors are further to:
determine one or more object interaction attenuations for one or more object interactions associated with the contribution ray based at least on the ray tracing; and
compute an object interaction attenuation component of the attenuation based at least on an accumulation of the one or more object interaction attenuations.

17. The one or more processors of claim 16, wherein the one or more processors are further to:
compute the one or more object interaction attenuations based at least on one or more material characteristics of one or more objects associated with the one or more object interactions, and an indication of a frequency of the ultrasonic acoustic signal.

18. The one or more processors of claim 12, wherein the one or more processors are further to:
determine the envelope using a time-dependent gain function computed from the aggregation of the plurality of contribution energies.

19. The system of claim 12, wherein the system is comprised in at least one of:
a control system for an autonomous or semi-autonomous machine;
a perception system for an autonomous or semi-autonomous machine;
a system for performing simulation operations;
a system for performing digital twin operations;
a system for performing light transport simulation;
a system for performing sound transport simulation;
a system for performing content creation for three-dimensional assets;
a system for performing collaborative content creation for three-dimensional assets;
a system for performing deep learning operations;
a system for performing remote operations;
a system for performing real-time streaming;
a system for generating or presenting one or more of augmented reality content, virtual reality content, or mixed reality content;
a system implemented using an edge device;
a system implemented using a robot;
a system for performing conversational AI operations;
a system implementing one or more language models;
a system implementing one or more large language models (LLMs);
a system implementing one or more vision language models (VLMs);
a system for generating synthetic data;
a system for generating synthetic data using AI;
a system incorporating one or more virtual machines (VMs);
a system implemented at least partially in a data center; or
a system implemented at least partially using cloud computing resources.

20. A method comprising:
ray tracing a plurality of rays representing an ultrasonic acoustic signal emitted from a sensor emitter in a simulated environment;
computing an aggregate contribution energy based at least on the ray-traced plurality of rays;
computing an acoustic wave envelope based at least on the aggregate contribution energy;
computing a vibrational response of a sensor receiver to the acoustic wave envelope;
generating one or more output signals representing one or more simulated ultrasonic sensor measurements based at least on the vibrational response; and
controlling an operation of a simulated ego-object in the simulated environment based at least on the one or more output signals.
